(19) United States
(12) Patent Application Publication
(10) Pub. No.: US 2026/0181915 A1
(43) Pub. Date: Jun. 25, 2026

(54) SEMICONDUCTOR MEMORY DEVICE

(71) Applicant: Kioxia Corporation, Tokyo (JP)

(72) Inventors: Yusuke OKUMURA, Yokkaichi (JP); Shigeki KOBAYASHI, Kamakura (JP)

(73) Assignee: Kioxia Corporation, Tokyo (JP)

(21) Appl. No.: 19/220,344

(22) Filed: May 28, 2025

(30) Foreign Application Priority Data
Dec. 20, 2024 (JP) 2024-225402

(51) Int. Cl. H10B 80/00; H01L 23/00; H01L 25/00; H01L 25/065; H01L 25/18

(52) U.S. Cl. CPC H10B 80/00; H10W 90/00; H10W 80/312; H10W 80/327; H10W 90/792

(57) ABSTRACT

In general, according to one embodiment, a semiconductor memory device includes: first, plurality of second, third, and plurality of fourth interconnect layers which are stacked in this order in a first direction wherein the second and fourth interconnect layers include a plurality of first and second terrace portions, respectively; first and second memory pillars which extend in the first direction, pass through the second and fourth interconnect layers, respectively, and are in contact with the first and third interconnect layers, respectively; first and third contacts which extends in the first direction and are in contact with one of the first and second terrace portions, respectively; and a second contact which extends in the first direction above the first contact, and passes through the fourth interconnect layers.

### CROSS-REFERENCE TO RELATED APPLICATIONS

This application is based upon and claims the benefit of priority from Japanese Patent Application No. 2024-225402, filed Dec. 20, 2024, the entire contents of which are incorporated herein by reference.

### FIELD

Embodiments described herein relate generally to a semiconductor memory device.

### BACKGROUND

A NAND flash memory is known as a semiconductor memory device that can memorize data in a non-volatile manner. In the NAND flash memory, a three-dimensional memory structure may be adopted for increasing the level of integration and capacity.

### BRIEF DESCRIPTION OF THE DRAWINGS

FIG. 1 is a block diagram illustrating an example of a configuration of a memory system according to a first embodiment.

FIG. 2 is a perspective view illustrating an example of an appearance of a semiconductor memory device according to the first embodiment.

FIG. 3 is a perspective view illustrating an overview of a bonding structure of the semiconductor memory device according to the first embodiment.

FIG. 4 is a circuit diagram illustrating an example of a circuit configuration of a memory cell array included in the semiconductor memory device according to the first embodiment.

FIG. 5 is a plan view illustrating an example of a planar layout of the memory cell array included in the semiconductor memory device according to the first embodiment.

FIG. 6 is a sectional view schematically illustrating an example of a sectional structure of a first memory layer and a second memory layer that are bonded together, which are included in the semiconductor memory device according to the first embodiment.

FIG. 7 is a plan view illustrating an example of a planar layout in a memory area of the memory cell array included in the semiconductor memory device according to the first embodiment.

FIG. 8 is a sectional view taken along line VIII-VIII in FIG. 7, illustrating an example of a sectional structure in the memory area of the memory cell array included in the semiconductor memory device according to the first embodiment.

FIG. 9 is a sectional view taken along line IX-IX in FIG. 8, illustrating an example of a sectional structure of a memory pillar included in the semiconductor memory device according to the first embodiment.

FIG. 10 is a plan view illustrating an example of a planar layout in a hookup area of the memory cell array included in the semiconductor memory device according to the first embodiment.

FIG. 11 is a sectional view taken along line XI-XI in FIG. 10, illustrating an example of a sectional structure in the hookup area of the memory cell array included in the semiconductor memory device according to the first embodiment.

FIG. 12 is a sectional view taken along line XII-XII in FIG. 10, illustrating an example of a sectional structure in the hookup area of the memory cell array included in the semiconductor memory device according to the first embodiment.

FIG. 13 is a sectional view illustrating an example of a sectional structure of the first memory layer, the second memory layer, and a joint layer provided between the first memory layer and the second memory layer included in the semiconductor memory device according to the first embodiment.

FIG. 14 is a sectional view taken along line XIV-XIV in FIG. 13, illustrating an example of a sectional structure of the first memory layer, the second memory layer, and the joint layer provided between the first memory layer and the second memory layer included in the semiconductor memory device according to the first embodiment.

FIG. 15 is a sectional view taken along line XV-XV in FIG. 13, illustrating an example of a sectional structure of the first memory layer, the second memory layer, and the joint layer provided between the first memory layer and the second memory layer included in the semiconductor memory device according to the first embodiment.

FIG. 16 is a sectional view illustrating an example of a sectional structure of the semiconductor memory device according to the first embodiment.

FIG. 17 is a sectional view illustrating an example of a sectional structure in the vicinity of two joint pads bonded to each other and provided in the joint layer between the first memory layer and the second memory layer included in the semiconductor memory device according to the first embodiment.

FIG. 18 is a flowchart illustrating an example of a manufacturing process of the memory cell array included in the semiconductor memory device according to the first embodiment.

FIG. 19 is a sectional view illustrating an example of a sectional structure of the semiconductor memory device according to the first embodiment in the middle of manufacturing.

FIG. 20 is a sectional view illustrating an example of a sectional structure of the semiconductor memory device according to the first embodiment in the middle of manufacturing.

FIG. 21 is a sectional view illustrating an example of a sectional structure of the semiconductor memory device according to the first embodiment in the middle of manufacturing.

FIG. 22 is a sectional view illustrating an example of a sectional structure of the semiconductor memory device according to the first embodiment in the middle of manufacturing.

FIG. 23 is a sectional view illustrating an example of a sectional structure of the semiconductor memory device according to the first embodiment in the middle of manufacturing.

FIG. 24 is a sectional view illustrating an example of a sectional structure of the semiconductor memory device according to the first embodiment in the middle of manufacturing.

FIG. 25 is a sectional view illustrating an example of a sectional structure of the semiconductor memory device according to the first embodiment in the middle of manufacturing.

FIG. 26 is a sectional view illustrating an example of a sectional structure of the semiconductor memory device according to the first embodiment in the middle of manufacturing.

FIG. 27 is a sectional view illustrating an example of a sectional structure of the semiconductor memory device according to the first embodiment in the middle of manufacturing.

FIG. 28 is a sectional view illustrating an example of a sectional structure of the semiconductor memory device according to the first embodiment in the middle of manufacturing.

FIG. 29 is a sectional view illustrating an example of a sectional structure of the semiconductor memory device according to the first embodiment in the middle of manufacturing.

FIG. 30 is a sectional view illustrating an example of a sectional structure of the semiconductor memory device according to the first embodiment in the middle of manufacturing.

FIG. 31 is a sectional view illustrating an example of a sectional structure of the semiconductor memory device according to the first embodiment in the middle of manufacturing.

FIG. 32 is a sectional view illustrating an example of a sectional structure of the semiconductor memory device according to the first embodiment in the middle of manufacturing.

FIG. 33 is a sectional view illustrating an example of a sectional structure of the semiconductor memory device according to the first embodiment in the middle of manufacturing.

FIG. 34 is a sectional view illustrating an example of a sectional structure of the semiconductor memory device according to the first embodiment in the middle of manufacturing.

FIG. 35 is a sectional view illustrating an example of a sectional structure of a first memory layer, a second memory layer, and a joint layer provided between the first memory layer and the second memory layer included in a semiconductor memory device according to a first modification of the first embodiment.

FIG. 36 is a sectional view illustrating an example of a sectional structure of a first memory layer, a second memory layer, and a joint layer provided between the first memory layer and the second memory layer included in a semiconductor memory device according to a second modification of the first embodiment.

FIG. 37 is a sectional view illustrating an example of a sectional structure in a hookup area of a memory cell array included in a semiconductor memory device according to a third modification of the first embodiment.

FIG. 38 is a sectional view illustrating an example of a sectional structure of a first memory layer, a second memory layer, and a joint layer provided between the first memory layer and the second memory layer included in a semiconductor memory device according to a second embodiment.

FIG. 39 is a sectional view taken along line XXXIX-XXXIX in FIG. 38, illustrating an example of a sectional structure of the first memory layer, the second memory layer, and the joint layer provided between the first memory layer and the second memory layer included in the semiconductor memory device according to the second embodiment.

FIG. 40 is a sectional view illustrating an example of a sectional structure of a first memory layer, a second memory layer, and a joint layer provided between the first memory layer and the second memory layer included in a semiconductor memory device according to a first modification of the second embodiment.

FIG. 41 is a sectional view illustrating an example of a sectional structure of a first memory layer, a second memory layer, and a joint layer provided between the first memory layer and the second memory layer included in a semiconductor memory device according to a second modification of the second embodiment.

FIG. 42 is a plan view illustrating an example of a planar layout in a hookup area of a memory cell array included in a semiconductor memory device according to a third embodiment.

FIG. 43 is a sectional view taken along line XLIII-XLIII in FIG. 42, illustrating an example of a sectional structure in the hookup area of the memory cell array included in the semiconductor memory device according to the third embodiment.

FIG. 44 is a plan view illustrating an example of a planar layout of a memory cell array included in a semiconductor memory device according to a fourth embodiment.

FIG. 45 is a sectional view schematically illustrating an example of a sectional structure of a first memory layer and a second memory layer that are bonded together, which are included in the semiconductor memory device according to the fourth embodiment.

FIG. 46 is a plan view illustrating an example of a planar layout in a hookup area of the memory cell array included in the semiconductor memory device according to the fourth embodiment.

FIG. 47 is a plan view illustrating an example of a planar layout in a hookup area of a memory cell array included in a semiconductor memory device according to a fifth embodiment.

FIG. 48 is a sectional view illustrating an example of a sectional structure of a first memory layer, a second memory layer, and a joint layer provided between the first memory layer and the second memory layer included in the semiconductor memory device according to the fifth embodiment.

FIG. 49 is a plan view illustrating an example of a planar layout in a hookup area of a memory cell array included in a semiconductor memory device according to a sixth embodiment.

FIG. 50 is a plan view illustrating an example of a planar layout of a memory cell array included in a semiconductor memory device according to a seventh embodiment.

FIG. 51 is a sectional view schematically illustrating an example of a sectional structure of a first memory layer and a second memory layer that are bonded together, which are included in the semiconductor memory device according to the seventh embodiment.

FIG. 52 is a plan view illustrating an example of a planar layout in a hookup area of the memory cell array included in the semiconductor memory device according to the seventh embodiment.

FIG. 53 is a sectional view illustrating an example of a sectional structure of the first memory layer, the second memory layer, and a joint layer provided between the first memory layer and the second memory layer included in the semiconductor memory device according to the seventh embodiment.

FIG. 54 is a plan view illustrating an example of a planar layout of a memory cell array included in a semiconductor memory device according to an eighth embodiment.

FIG. 55 is a sectional view schematically illustrating an example of a sectional structure of a first memory layer and a second memory layer that are bonded together, which are included in the semiconductor memory device according to the eighth embodiment.

FIG. 56 is a plan view illustrating an example of a planar layout in a hookup area of the memory cell array included in the semiconductor memory device according to the eighth embodiment.

### DETAILED DESCRIPTION

In general, according to one embodiment, a semiconductor memory device includes: a first interconnect layer which is provided in a first area as viewed in a first direction; a plurality of second interconnect layers which are provided apart from each other in the first direction above the first interconnect layer and over the first area and a second area aligned with the first area in a second direction intersecting the first direction, the second interconnect layers including, in the second area, a plurality of first terrace portions provided so as not to overlap an upper second interconnect layer in the first direction and a first bridge portion extending in the second direction, and the first terrace portions and the first bridge portion being arranged in a third direction intersecting the first direction and the second direction; a third interconnect layer which is provided in the first area above the second interconnect layers; a plurality of fourth interconnect layers which are provided apart from each other in the first direction above the third interconnect layer and over the first area and the second area, the fourth interconnect layers including, in the second area, a plurality of second terrace portions provided at positions overlapping the first bridge portion as viewed in the first direction so as not to overlap an upper fourth interconnect layer in the first direction and a second bridge portion extending in the second direction and provided at positions overlapping the first terrace portions as viewed in the first direction, and the second terrace portions and the second bridge portion being arranged in the third direction; a first memory pillar which extends in the first direction in the first area and is in contact with the first interconnect layer, and in which portions passing through the second interconnect layers function as a plurality of first memory cells; a second memory pillar which extends in the first direction in the first area and is in contact with the third interconnect layer, and in which portions passing through the fourth interconnect layers function as a plurality of second memory cells; a first contact which is in contact with one of the first terrace portions and extends in the first direction in the second area; a second contact which extends in the first direction above the first contact in the second area, passes through the fourth interconnect layers, and is electrically coupled to the first contact; and a third contact which is in contact with one of the second terrace portions and extends in the first direction in the second area.

Hereinafter, embodiments will be described with reference to the drawings. The drawings are schematic, and dimensions and ratios of the drawings are not necessarily the same as actual ones. In the following description, constituent elements having substantially the same function and configuration are denoted by the same reference signs. In a case where elements having similar configurations are particularly distinguished from each other, different characters or numbers may be added to the end of the same reference sign.

In the following description, a first component being “coupled” to a different second component encompasses the first component being coupled to the second component indirectly through the intervention of an intermediate element that is conductive constantly or selectively, or directly without any intervention of such an intermediate element.

### 1. First Embodiment

### 1.1 Configurations

### 1.1.1 Memory System

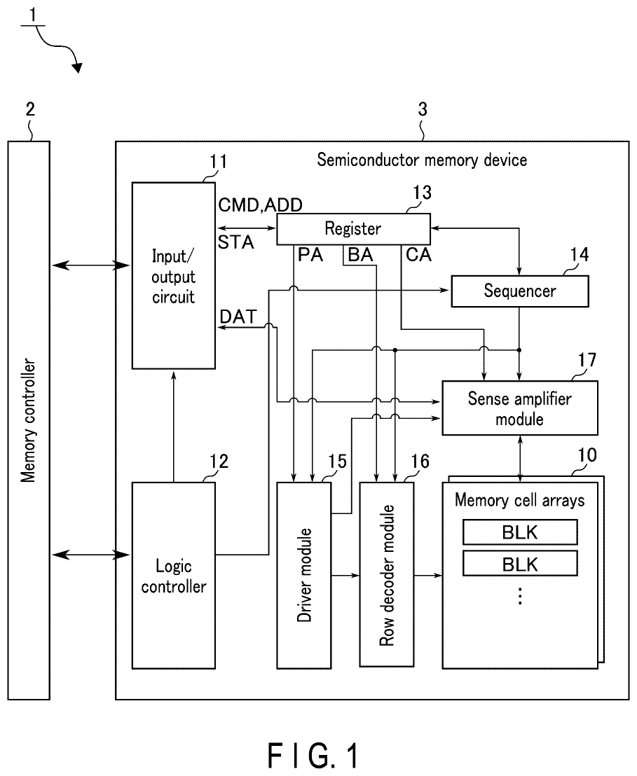

A semiconductor memory device according to a first embodiment will be described. FIG. 1 is a block diagram illustrating an example of a configuration of a memory system according to the first embodiment. A memory system 1 is a storage device configured to be coupled to an external host device (not illustrated). The memory system 1 is, for example, a memory card such as an SD^{TM} card, a universal flash storage (UFS), or a solid state drive (SSD). The memory system 1 includes a memory controller 2 and a semiconductor memory device 3.

The memory controller 2 includes, for example, an integrated circuit such as a system on a chip (SoC). The memory controller 2 controls the semiconductor memory device 3 based on a request from an external host device. Specifically, the memory controller 2 writes data requested to be written by an external host device to the semiconductor memory device 3. The memory controller 2 reads, from the semiconductor memory device 3, data requested to be read by an external host device and outputs the data to the external host device.

The semiconductor memory device 3 is, for example, a NAND flash memory that can memorize data in a non-volatile manner.

Communication between the memory controller 2 and the semiconductor memory device 3 conforms to, for example, a single data rate (SDR) interface, a toggle double data rate (DDR) interface, or an open NAND flash interface (ONFI).

### 1.1.2 Semiconductor Memory Device

Subsequently, an internal configuration of the semiconductor memory device 3 according to the first embodiment will be described with reference to the block diagram provided in FIG. 1. The semiconductor memory device 3 includes, for example, a plurality of memory cell arrays 10, an input/output circuit 11, a logic controller 12, a register 13, a sequencer 14, a driver module 15, a row decoder module 16, and a sense amplifier module 17.

The plurality of memory cell arrays 10 are aggregates of a set of memory cell transistors and constituent elements coupled to the memory cell transistors. Each memory cell array 10 includes a plurality of blocks BLK. For example, each memory cell array 10 includes (n+1) blocks BLK0 to BLKn (n is an integer of 1 or more). The block BLK is an aggregate of a plurality of memory cell transistors that can memorize data in a non-volatile manner. The block BLK is used as, for example, an erase unit at the time of erasing data memorized in the memory cell transistors. Each memory cell array 10 includes a plurality of bit lines and a plurality of word lines. Each memory cell transistor is associated with, for example, a combination of one bit line and one word line. In the following description, a case where two memory cell arrays 10-1 and 10-2 are provided will be described. The circuit configurations of the memory cell arrays 10-1 and 10-2 are substantially the same. In the following description, a suffix “_1” is added to the block BLK included in the memory cell array 10-1. A suffix “_2” is added to the block BLK included in the memory cell array 10-2. That is, the semiconductor memory device 3 includes a plurality of blocks BLK0_1 to BLKn_1 and a plurality of blocks BLK0_2 to BLKn_2. In a case where the memory cell arrays 10-1 and 10-2 are not distinguished from each other, they are described without suffixes. Note that three or more memory cell arrays 10 may be provided. A detailed configuration of the memory cell array 10 will be described later.

The input/output circuit 11 is an interface circuit responsible for transmission and reception of input/output signals to and from the memory controller 2. The input/output signal includes, for example, data DAT, a command CMD, address information ADD, and status information STA. The input/output circuit 11 inputs and outputs the data DAT to and from the sense amplifier module 17 as well as to and from the memory controller 2. The input/output circuit 11 outputs each of the command CMD and the address information ADD transferred from the memory controller 2 to the register 13. The input/output circuit 11 outputs the status information STA transferred from the register 13 to the memory controller 2.

The logic controller 12 receives a control signal input from the memory controller 2. Based on the control signal, the logic controller 12 controls each of the input/output circuit 11 and the sequencer 14. For example, the logic controller 12 notifies the input/output circuit 11 that the input/output signal received by the input/output circuit 11 is the command CMD, the address information ADD, or the like. The logic controller 12 orders the input/output circuit 11 to input or output an input/output signal. The logic controller 12 controls the sequencer 14 and enables the semiconductor memory device 3. In addition, the logic controller 12 outputs, to the memory controller 2, a signal indicating whether the semiconductor memory device 3 is in a ready state or a busy state.

The register 13 temporarily stores the command CMD, the address information ADD, and the status information STA. The command CMD includes, for example, an order for causing the sequencer 14 to execute a read operation, a write operation, an erase operation, and the like. The address information ADD includes, for example, a block address BA, a page address PA, and a column address CA. For example, the block address BA, the page address PA, and the column address CA are used to select the block BLK, the word line, and the bit line, respectively. The status information STA is updated based on the control of the sequencer 14 and transferred to the input/output circuit 11.

The sequencer 14 controls the entire operation of the semiconductor memory device 3. For example, the sequencer 14 controls the driver module 15, the row decoder module 16, the sense amplifier module 17, and the like based on the command CMD stored in the register 13 and executes a read operation, a write operation, an erase operation, and the like.

The driver module 15 generates a plurality of voltages that have different magnitudes and are used in a read operation, a write operation, an erase operation, and the like. The driver module 15 supplies the generated voltage to the row decoder module 16, the sense amplifier module 17, and the like. In addition, the driver module 15 applies the generated voltage to, for example, the signal line corresponding to the word line selected based on the page address PA stored in the register 13.

The row decoder module 16 selects, for example, the corresponding one block BLK in the memory cell array 10 based on the block address BA stored in the register 13. The row decoder module 16 transfers, for example, the voltage of the signal line applied by the driver module 15 to the selected word line in the selected block BLK.

The sense amplifier module 17 includes a sense amplifier that can determine data based on a voltage of an associated bit line, a latch circuit that temporarily stores data, and the like. In the write operation, the sense amplifier module 17 applies a desired voltage to each bit line in accordance with write data DAT received from the input/output circuit 11. In addition, in the read operation, the sense amplifier module 17 determines the data memorized in the memory cell transistor based on the magnitude of the voltage of the bit line. Thereafter, the sense amplifier module 17 transfers the determination result as read data DAT to the input/output circuit 11.

### 1.1.3 Appearance of Semiconductor Memory Device

The semiconductor memory device 3 according to the first embodiment is formed by bonding three semiconductor circuit substrates each including a semiconductor circuit formed thereon and by separating the bonded semiconductor circuit substrates for each chip. That is, the semiconductor memory device 3 according to the first embodiment includes a structure formed by bonding a first semiconductor substrate, a second semiconductor substrate, and a third semiconductor substrate to each other. Each of the first to third semiconductor substrates is, for example, a silicon substrate. Hereinafter, a case where the second semiconductor substrate and the third semiconductor substrate are removed in the process of manufacturing the semiconductor memory device 3 will be described. Depending on the structure of the semiconductor memory device 3, a part of the second semiconductor substrate and a part of the third semiconductor substrate may remain after bonding.

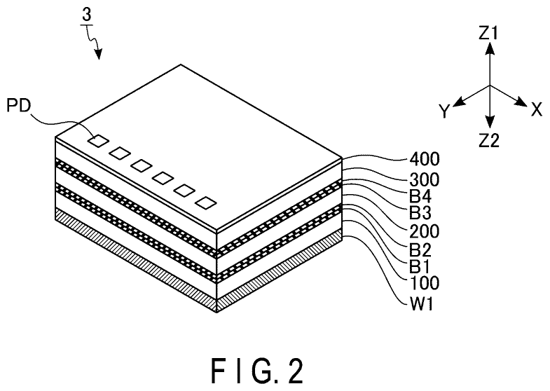

FIG. 2 is a perspective view illustrating an example of an appearance of the semiconductor memory device according to the first embodiment. In FIG. 2, hatching is added in order to enhance the visibility of the drawing, but the hatching is not necessarily related to the material or characteristics of a constituent element to which the hatching is added. As illustrated in FIG. 2, the semiconductor memory device 3 has, for example, a structure in which a first semiconductor substrate W1, a control circuit layer 100, a joint layer B1, a joint layer B2, a first memory layer 200, a joint layer B3, a joint layer B4, a second memory layer 300, and an interconnect layer 400 are stacked in this order.

In the following description, a plane on which the first semiconductor substrate W1 extends is defined as an XY plane. Among the directions in which the stacked structures are stacked, a direction from the first semiconductor substrate W1 toward the interconnect layer 400 is defined as a Z1 direction, and a direction from the interconnect layer 400 toward the first semiconductor substrate W1 is defined as a Z2 direction. The Z1 direction and the Z2 direction are substantially perpendicular to the first semiconductor substrate W1. Note that, in the case of not distinguishing the Z1 direction and the Z2 direction, each of the Z1 direction and the Z2 direction is simply referred to as a Z direction.

The control circuit layer 100 includes a control circuit formed using the first semiconductor substrate W1. The first semiconductor substrate W1 includes an impurity diffusion area or the like in accordance with the design of the control circuit. The control circuit layer 100 includes, for example, the input/output circuit 11, the logic controller 12, the register 13, the sequencer 14, the driver module 15, the row decoder module 16, and the sense amplifier module 17.

The joint layer B1 is formed using the first semiconductor substrate W1. The joint layer B1 includes a plurality of joint pads electrically coupled to a control circuit provided in the control circuit layer 100 and forming a part of a semiconductor circuit.

The joint layer B2 is formed using a second semiconductor substrate (not illustrated). The joint layer B2 includes a plurality of joint pads electrically coupled to the memory cell array 10-1 provided in the first memory layer 200 and forming a part of the semiconductor circuit, and a plurality of joint pads electrically coupled to an interconnect for coupling the memory cell array 10-2 provided in the second memory layer 300 and the control circuit provided in the control circuit layer 100 and forming a part of the semiconductor circuit.

The first memory layer 200 includes the memory cell array 10-1 formed using a second semiconductor substrate (not illustrated).

The joint layer B3 is formed after the second semiconductor substrate is removed. The joint layer B3 includes a plurality of joint pads that are electrically coupled to the plurality of joint pads provided in the joint layer B2 and form a part of the semiconductor circuit.

The joint layer B4 is formed using a third semiconductor substrate (not illustrated), and the joint layer B4 includes a plurality of joint pads electrically coupled to the memory cell array 10-2 provided in the second memory layer 300 and forming a part of the semiconductor circuit.

The second memory layer 300 includes the memory cell array 10-2 formed using the third semiconductor substrate (not illustrated).

The interconnect layer 400 is formed after the first to third semiconductor substrates are bonded together. The interconnect layer 400 includes an interconnect coupled to a semiconductor circuit provided in the second memory layer 300 and a plurality of pads PD. The plurality of pads PD are exposed on the surface of the semiconductor memory device 3. The plurality of pads PD are used for coupling between the semiconductor memory device 3 and the memory controller 2 or the like.

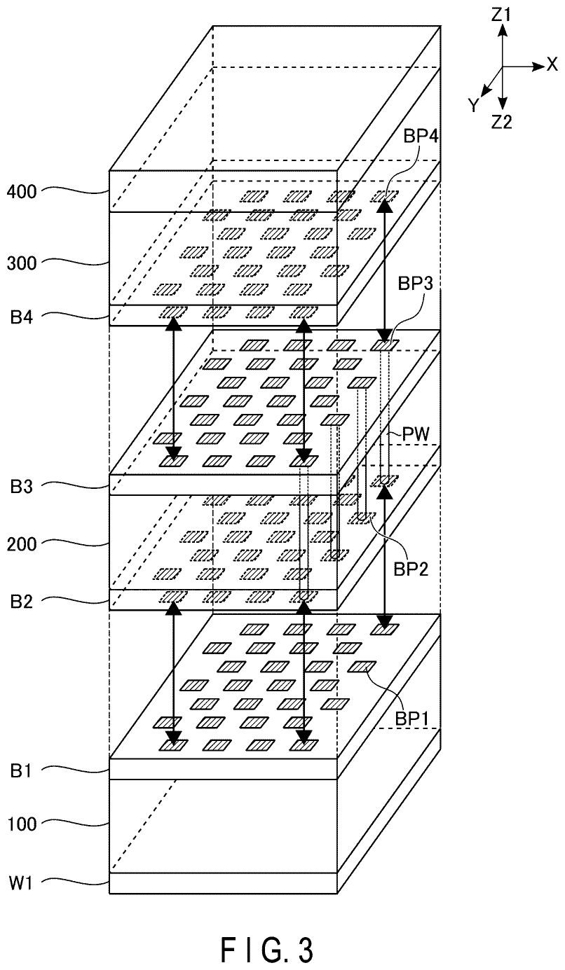

FIG. 3 is a perspective view illustrating an overview of a bonding structure of the semiconductor memory device according to the first embodiment. The bonding of the first to third semiconductor substrates will be described with reference to FIG. 3. As illustrated in FIG. 3, the semiconductor memory device 3 further includes a plurality of joint pads BP1, BP2, BP3, and BP4 and a plurality of interconnects PW.

As illustrated in FIG. 3, a plurality of joint pads BP1 included in the joint layer B1 and a plurality of joint pads BP2 included in the joint layer B2 are coupled to each other. As a result, the control circuit provided in the control circuit layer 100 and the memory cell array 10-1 provided in the first memory layer 200 are electrically coupled to each other via the joint pads BP1 and BP2. In addition, the control circuit provided in the control circuit layer 100 and the interconnect PW for coupling the control circuit and the memory cell array 10-2 provided by passing through the memory cell array 10-1 in the Z direction in the first memory layer 200 are electrically coupled to each other via the joint pads BP1 and BP2. A portion between the joint layers B1 and B2 corresponds to a boundary portion between a layer formed using the first semiconductor substrate W1 and a layer formed using the second semiconductor substrate (not illustrated).

A plurality of joint pads BP3 included in the joint layer B3 and a plurality of joint pads BP4 included in the joint layer B4 are coupled to each other. As a result, the interconnect PW provided in the first memory layer 200 and the memory cell array 10-2 provided in the second memory layer 300 are electrically coupled to each other via the joint pads BP3 and BP4. That is, the control circuit provided in the control circuit layer 100 and the memory cell array 10-2 provided in the second memory layer 300 are electrically coupled to each other via the joint pads BP1, BP2, BP3, and BP4 and the interconnect PW. A portion between the joint layers B3 and B4 corresponds to a boundary portion between a layer formed using the second semiconductor substrate (not illustrated) and a layer formed using the third semiconductor substrate (not illustrated).

### 1.1.4 Circuit Configuration of Memory Cell Array

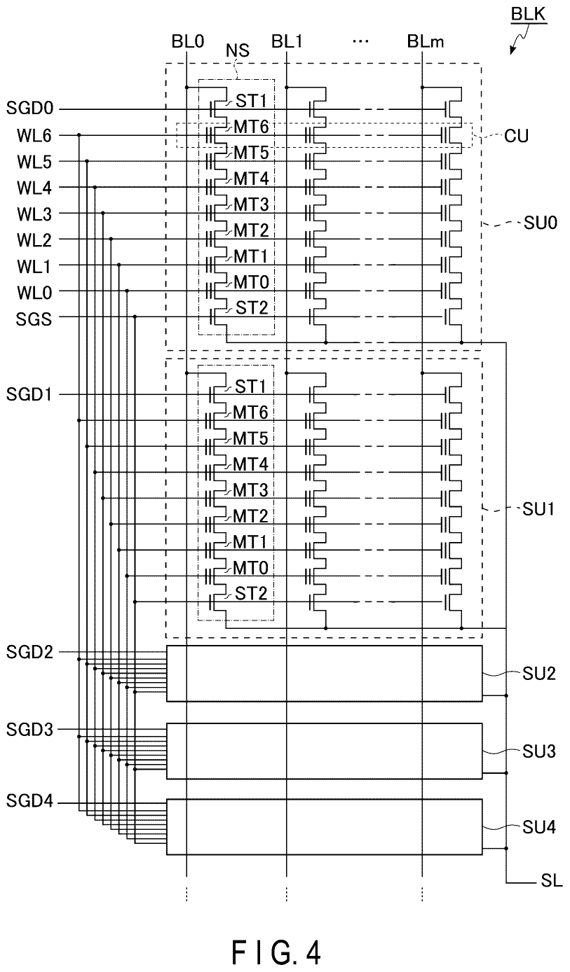

Hereinafter, an example of a circuit configuration of the memory cell array 10 included in the semiconductor memory device 3 according to the first embodiment will be described. FIG. 4 is a circuit diagram illustrating an example of a circuit configuration of the memory cell array included in the semiconductor memory device according to the first embodiment. FIG. 4 illustrates a circuit configuration in one block BLK. The block BLK includes, for example, five string units SU0 to SU4.

Each string unit SU includes a plurality of NAND strings NS respectively associated with the bit lines BL0 to BLm (m is an integer of 1 or more). Each NAND string NS includes, for example, seven memory cell transistors MT0 to MT6 and select transistors ST1 and ST2. Each memory cell transistor MT includes a control gate and a charge storage film and memorizes data in a non-volatile manner based on the amount of charges in the charge storage film. Each of the select transistors ST1 and ST2 is used to select the string unit SU during various operations.

In each NAND string NS, the memory cell transistors MT0 to MT6 are coupled in series in this order. The drain of the select transistor ST1 is coupled to the associated bit line BL, and the source of the select transistor ST1 is coupled to the drain of the memory cell transistor MT6. The drain of the select transistor ST2 is coupled to the source of the memory cell transistor MT0, and the source of the select transistor ST2 is coupled to a source line SL.

Control gates of the memory cell transistors MT0 to MT6 in the same block BLK are coupled to word lines WL0 to WL6, respectively. Gates of the select transistors ST1 in the string units SU0 to SU4 are coupled to select gate lines SGD0 to SGD4, respectively. Gates of the select transistors ST2 in the same block BLK are coupled to a select gate line SGS.

Different column addresses CA are allocated to the bit lines BL0 to BLm. Each bit line BL is shared by the NAND string NS to which the same column address CA is allocated among the plurality of blocks BLK. Each of the word lines WL0 to WL6 is provided for each block BLK. The source line SL is shared among the plurality of blocks BLK, for example.

An aggregate of a plurality of the memory cell transistors MT coupled to the common word line WL in one string unit SU is referred to as, for example, a cell unit CU. For example, the memory capacity of the cell unit CU including the memory cell transistors MT each memorizing 1-bit data is defined as “one-page data”. The cell unit CU may have a memory capacity of two-page data or more in accordance with the number of bits of data memorized in the memory cell transistor MT.

Note that the circuit configuration of each memory cell array 10 included in the semiconductor memory device 3 according to the first embodiment is not limited to the above description. For example, the number of the string units SU included in each block BLK can be designed to be any number. The number of the memory cell transistors MT and the select transistors ST1 and ST2 included in each NAND string NS can be designed to be any number.

### 1.1.5 Configuration of Memory Cell Array

Hereinafter, an example of configurations of the plurality of memory cell arrays 10 included in the semiconductor memory device 3 according to the first embodiment will be described. The configurations of the two memory cell arrays 10-1 and 10-2 included in the semiconductor memory device 3 according to the first embodiment are similar. In the following description, an X direction corresponds to the extending direction of the word line WL. A Y direction corresponds to the extending direction of the bit line BL. In the plan view, hatching is added as appropriate in order to enhance the visibility of the drawing. The hatching added to the plan view is not necessarily related to the material or characteristics of the constituent element to which hatching is added. In the sectional view, illustration of the configuration is omitted as appropriate in order to enhance the visibility of the drawing. In the following description, the Z2 direction is defined as an upward direction, and the Z1 direction is defined as a downward direction.

### 1.1.5.1 Overview

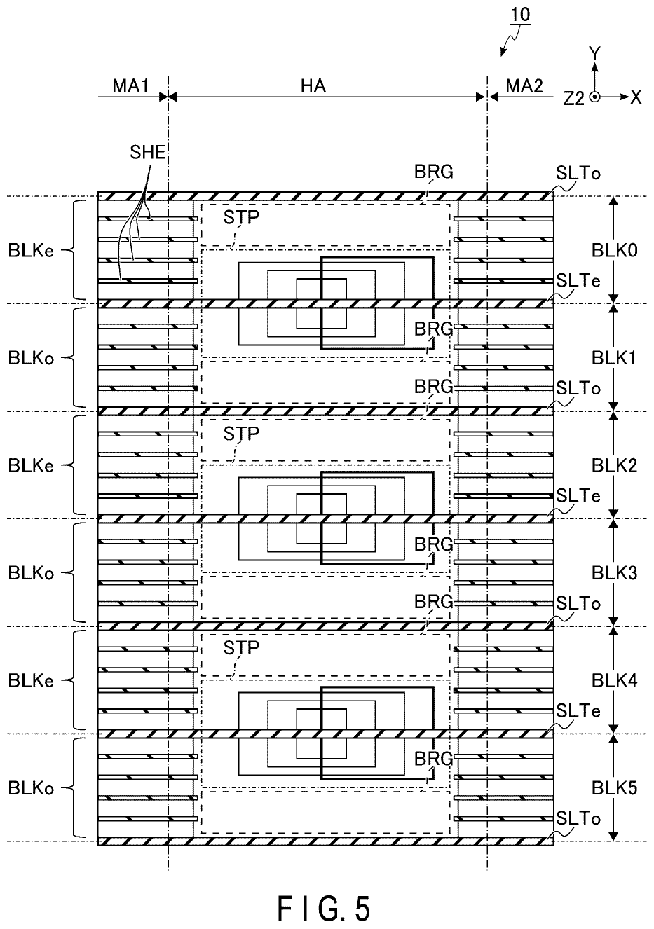

FIG. 5 is a plan view illustrating an example of a planar layout of the memory cell array included in the semiconductor memory device according to the first embodiment. FIG. 5 illustrates areas corresponding to six blocks BLK0 to BLK5. The sequence numbers at the ends for distinguishing the blocks BLK are assigned in ascending order from the upper side of this paper. In each memory cell array 10, for example, the layout illustrated in FIG. 5 is repeatedly disposed in the Y direction. In addition, a block BLK having an even sequence number at the end for distinguishing the block BLK is referred to as “BLKe”, and a block having an odd sequence number is referred to as “BLKo”.

Each memory cell array 10 includes a stacked interconnect formed by stacking a plurality of interconnect layers (i.e., the word lines WL0 to WL6 and the select gate lines SGS and SGD) apart from each other in the Z direction. As illustrated in FIG. 5, each memory cell array 10 includes a plurality of members SLT and a plurality of members SHE. The planar layout of the memory cell array 10 is divided into, for example, memory areas MA1 and MA2 and a hookup area HA in the X direction. The hookup area HA is provided between the memory area MA1 and the memory area MA2.

The memory areas MA1 and MA2 are areas that include a plurality of the NAND strings NS and are used for memorizing data. The hookup area HA is an area used for coupling between the stacked interconnect and the row decoder module 16.

The plurality of members SLT each extend along the X direction and are arranged in the Y direction. Each member SLT crosses the memory areas MA1 and MA2 and the hookup area HA in the X direction in the boundary area between the adjacent blocks BLK. In other words, each of the areas partitioned by the member SLT corresponds to one block BLK in each memory cell array 10. Each member SLT has, for example, a structure in which a plate-shaped contact is embedded inside an insulator. Each member SLT divides the stacked interconnect adjacent to each other with the member SLT interposed therebetween.

As illustrated in FIG. 5, in the present embodiment, among the plurality of members SLT arranged in the Y direction, the members SLT disposed in odd-numbered positions are referred to as “SLTo”, and the members SLT disposed in even-numbered positions are referred to as “SLTe”. In each memory cell array 10, a plurality of sets of the members SLTo and SLTe are alternately arranged in the Y direction.

The hookup area HA includes a stepped area STP and a bridge area BRG. The stepped area STP is provided across the two blocks BLK so as to straddle the member SLTe. The bridge area BRG is provided between the stepped area STP and the member SLTo in each block BLK. That is, in each block BLK, one stepped area STP and one bridge area BRG are provided side by side in the Y direction.

The plurality of members SHE are disposed in each of the memory areas MA1 and MA2. The plurality of members SHE corresponding to the memory area MA1 are each provided to cross the memory area MA1 in the X direction and are arranged in the Y direction. The plurality of members SHE corresponding to the memory area MA2 are each provided to cross the memory area MA2 in the X direction and are arranged in the Y direction. An end portion on the right side of this paper of each member SHE corresponding to the memory area MA1 and an end portion on the left side of this paper of each member SHE corresponding to the memory area MA2 are included in the hookup area HA. For example, in each of the memory areas MA1 and MA2, four members SHE are disposed between the members SLT adjacent in the Y direction. A combination of each of the areas partitioned by the members SLT and SHE in the memory area MA1 and each of the areas partitioned by the members SLT and SHE in the memory area MA2 corresponds to one string unit SU in the memory cell array 10. Each member SHE has, for example, a structure filled with an insulator. Each member SHE divides the adjacent select gate lines SGD with the member SHE interposed therebetween.

Note that the planar layout of the plurality of memory cell arrays 10 included in the semiconductor memory device 3 according to the first embodiment is not limited to the layout described above. For example, the number of the members SHE disposed between the adjacent members SLT can be designed to be any number. The number of the string units SU formed between the adjacent members SLT can be changed based on the number of the members SHE disposed between the adjacent members SLT.

In the semiconductor memory device 3 according to the first embodiment, as illustrated in FIGS. 2 and 3, the memory cell array 10-1 provided in the first memory layer 200 and the memory cell array 10-2 provided in the second memory layer 300 are bonded via the joint layers B3 and B4. Hereinafter, an overview of the bonding structure will be described.

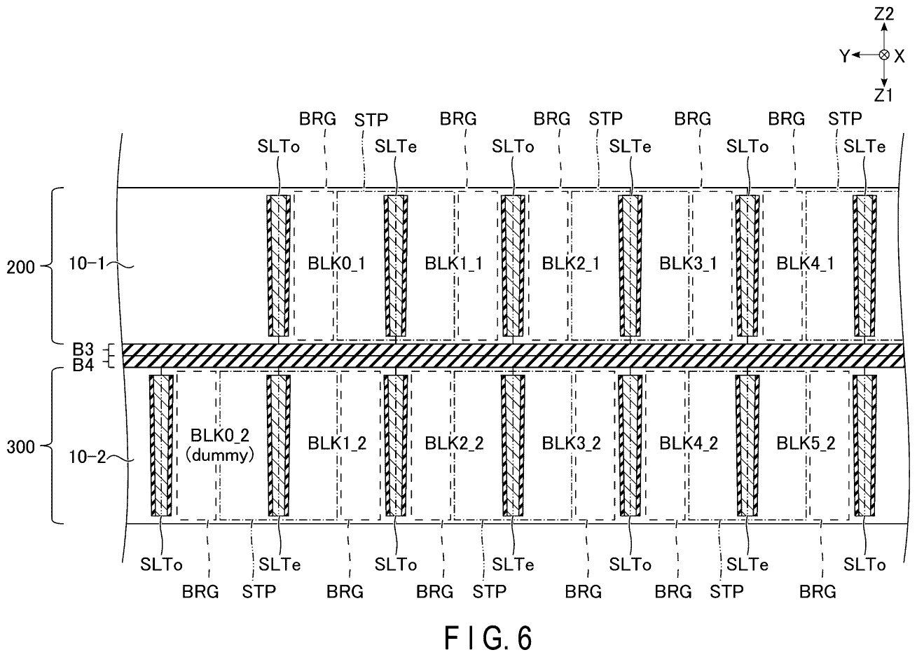

FIG. 6 is a schematic sectional view schematically illustrating an example of a sectional structure of a first memory layer and a second memory layer that are bonded together, which are included in the semiconductor memory device according to the first embodiment. FIG. 6 illustrates the first memory layer 200 and the second memory layer 300, and the joint layers B3 and B4. As illustrated in FIG. 6, the memory cell array 10-1 of the first memory layer 200 and the memory cell array 10-2 of the second memory layer 300 are bonded to each other in the Z direction while being shifted in the Y direction by one block BLK via the joint layers B3 and B4.

Specifically, a block BLK(i−1)_1 of the memory cell array 10-1 is provided above a block BLKi_2 of the memory cell array 10-2 (i is an integer satisfying 1≤i≤n). That is, an odd-numbered block BLKo_1 of the memory cell array 10-1 is provided above an even-numbered block BLKe_2 of the memory cell array 10-2. An even-numbered block BLKe_1 of the memory cell array 10-1 is provided above an odd-numbered block BLKo_2 of the memory cell array 10-2.

As illustrated in FIG. 6, the block BLK in the memory cell array 10-1 is not provided above the block BLK0_2 of the memory cell array 10-2. Although not illustrated, the block BLK in the memory cell array 10-2 is not provided below the block BLKn_1 (the last block BLK arranged in the Y direction) of the memory cell array 10-1. The block BLK0_2 of the memory cell array 10-2 and the block BLKn_1 of the memory cell array 10-1 are dummy blocks (dummy). The word line WL and the select gate lines SGD and SGS formed in the dummy block are not coupled to the row decoder module 16. Therefore, a memory pillar MP formed in the dummy block does not memorize data.

In the two bonded memory cell arrays 10-1 and 10-2, the members SLT included in each memory cell array 10 are provided at positions overlapping in the Z direction approximately. Specifically, the member SLTe of the memory cell array 10-1 is provided above the member SLTo of the memory cell array 10-2. The member SLTo of the memory cell array 10-1 is provided above the member SLTe of the memory cell array 10-2. That is, the members SLTo and SLTe are provided so as to overlap each other one by one in the Z direction. One of the members SLT adjacent to the dummy block that is not adjacent to the other block BLK does not overlap the other member SLT in the Z direction.

As illustrated in FIG. 6, the stepped area STP of the memory cell array 10-1 and the stepped area STP of the memory cell array 10-2 are provided side by side in the Y direction and at different positions in the Z direction in plan view. Specifically, the bridge area BRG of the memory cell array 10-2 is provided below the stepped area STP of the memory cell array 10-1. The bridge area BRG of the memory cell array 10-1 is provided above the stepped area STP of the memory cell array 10-2. That is, in the vicinity of the member SLT in an arbitrary block BLK excluding the dummy block, in a case where the stepped area STP is provided and a stepwise structure is formed in one of the memory cell arrays 10-1 and 10-2 at positions overlapping each other in the Z direction, a structure in which the bridge area BRG is provided and the plurality of interconnect layers 22 and 23 are stacked is formed in the other of the memory cell arrays 10-1 and 10-2.

A detailed bonding structure of the memory cell arrays 10-1 and 10-2 will be described later.

### 1.1.5.2 Memory Area

In this section and the following section, a structure common to the memory cell arrays 10-1 and 10-2 will be described. The second semiconductor substrate and the third semiconductor substrate used for manufacturing the memory cell arrays 10-1 and 10-2 are collectively referred to as a semiconductor substrate W.

### (Planar Layout)

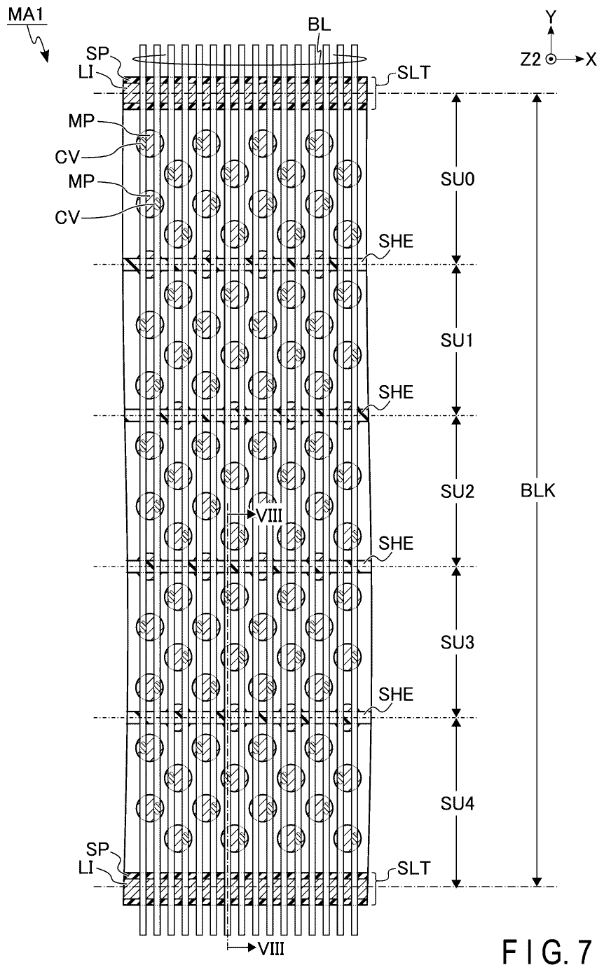

FIG. 7 is a plan view illustrating an example of a planar layout in the memory area of the memory cell array included in the semiconductor memory device according to the first embodiment. Note that FIG. 7 representatively illustrates a structure in one block BLK in the memory area MA1, but the structure of the memory area MA2 is similar to the structure of the memory area MA1. As illustrated in FIG. 7, in the memory areas MA1 and MA2, the memory cell array 10 includes a plurality of memory pillars MP, a plurality of contacts CV, and a plurality of bit lines BL. Each member SLT includes a contact LI and a spacer SP.

Each memory pillar MP functions as, for example, one NAND string NS. The plurality of memory pillars MP are disposed in such a staggered manner as to have, for example, 24 rows in the Y direction in an area between two adjacent members SLT. In the example illustrated in FIG. 7, one member SHE overlaps each memory pillar MP of the fifth row, the tenth row, the 15th row, and the 20th row as counted from the upper side of this paper.

The plurality of bit lines BL each extend in the Y direction and are arranged in the X direction. Each bit line BL is disposed so as to overlap at least one memory pillar MP for each string unit SU. In the example illustrated in FIG. 7, two bit lines BL are disposed so as to overlap one memory pillar MP. In the case where the plurality of bit lines BL overlap the memory pillar MP, one bit line BL among the plurality of bit lines BL and the corresponding one memory pillar MP are electrically coupled via the contact CV. Note that, in the case where only one bit line BL overlaps the memory pillar MP, the bit line BL and the corresponding one memory pillar MP are electrically coupled via the contact CV.

For example, the contact CV between the memory pillar MP in contact with the member SHE and the corresponding bit line BL is omitted. In other words, the contact CV between the memory pillar MP in contact with the two different select gate lines SGD and the bit line BL is omitted. Neither the number nor arrangement of the memory pillars MP, the members SHE, or the like between the adjacent members SLT is limited to the configuration illustrated in FIG. 7 and these can be suitably changed. For example, the number of the bit lines BL overlapping each memory pillar MP can be designed to be any number.

The contact LI is a conductor extending in a XZ plane. The lower surface of the contact LI is in contact with the source line SL (not illustrated). The spacer SP is an insulator provided on a side surface of the contact LI. In other words, the spacer SP is provided in contact with the contact LI so as to sandwich the contact LI in the Y direction.

### (Sectional Structure)

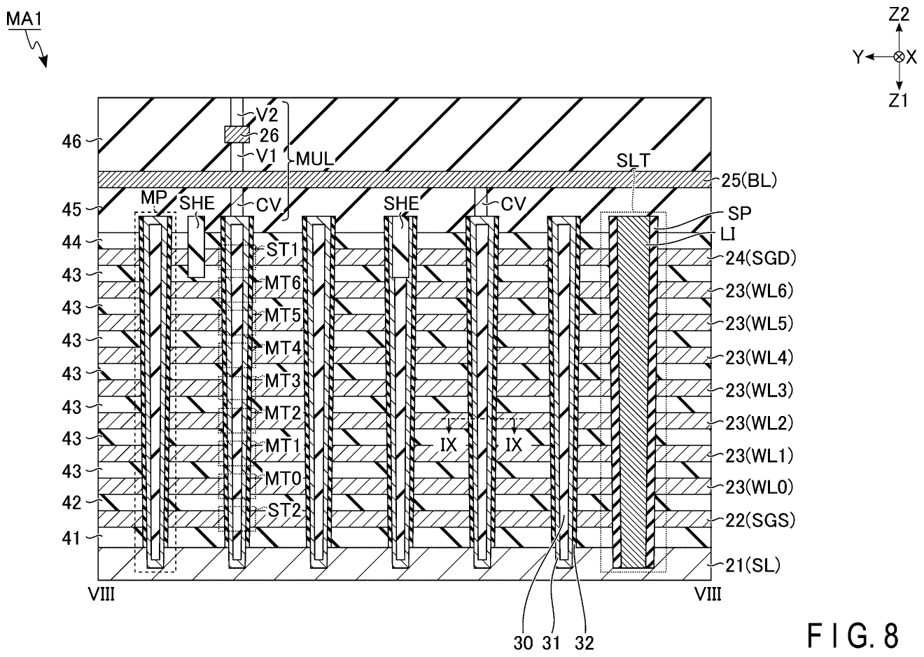

FIG. 8 is a sectional view taken along line VIII-VIII in FIG. 7, illustrating an example of a sectional structure in the memory area of the memory cell array included in the semiconductor memory device according to the first embodiment. As illustrated in FIG. 8, the memory cell array 10 further includes interconnect layers 21 to 26, insulating layers 41 to 46, and contacts CV, V1, and V2.

The insulating layer 41, the interconnect layer 22, and the insulating layer 42 are stacked in this order above the semiconductor substrate W (not illustrated). The interconnect layer 22 is formed in, for example, a plate shape extending along the X direction on the XY plane. The interconnect layer 22 is used as the select gate line SGS. The interconnect layer 22 contains, for example, tungsten (W) or molybdenum (Mo).

A plurality of interconnect layers 23 and a plurality of insulating layers 43 are alternately stacked above the insulating layer 42. Each interconnect layer 23 is formed in, for example, a plate shape extending along the X direction on the XY plane. The interconnect layers 23 are used as the word lines WL0 to WL6 in order from the interconnect layer 22 side. The plurality of interconnect layers 23 contain, for example, tungsten or molybdenum.

The interconnect layer 24, the insulating layer 44, and the insulating layer 45 are stacked in this order above the uppermost insulating layer 43. The interconnect layer 24 is formed in, for example, a plate shape extending along the X direction on the XY plane. The interconnect layer 24 is used as the select gate line SGD. The interconnect layer 24 contains, for example, tungsten or molybdenum.

A plurality of interconnect layers 25 and an insulating layer 46 are stacked in this order above the insulating layer 45. Each interconnect layer 25 is formed in, for example, a line shape extending along the Y direction. Each interconnect layer 25 is used as the bit line BL. In an area (not illustrated), the plurality of interconnect layers 25 are arranged along the X direction. The plurality of interconnect layers 25 contain, for example, copper.

A plurality of interconnect layers 26 are provided above the plurality of interconnect layers 25 and inside the insulating layer 46. Each interconnect layer 26 is an interconnect that relays coupling between the corresponding bit line BL (that is, the interconnect layer 25) and the sense amplifier module 17. The plurality of interconnect layers 26 contain, for example, copper.

Although not illustrated, a joint layer is formed above the insulating layer 46. For example, the joint layer B2 is provided above the insulating layer 46 in the memory cell array 10-1. The joint layer B4 is provided above the insulating layer 46 in the memory cell array 10-2.

Thereafter, the semiconductor substrate W is removed, and the interconnect layer 21 is provided. The interconnect layer 21 is formed in, for example, a plate shape extending along the X direction on the XY plane. The interconnect layer 21 is used as the source line SL. The interconnect layer 21 includes, for example, polysilicon doped with impurities such as phosphorus.

Although not illustrated, an interconnect layer or a joint layer is provided below the interconnect layer 21. For example, the joint layer B3 is provided below the interconnect layer 21 in the memory cell array 10-1. The interconnect layer 400 is provided below the interconnect layer 21 in the memory cell array 10-2.

Each memory pillar MP is provided extending along the Z direction. The memory pillars MP penetrate the interconnect layers 22 to 24 and the insulating layers 41 to 44. Each memory pillar MP has, for example, a sectional area (XY sectional area) along the XY plane increasing from the lower side to the upper side. In addition, each memory pillar MP includes, for example, a core film 30, a semiconductor film 31, and a stacked film 32. The core film 30 is provided extending along the Z direction. For example, an upper end of the core film 30 is positioned in the insulating layer 45, and a lower end of the core film 30 is positioned in the interconnect layer 21. The core film 30 includes, for example, an insulator such as silicon oxide (SiO). The semiconductor film 31 covers the periphery of the core film 30, for example. On the lower end and the side surface near the lower end of the memory pillar MP, a part of the semiconductor film 31 is in contact with the interconnect layer 21. The semiconductor film 31 contains, for example, silicon. The stacked film 32 covers the side surface of the semiconductor film 31 except for a portion where the semiconductor film 31 and the interconnect layer 21 are in contact with each other.

In the structure of the memory pillar MP illustrated in FIG. 8, a portion where the memory pillar MP and the interconnect layer 22 intersect each other functions as the select transistor ST2. Portions where the memory pillars MP and each interconnect layer 23 intersect each other function as the memory cell transistors MT0 to MT6, respectively. A portion where the memory pillar MP and the interconnect layer 24 intersect each other functions as the select transistor ST1.

The columnar contact CV is provided on the upper surface of the semiconductor film 31 in the memory pillar MP. In the area illustrated in FIG. 8, two contacts CV corresponding to two memory pillars MP among six memory pillars MP are displayed. To the memory pillar MP that does not overlap the member SHE and is not coupled to the contact CV in this area, another contact CV is coupled in an area (not illustrated).

One interconnect layer 25, that is, one bit line BL is in contact with the upper surface of each contact CV. One contact CV is coupled to one interconnect layer 25 in each of the spaces partitioned by the members SLT and SHE. That is, for example, one memory pillar MP in each area between the adjacent members SLT and SHE and one memory pillar MP in each area between the two adjacent members SHE are electrically coupled to each interconnect layer 25.

The contacts V1 and V2 are provided inside the insulating layer 46. The contact V1 is in contact with one interconnect layer 25 on the lower surface and in contact with one interconnect layer 26 on the upper surface to couple the two. The lower surface of the contact V2 is in contact with one interconnect layer 26, and the upper surface is exposed from the insulating layer 46. The contact V2 couples the joint pad included in the joint layer provided on the upper surface side of the memory cell array 10 and the interconnect layer 26. The interconnect layers 25 and 26 and the contacts CV, V1, and V2 are collectively referred to as upper layer interconnects MUL.

The member SLT is formed so as to extend along the XZ plane, for example. The members SLT penetrate the interconnect layers 22 to 24 and the insulating layers 41 to 44. Each of the members SLT has, for example, a width in the Y direction increasing from the lower side to the upper side.

In the member SLT, the contact LI is provided so as to extend along the XZ plane, and the spacer SP is provided between the contact LI and the interconnect layers 22 to 24. The upper end of the contact LI is positioned, for example, in the insulating layer 45. The lower end of the contact LI is in contact with, for example, the interconnect layer 21. Note that the contact LI may be omitted depending on the structure of the memory cell array 10.

The member SHE is formed in, for example, a plate shape extending along the XZ plane and divides the interconnect layer 24 and the insulating layer 44. The upper end of the member SHE is positioned in the insulating layer 45. The lower end of the member SHE is positioned in the uppermost insulating layer 43, for example. The member SHE includes, for example, an insulator such as silicon oxide. Note that the upper end of the member SHE and the upper end of the member SLT may be aligned or may not be aligned. In addition, the upper end of the member SHE and the upper end of the memory pillar MP may be aligned or may not be aligned.

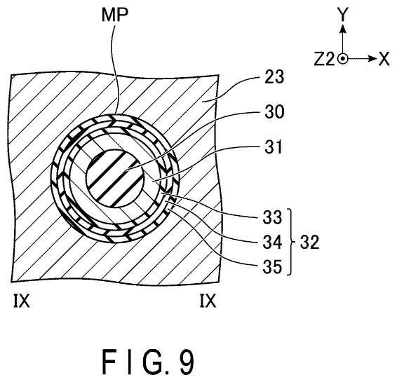

FIG. 9 is a sectional view taken along line IX-IX in FIG. 8, illustrating an example of a sectional structure of the memory pillar included in the semiconductor memory device according to the first embodiment. More specifically, FIG. 9 illustrates a sectional structure of the memory pillar MP in a layer being parallel to the surface of the semiconductor substrate W (not illustrated) and including the interconnect layer 23. As illustrated in FIG. 9, the stacked film 32 includes, for example, a tunnel insulating film 33, a charge storage film 34, and a block insulating film 35.

In the section including the interconnect layer 23, the core film 30 is provided, for example, at the central portion of the memory pillar MP. The semiconductor film 31 surrounds the side surface of the core film 30. The tunnel insulating film 33 surrounds the side surface of the semiconductor film 31. The charge storage film 34 surrounds the side surface of the tunnel insulating film 33. The block insulating film 35 surrounds the side surface of the charge storage film 34. The interconnect layer 23 surrounds the side surface of the block insulating film 35.

The semiconductor film 31 is used as a channel (current path) of the memory cell transistors MT0 to MT6 and the select transistors ST1 and ST2. Each of the tunnel insulating film 33 and the block insulating film 35 contains, for example, silicon oxide. The charge storage film 34 has a function of storing charges and contains, for example, silicon nitride (SiN). With this structure, each memory pillar MP can function as, for example, one NAND string NS.

### 1.1.5.3 Hookup Area

### (Planar Layout)

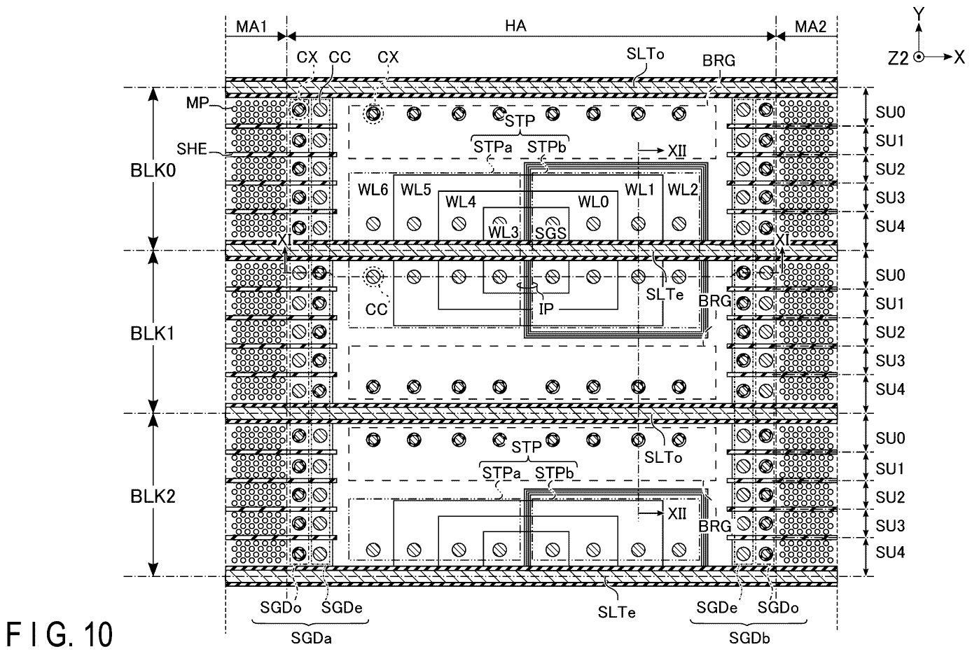

FIG. 10 is a plan view illustrating an example of a planar layout in the hookup area of the memory cell array included in the semiconductor memory device according to the first embodiment. FIG. 10 illustrates the hookup area HA and a part of the memory areas MA1 and MA2 near the hookup area HA. The areas illustrated in FIG. 10 correspond to the blocks BLK0 to BLK2. Note that, in FIG. 10, some insulating layers are omitted for simplification of description.

The memory cell array 10 includes a plurality of contacts CC and CX in the hookup area HA. The contact CC is a contact electrically coupled to one of the interconnect layers 22 to 24 included in the memory cell array 10. The contact CX is a contact that is insulated from the interconnect layers 22 to 24 included in the memory cell array 10 and passes through the stacked interconnect in the Z direction. The plurality of contacts CX provided in the memory cell array 10-1 function as interconnects PW that couple the plurality of contacts CC provided in the memory cell array 10-2 and the row decoder module 16 provided in the control circuit layer 100.

As illustrated in FIG. 10, the select gate line SGD includes a first portion SGDa disposed in the memory area MA1 and the hookup area HA near the memory area MA1, and a second portion SGDb disposed in the memory area MA2 and the hookup area HA near the memory area MA2. In addition, the select gate line SGD has five portions divided in the Y direction by the plurality of members SHE in each of the first portion SGDa and the second portion SGDb. Portions of the select gate line SGD divided in the Y direction by the plurality of members SHE are insulated from each other. That is, in one block BLK, the select gate line SGD is divided into ten pieces.

In the first portion SGDa and the second portion SGDb of the select gate line SGD, the inner contact area and the outer contact area are provided side by side in the X direction. The inner contact area is provided on the hookup area HA side, and the outer contact area is provided on the adjacent memory area MA1 or MA2 side. The inner contact area is distinguished by adding “e” to the end, and the outer contact area is distinguished by adding “o” to the end.

For each of the 10 divided select gate lines SGD, one contact CC and one contact CX are provided in each of the inner contact area SGDe and the outer contact area SGDo. Specifically, for example, in the select gate line SGD in the even-numbered block BLKe, the contact CC is provided in the inner contact area SGDe, and the contact CX is provided in the outer contact area SGDo. In the select gate line SGD in the odd-numbered block BLKo, the contact CX is provided in the inner contact area SGDe, and the contact CC is provided in the outer contact area SGDo. In the select gate line SGD in the even-numbered block BLKe, the contact CX may be provided in the inner contact area SGDe, and the contact CC may be provided in the outer contact area SGDo. In the select gate line SGD in the odd-numbered block BLKo, the contact CC may be provided in the inner contact area SGDe, and the contact CX may be provided in the outer contact area SGDo.

The contacts CC provided in the first portion SGDa and the contacts CC provided in the second portion SGDb of the select gate line SGD corresponding to each other are electrically coupled to each other via an upper interconnect layer (not illustrated). The contacts CX provided in the first portion SGDa and the contacts CX provided in the second portion SGDb of the select gate line SGD corresponding to each other are electrically coupled to each other via an upper interconnect layer (not illustrated).

As illustrated in FIG. 10, in the hookup area HA, each interconnect layer 22 to 24 included in the stacked interconnect includes a terrace portion that does not overlap the upper interconnect layer. A shape of terrace portion of the stacked interconnect in the hookup area HA is similar to a step, a terrace, a rimstone, and the like. The contact CC is coupled at the terrace portion of each interconnect layer 22 to 24 included in the stacked interconnect.

A stadium-shaped stepped structure is formed in the stacked interconnect in the stepped area STP. The stadium-shaped stepped structure is a structure in which a terrace portion of an upper interconnect layer is formed so as to surround a terrace portion of a lower interconnect layer from four sides in plan view. In other words, the stadium-shaped stepped structure has a structure recessed stepwise toward the central portion. The stadium-shaped stepped structure is provided so as to straddle the member SLTe and has a symmetrical structure with respect to the member SLTe.

The plurality of interconnect layers 23 include an inclined portion IP in the hookup area HA. The inclined portion IP is an end surface provided in a rectangular shape in plan view and including end portions of a plurality of (four in the example illustrated in FIG. 10) interconnect layers 23 continuously stacked. A part of the inclined portion IP is provided to cross the stepped area STP in the Y direction. In the inclined portion IP, the end portions of the plurality of interconnect layers 23 continuously stacked are inclined at substantially the same inclination angle in the oblique direction on the XZ plane and the YZ plane and form an inclined surface. The inclined portion IP is provided so as to surround a portion of the stadium-shaped stepped structure on the memory area MA2 side with respect to a central portion along the X direction. The stepped area STP is divided into stepped areas STPa and STPb by the inclined portion IP. The stepped areas STPa and STPb are provided side by side in the X direction.

The stepped area STPa includes an area between the memory area MA1 and the inclined portion IP outside the inclined portion IP of the stepped area STP. In the stepped area STPa, terrace portions of the word lines WL3 to WL6 are provided. Specifically, the terrace portion of the word line WL3 is surrounded by the word line WL4. The terrace portion of the word line WL4 is surrounded by the word line WL5. The terrace portion of the word line WL5 is surrounded by the word line WL6. That is, in the stepped area STPa, the stadium-shaped stepped structure has a stepwise structure in three directions including: a direction ascending from the terrace portion of the word line WL3 toward the memory area MA1 side; and directions ascending from the terrace portion of the word line WL3 respectively toward sides of two bridge areas BRG provided so as to sandwich, in the Y direction, the stepped area STP in which the stadium-shaped stepped structure is provided.

The stepped area STPb is an area including the inside of the inclined portion IP of the stepped area STP. In the stepped area STPb, terrace portions of the select gate line SGS and the word lines WL0 to WL2 are provided. Specifically, the terrace portion of the select gate line SGS is surrounded by the word line WL0. The terrace portion of the word line WL0 is surrounded by the word line WL1. The terrace portion of the word line WL1 is surrounded by the word line WL2. That is, in the stepped area STPb, the stadium-shaped stepped structure has a stepwise structure in three directions including: a direction ascending from the terrace portion of the select gate line SGS toward the memory area MA2 side; and directions ascending from the terrace portion of the select gate line SGS respectively toward sides of two bridge areas BRG provided so as to sandwich, in the Y direction, the stepped area STP in which the stadium-shaped stepped structure is provided.

The plurality of interconnect layers 22 and 23 include a bridge portion in the bridge area BRG. In each of the plurality of interconnect layers 22 and 23, a portion provided in the memory area MA1 and a portion provided in the memory area MA2 are coupled via the bridge portion. That is, in each of the plurality of interconnect layers 22 and 23, a portion provided in the memory area MA1 and a portion provided in the memory area MA2 have equal potentials.

The plurality of contacts CC are further provided corresponding to the terrace portions of the select gate line SGS and the word lines WL0 to WL6, respectively. As illustrated in FIG. 10, the plurality of contacts CC are provided side by side in the X direction in the stepped area STP. For example, the contacts CC provided in the stepped area STP correspond to the word lines WL6, WL5, WL4, and WL3, the select gate line SGS, and the word lines WL0, WL1, and WL2 in this order from the left side of the paper.

The plurality of contacts CX are provided side by side in the X direction in the bridge area BRG. The distances of the plurality of contacts CX provided in the block BLKe from the member SLTo are designed to be substantially equal to the distances of the plurality of contacts CC provided in the block BLKo from the member SLTe. The distances of the plurality of contacts CX provided in the block BLKo from the member SLTo are designed to be substantially equal to the distances of the plurality of contacts CC provided in the block BLKe from the member SLTe.

As illustrated in FIG. 10, the memory cell array 10 according to the first embodiment has a structure in which a plurality of contacts CC and CX are provided so as to be arranged for two rows in total, one row each in the Y direction, in an area sandwiched between the two members SLT in the Y direction. This structure is referred to as a “two-lane contact structure”.

### (Sectional Structure)

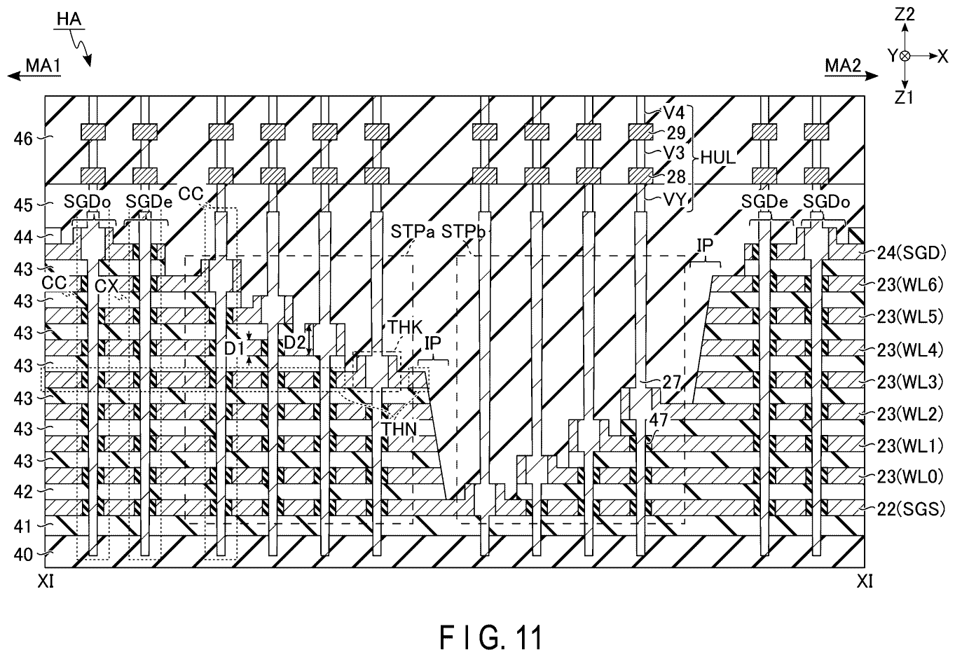

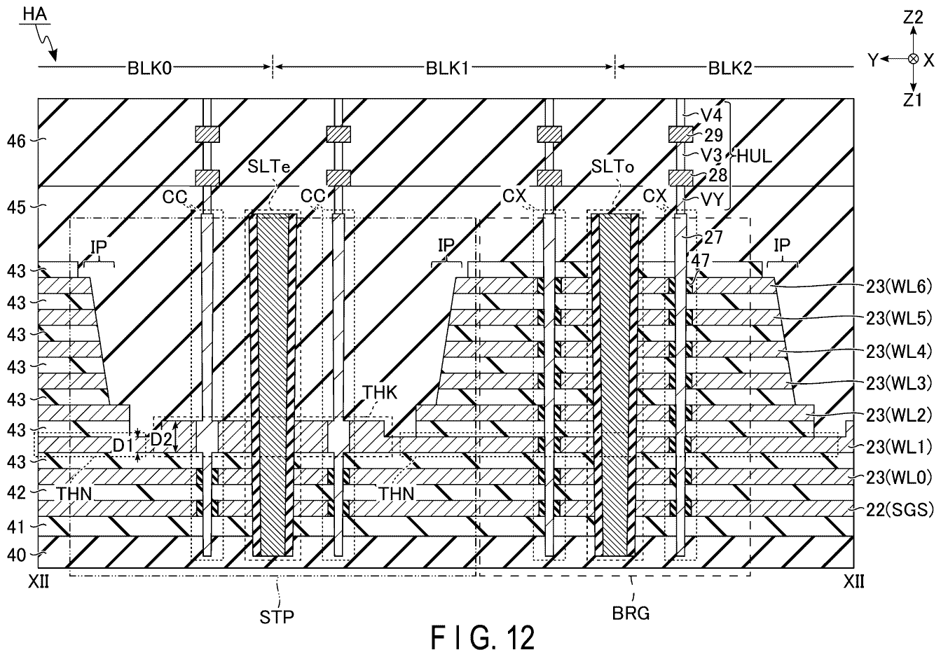

FIG. 11 is a sectional view taken along line XI-XI in FIG. 10, illustrating an example of a sectional structure in the hookup area of the memory cell array included in the semiconductor memory device according to the first embodiment. FIG. 11 illustrates XZ sections of the hookup area HA of the block BLK1 and the plurality of contacts CC and CX. FIG. 11 corresponds to a section including the stepped area STP. FIG. 12 is a sectional view taken along line XII-XII in FIG. 10, illustrating an example of a sectional structure in the hookup area of the memory cell array included in the semiconductor memory device according to the first embodiment. FIG. 12 illustrates YZ sections of a part of the hookup area HA of the blocks BLK0 to BLK2, the plurality of contacts CC and CX, and the plurality of members SLT.

As illustrated in FIG. 11, the stacked interconnect included in the memory cell array 10 has a structure descending from the memory area MA1 toward the memory area MA2, which is a part of the stadium-shaped stepped structure, in the stepped area STPa. The stacked interconnect has a structure ascending from the memory area MA1 toward the memory area MA2, which is a part of the stadium-shaped stepped structure, in the stepped area STPb.

Each of the interconnect layers 22 to 24 includes a thin film portion THN and a thick film portion THK. Each thin film portion THN extends in the X direction and has, for example, a first thickness D1 in the Z direction. The thick film portion THK is provided at each terrace portion in each stepped area STP. Each thick film portion THK has, for example, a second thickness D2 greater than the first thickness D1 in the Z direction. For example, the second thickness D2 in the Z direction of the thick film portion THK is substantially equal to the thickness obtained by adding the first thickness D1 and the thickness in the Z direction of the insulating layers 42 to 44 respectively provided one layer above the interconnect layers 22 to 24. Note that the thick film portion THK may be omitted depending on the configuration of another contact provided corresponding to the contact CC in the contacts CC and CX, and the configuration of such another contact will be described later.

As illustrated in FIG. 11, in the stepped areas STPa and STPb, the plurality of thick film portions THK provided in the respective interconnect layers 22 and 23 are provided side by side in the X direction. Each thick film portion THK is separated in the X direction from the side surface of the thick film portion THK of the interconnect layer 23 or 24 provided one layer above the interconnect layer 22 or 23. That is, the plurality of thick film portions THK provided in one stepped area STP are provided apart from each other in the X direction. In addition, each thick film portion THK is separated from the inclined portion IP provided on the upper side of the thick film portion THK in the X direction.

In the terrace portion of the interconnect layer 24 corresponding to the select gate line SGD, the thick film portion THK is provided in any one of the outer contact area SGDo and the inner contact area SGDe, and the thin film portion THN is provided in the other. Specifically, the terrace portion in the area where the contact CC is provided is thickened. In the example of the block BLK1 (that is, the odd-numbered block BLKo) illustrated in FIG. 11, the thick film portion THK is provided in the outer contact area SGDo. Although not illustrated, in the even-numbered block BLKe, the thick film portion THK is provided in the inner contact area SGDe. The thin film portion THN is provided in an area where the thick film portion THK is not provided.

As illustrated in FIG. 12, each thick film portion THK of the interconnect layers 22 and 23 is provided over two blocks BLK so as to straddle the member SLTe in the Y direction. In other words, each thick film portion THK is in contact with any of the plurality of members SLTe in the Y direction. Although not illustrated, the thick film portion THK of the interconnect layer 24 corresponding to the select gate line SGD is provided, for example, so as to straddle all the members SLT in the Y direction except for the members SLT provided at both ends among the members SLT arranged in the Y direction. In other words, the thick film portion THK of the interconnect layer 24 in each block BLK is in contact with the member SLTo at one end portion in the Y direction and in contact with the member SLTe at the other end portion in the Y direction. Each thick film portion THK of the interconnect layers 22 and 23 is separated in the Y direction from the side surface of the interconnect layer 23 or 24 provided one layer above the interconnect layer 22 or 23.

As illustrated in FIGS. 11 and 12, the memory cell array 10 further includes an insulating layer 40, a plurality of interconnect layers 28 and 29, and a plurality of contacts VY, V3, and V4 in the hookup area HA.

The plurality of contacts CC and CX are provided extending in the Z direction. The contacts CC and CX pass (extend) through, in the Z direction, the interconnect layers 22, 23, and 24 and the insulating layers 41, 42, 43, 44, and 45 provided at the positions where the contacts CC and CX are disposed in plan view. The upper surface of each of the contacts CC and CX is in contact with the corresponding contact VY. The lower surface of each of the contacts CC and CX is provided inside the insulating layer 40. The contacts CC and CX provided extending through the stacked interconnect in the Z direction in this manner are referred to as “through contacts”. Each of the contacts CC and CX has a larger sectional area (XY sectional area) along the XY plane from the lower side toward the upper side, for example.

Each of the plurality of contacts CC and CX includes a conductor 27 and a plurality of insulators 47. The conductor 27 functions as a conductive portion of the contacts CC and CX. The conductor 27 has a shape extending in the Z direction and extends through at least a part of the plurality of interconnect layers 22 to 24 and at least a part of the insulating layers 41 to 45 in the Z direction. The conductor 27 contains, for example, tungsten or molybdenum. The plurality of insulators 47 include, for example, silicon oxide.

The conductor 27 included in each contact CC is coupled to any one of the interconnect layers 22, 23, and 24 provided with the thick film portion THK in the XY plane direction at a portion extending through the thick film portion THK. The interconnect layer 22, 23, or 24 to which the conductor 27 is coupled is the interconnect layer 22, 23, or 24 to which the contact CC corresponds. The conductor 27 included in each contact CX is not electrically coupled to any of the interconnect layers 22, 23, and 24 included in the memory cell array 10. The lower end of the conductor 27 is provided inside the insulating layer 40.

The plurality of insulators 47 included in the contacts CC and CX are provided so as to surround the side surface of the conductor 27 in a portion where the conductor 27 extends through the thin film portion THN in the interconnect layers 22, 23, and 24. The plurality of insulators 47 insulate the conductor 27 and the thin film portions THN of the interconnect layers 22, 23, and 24 through which the conductor 27 extends. That is, each contact CC is coupled to one interconnect layer 22, 23, or 24 of which the thick film portion THK is passed by the contact CC and is insulated from the other interconnect layers 22, 23, and 24 of which the thin film portion THN is passed by the contact CC. Each contact CX is insulated from the interconnect layers 22, 23, and 24 since the thin film portion THN is passed by the contact CX in all of the interconnect layers 22, 23, and 24. Note that the configuration of the contact CC is not limited to the above configuration as long as the contact CC is coupled to the corresponding one interconnect layer 22, 23, or 24 and is insulated from other interconnect layers 22, 23, and 24.

The insulating layer 40 is provided below the insulating layer 41 and is provided in a layer corresponding to the interconnect layer 21 in the memory areas MA1 and MA2. The insulating layer 40 includes, for example, polysilicon. For example, an amorphous silicon layer corresponding to the interconnect layer 21 and the insulating layer 40 is formed, and portions corresponding to the interconnect layer 21 in the memory areas MA1 and MA2 are selectively doped with impurities such as phosphorus and then subjected to heat treatment, thereby forming structures corresponding to the interconnect layer 21 and the insulating layer 40.

A plurality of the interconnect layers 28 are provided above the plurality of contacts CC and CX, respectively. The plurality of interconnect layers 29 are provided above the plurality of interconnect layers 28 and inside the insulating layer 46. The plurality of interconnect layers 28 and 29 are interconnects that relay the coupling between the word line WL and the row decoder module 16. The plurality of interconnect layers 28 and 29 contain, for example, copper. The plurality of interconnect layers 28 are provided, for example, in the same layer as the plurality of interconnect layers 25. The plurality of interconnect layers 29 are provided, for example, in the same layer as the plurality of interconnect layers 26.

The plurality of contacts VY are provided above the plurality of contacts CC and CX and inside the insulating layer 45. Each contact VY is in contact with the conductor 27 of the corresponding contact CC or CX on the lower surface and in contact with the corresponding interconnect layer 28 on the upper surface to couple the two. The plurality of contacts V3 and V4 are provided inside the insulating layer 46. Each contact V3 is in contact with one interconnect layer 28 on the lower surface and in contact with one interconnect layer 29 on the upper surface to couple the two. The lower surface of each contact V4 is in contact with one interconnect layer 29, and the upper surface thereof is exposed from the insulating layer 46 and is coupled to, for example, a joint pad included in a joint layer provided on the upper surface side of the memory cell array 10. The interconnect layers 28 and 29 and the contacts VY, V3, and V4 are referred to as upper layer interconnects HUL.

1.1.6 Bonding Structure between Memory Layers

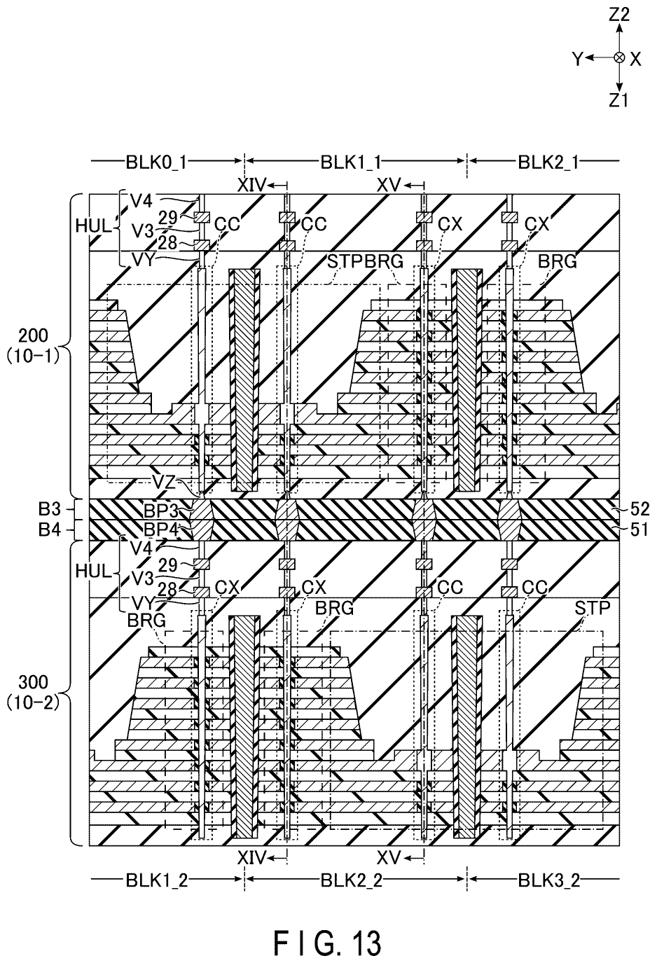

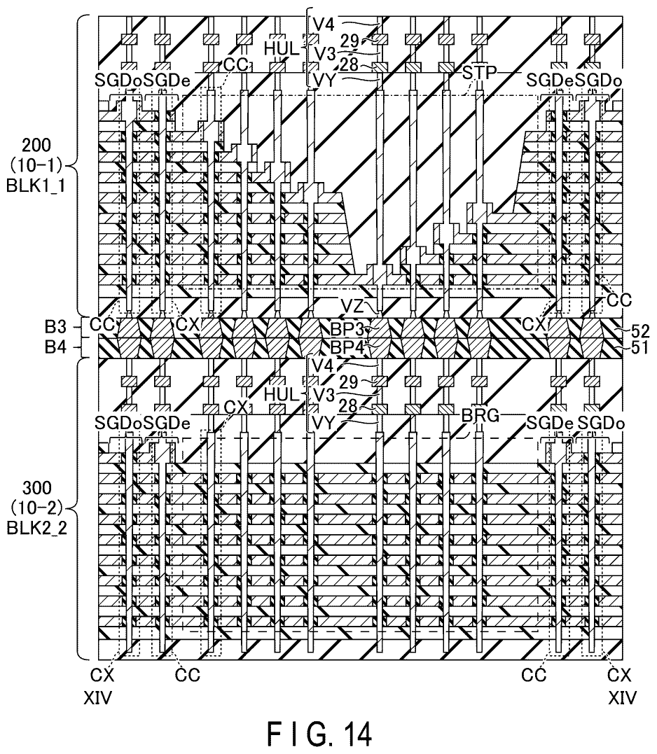

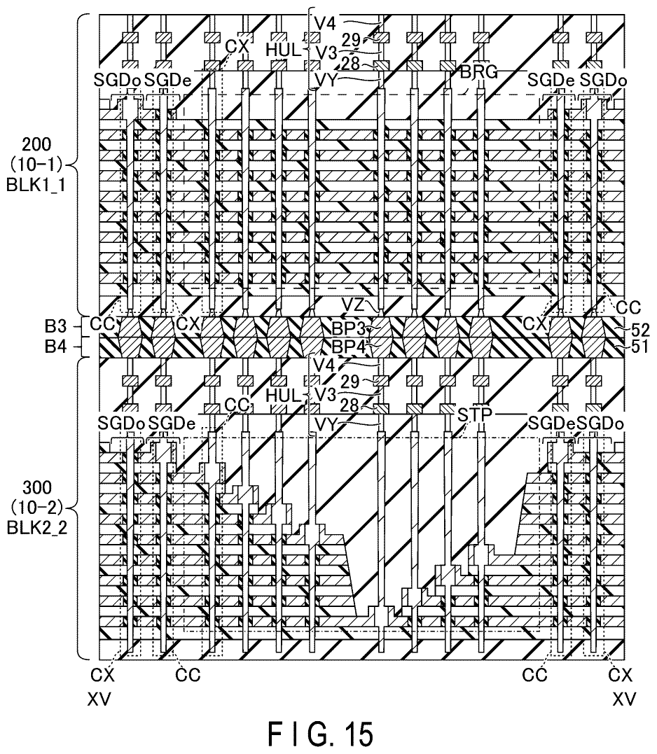

FIGS. 13 to 15 are sectional views illustrating an example of a sectional structure of the first memory layer, the second memory layer, and a joint layer provided between the first memory layer and the second memory layer included in the semiconductor memory device according to the first embodiment. The section of FIG. 13 corresponds to the YZ section illustrated in FIG. 12. In FIG. 13, areas corresponding to the blocks BLK0 to BLK2 in the memory cell array 10-1 and the blocks BLK1 to BLK3 in the memory cell array 10-2 are illustrated. FIGS. 14 and 15 are sectional views taken along lines XIV-XIV and XV-XV in FIG. 13, respectively. FIGS. 14 and 15 illustrate areas corresponding to the block BLK1 of the memory cell array 10-1 and the block BLK2 of the memory cell array 10-2. Similarly to FIG. 11, FIGS. 14 and 15 also illustrate sections of the contacts CC and CX passing through the interconnect layer 24 corresponding to the select gate line SGD in the Z direction.

As illustrated in FIGS. 13 to 15, the joint layer B3 includes an insulating layer 52. The plurality of joint pads BP3 are provided so as to pass through the insulating layer 52 in the Z direction. The joint layer B4 includes an insulating layer 51. The plurality of joint pads BP4 are provided so as to pass through the insulating layer 51 in the Z direction.

The first memory layer 200 further includes a plurality of contacts VZ. The plurality of contacts VZ are provided below the plurality of contacts CC and CX and inside the insulating layer 40 in the memory cell array 10-1. Each contact VZ is in contact with the conductor 27 of the corresponding contact CC or CX at the upper surface, and the lower surface thereof is exposed from the insulating layer 40 and is coupled to, for example, the joint pad BP3 included in the joint layer B3 provided on the lower surface side of the memory cell array 10.

The contacts CC and CX included in the memory cell array 10-1 are coupled to the plurality of joint pads BP3 provided in the joint layer B3 on the lower surface side of the memory cell array 10-1 via the corresponding contacts VZ. The contacts CC and CX included in the memory cell array 10-2 are coupled to the plurality of joint pads BP4 on the upper surface side of the memory cell array 10-2 via the upper layer interconnect HUL. At the boundary between the joint layers B3 and B4, the joint pads BP3 and BP4 are disposed to face each other and are coupled to each other in the Z direction. The contact CX included in the memory cell array 10-1 is coupled to the contact CC included in the memory cell array 10-2 via the joint pads BP3 and BP4, the contact VZ, and the upper layer interconnect HUL provided in the memory cell array 10-2. The contact CX included in the memory cell array 10-2 is coupled to the contact CC included in the memory cell array 10-1 via the joint pads BP3 and BP4, the contact VZ, and the upper layer interconnect HUL provided in the memory cell array 10-2. That is, in a case where the contact CX is formed on one side at a position where the memory cell arrays 10-1 and 10-2 overlap in the Z direction, the contact CC is formed on the other side, and the contacts CC and CX are coupled via the joint pads BP3 and BP4, the contact VZ, and the upper layer interconnect HUL provided in the memory cell array 10-2. The contacts CC, CX, and VZ, the joint pads BP3 and BP4, and the upper layer interconnect HUL provided in each of the memory cell arrays 10-1 and 10-2, which are coupled in the Z direction, can be regarded as one through contact extending through the memory cell arrays 10-1 and 10-2. The through contact is electrically coupled to one of the interconnect layers 22, 23, and 24 included in one of the memory cell arrays 10-1 and 10-2 and is insulated from the other interconnect layers 22, 23, and 24.

In the two bonded memory cell arrays 10, the contact CC provided in one stepped area STP and the contact CX provided in the other bridge area BRG correspond to each other and are provided at positions where the contacts CC and CX approximately overlap each other in the Z direction.

As illustrated in FIGS. 14 and 15, in the terrace portions of the select gate lines SGD provided at the positions overlapping each other in the Z direction of the memory cell arrays 10-1 and 10-2, the positions where the contacts CC corresponding to the respective select gate lines SGD are provided are shifted in the X direction and do not overlap each other in the Z direction. In the sections illustrated in FIGS. 14 and 15, since the memory cell array 10-1 corresponds to the block BLK1, for example, the contact CC is provided in the outer contact area SGDo, and the contact CX is provided in the inner contact area SGDe. On the other hand, since the memory cell array 10-2 corresponds to the block BLK2, the contact CX is provided in the outer contact area SGDo, and the contact CC is provided in the inner contact area SGDe. The contacts CC and CX provided at positions overlapping each other in the Z direction are coupled to each other via the joint pads BP3 and BP4, the contact VZ, and the upper layer interconnect HUL provided in the memory cell array 10-2. Therefore, the contacts CC, CX, and VZ, the joint pads BP3 and BP4, and the upper layer interconnect HUL of each of the memory cell arrays 10-1 and 10-2, which are coupled in the Z direction, can be regarded as one through contact. The through contact is coupled to one of the select gate lines SGD of any one of the memory cell arrays 10-1 and 10-2 and is insulated from the other interconnect layers 22, 23, and 24. In this manner, the select gate lines SGD of the memory cell arrays 10-1 and 10-2 are electrically separated from each other.

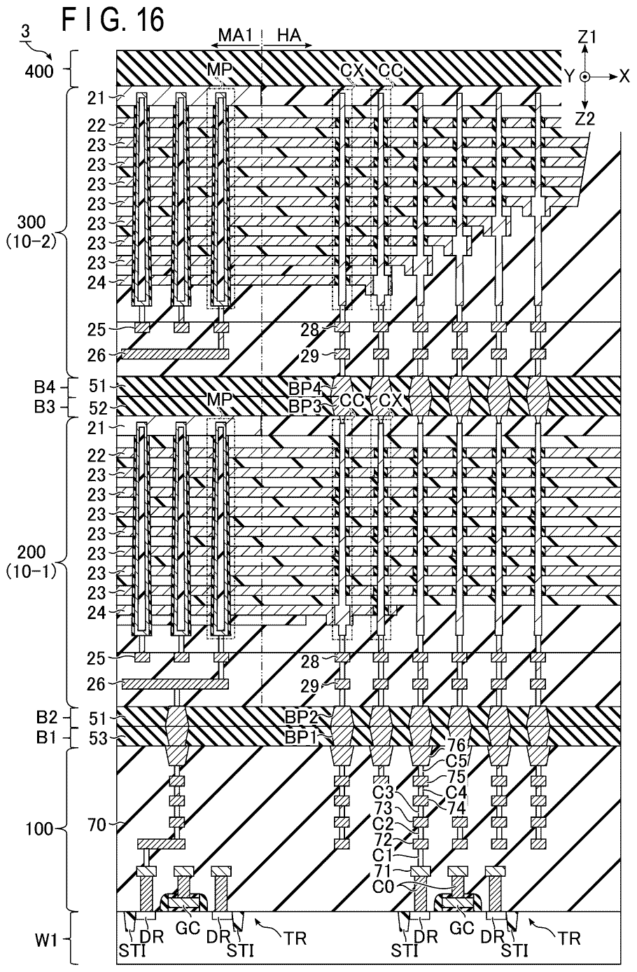

FIG. 16 is a sectional view illustrating an example of a sectional structure of the semiconductor memory device according to the first embodiment. FIG. 16 illustrates a structure in which the control circuit layer 100, the first memory layer 200, the second memory layer 300, and the interconnect layer 400 are bonded to each other. FIG. 16 corresponds to the section illustrated in FIG. 15. In FIG. 16, the Z1 direction is illustrated as being the upper side of the paper. As illustrated in FIG. 16, the control circuit layer 100 is provided with a plurality of transistors TR.

The first semiconductor substrate W1 includes a plurality of insulators STI and a plurality of impurity diffusion areas DR. The plurality of insulators STI are formed in the vicinity of the surface of the first semiconductor substrate W1 in the Z1 direction. In plan view, an active area used for forming the transistor TR is defined in an area surrounded by the insulator STI. The impurity diffusion area DR is formed in the active area, and is formed corresponding to each of a source region and a drain region of the transistor TR. For example, in a case where the transistor TR is an N-type transistor, a P-type well area is provided as the active area, and an N-type impurity diffusion area is provided as the impurity diffusion area DR. In a case where the transistor TR is a P-type transistor, an N-type well area is provided as the active area, and a P-type impurity diffusion area is provided as the impurity diffusion area DR.

An insulating layer 70 is provided on the surface of the first semiconductor substrate W1 in the Z1 direction. In the insulating layer 70, an interconnect layer of the control circuit layer 100 is formed. The control circuit layer 100 includes a plurality of gate electrodes GC, a plurality of contacts C0, C1, C2, C3, C4, and C5, and a plurality of interconnect layers 71, 72, 73, 74, 75, and 76. Each gate electrode GC is a gate portion of the associated transistor TR. Each gate electrode GC is provided between the adjacent impurity diffusion areas DR and at a position overlapping a well area in the Z1 direction with a gate insulating film interposed therebetween. Each contact C0 is provided in contact with the associated impurity diffusion area DR or the gate electrode GC. Each interconnect layer 71 is provided in contact with the associated contact C0. Each contact C1 is provided in contact with the associated interconnect layer 71. Each interconnect layer 72 is provided in contact with the associated contact C1. Each contact C2 is provided in contact with the associated interconnect layer 72. Each interconnect layer 73 is provided in contact with the associated contact C2. Each contact C3 is provided in contact with the associated interconnect layer 73. Each interconnect layer 74 is provided in contact with the associated contact C3. Each contact C4 is provided in contact with the associated interconnect layer 74. Each interconnect layer 75 is provided in contact with the associated contact C4. Each contact C5 is provided in contact with the associated interconnect layer 75. Each interconnect layer 76 is provided in contact with the associated contact C5. A surface of the interconnect layer 76 in the Z1 direction is exposed from the insulating layer 70. The contact C0, the interconnect layer 71, the contact C1, the interconnect layer 72, the contact C2, the interconnect layer 73, the contact C3, the interconnect layer 74, the contact C4, the interconnect layer 75, the contact C5, and the interconnect layer 76 are provided so as to overlap each other in this order in the Z1 direction.

The insulating layer 53 is provided on a surface of the insulating layer 70 in the Z1 direction. The insulating layer 53 is provided with a plurality of joint pads BP1. The plurality of joint pads BP1 are provided to face the plurality of joint pads BP2 in the Z direction and are in contact with each other. The plurality of joint pads BP1 are coupled to the corresponding interconnect layer 76 at the end portion on the first semiconductor substrate W1 side. The insulating layer 53 corresponds to the joint layer B1.

With the above configuration, each memory pillar MP provided in the first memory layer 200 and the second memory layer 300 is coupled to the transistor TR provided in the control circuit layer 100 via a plurality of corresponding interconnect layers, a plurality of contacts, and a plurality of joint pads. In addition, the interconnect layers corresponding to the word lines WL and the select gate lines SGS and SGD provided in the first memory layer 200 and the second memory layer 300 are coupled to the transistor TR provided in the control circuit layer 100 via a plurality of corresponding interconnect layers, a plurality of contacts, and a plurality of joint pads.

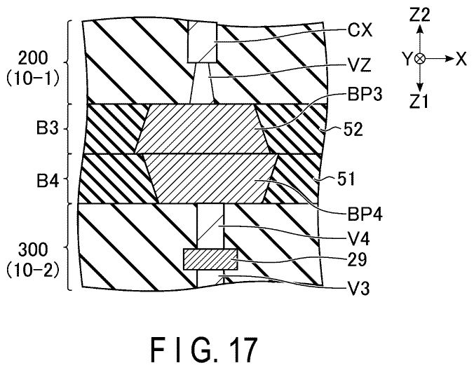

FIG. 17 is a sectional view illustrating an example of a sectional structure in the vicinity of two joint pads bonded to each other and provided in a joint layer between the first memory layer and the second memory layer included in the semiconductor memory device according to the first embodiment. FIG. 17 illustrates the joint pad BP3 formed in contact with the first memory layer 200, the joint pad BP4 formed in contact with the second memory layer 300, the contacts CX, VZ, V3, and V4 coupled thereto, and the interconnect layer 29. Note that FIG. 17 illustrates a case where the contact CX is coupled to the joint pad BP3, but the same applies even if the contact CC is coupled to the joint pad BP3.

As illustrated in FIG. 17, the joint pads BP3 and BP4 may have different tapered shapes based on an etching direction at the time of formation. Specifically, the joint pad BP3 formed in contact with the first memory layer 200 has, for example, a tapered shape tapered in the Z2 direction. The joint pad BP4 formed in contact with the second memory layer 300 has, for example, a tapered shape tapered in the Z1 direction. Therefore, in a portion where the joint pads BP3 and BP4 are bonded and combined, a side wall may not be linear in the shape of the section along the Z direction, and the shape of the section may be a non-rectangular shape. In addition, a set of two joint pads BP3 and BP4 disposed to face each other can be bonded to be shifted in accordance with alignment at the time of joint processing. Therefore, a step can be formed between the side surface of the joint pad BP3 and the side surface of the joint pad BP4. The set of two joint pads BP3 and BP4 disposed to face each other may have a boundary or may be integrated.

Although not illustrated, a sectional structure in the vicinity of the two joint pads BP1 and BP2 provided in the joint layers B1 and B2 between the control circuit layer 100 and the first memory layer 200 and bonded to each other is also similar to the structure illustrated in FIG. 17.

### 1.2 Manufacturing Method

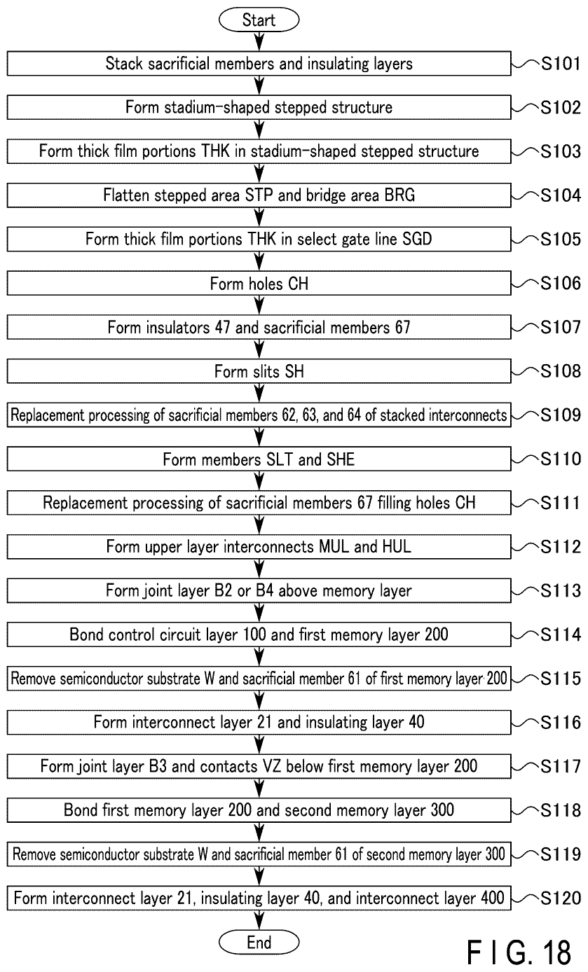

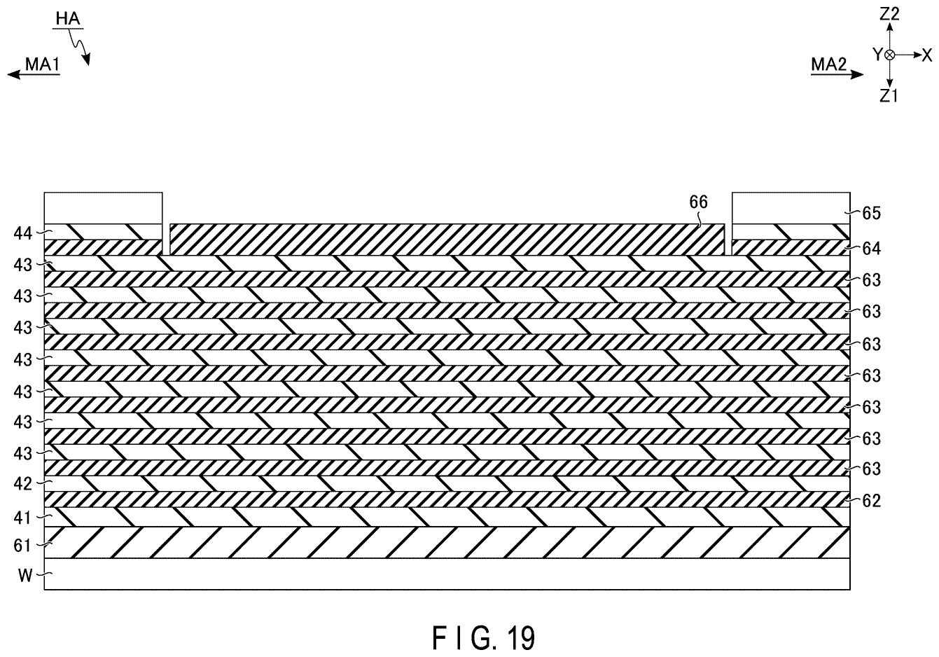

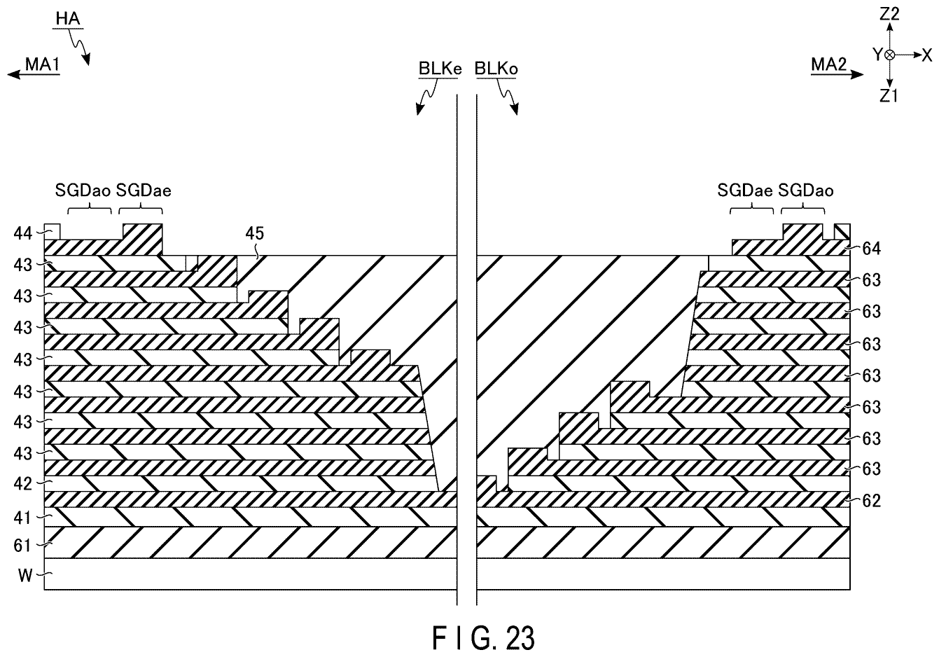

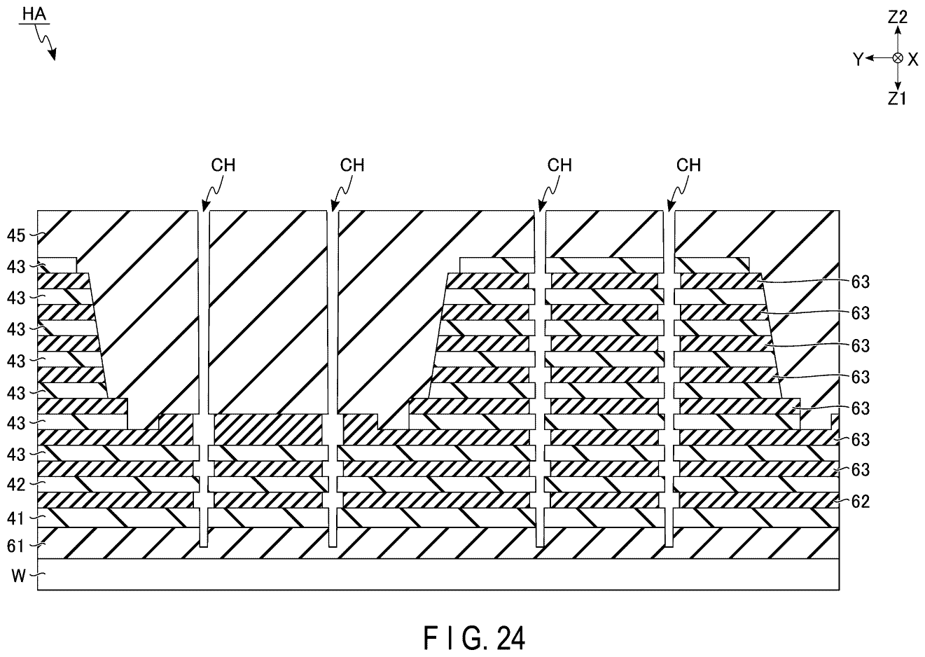

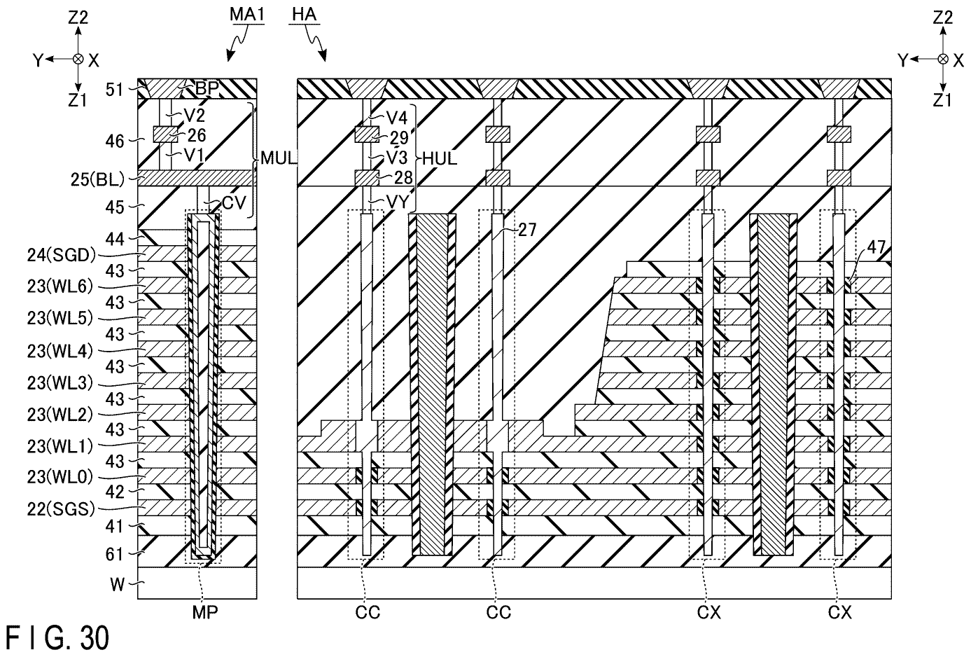

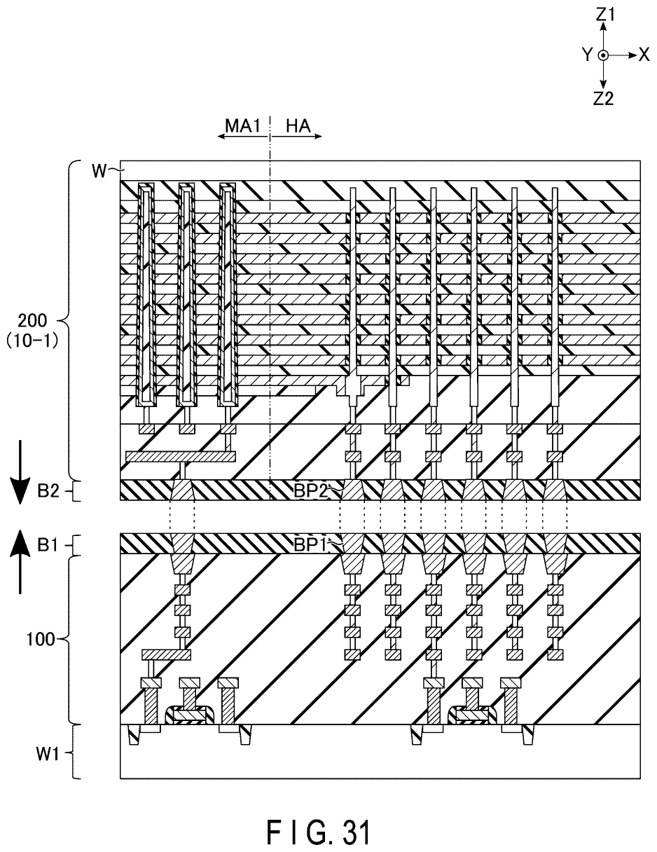

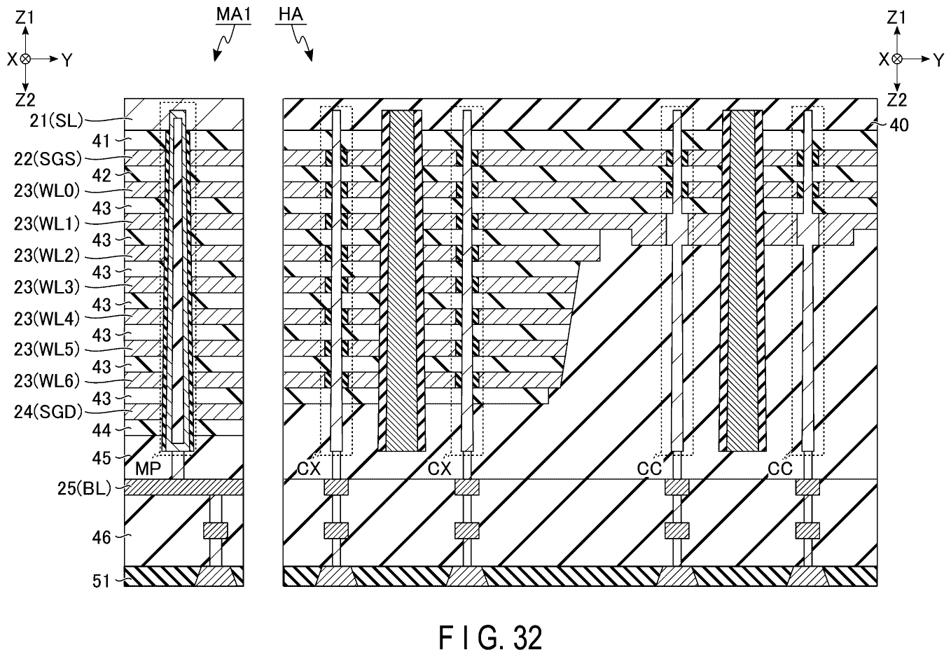

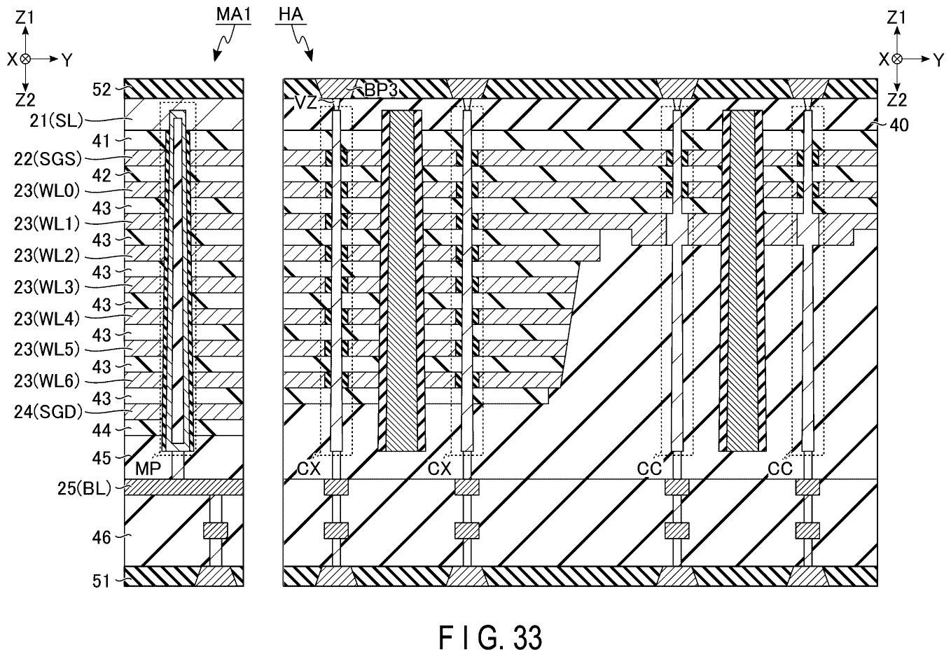

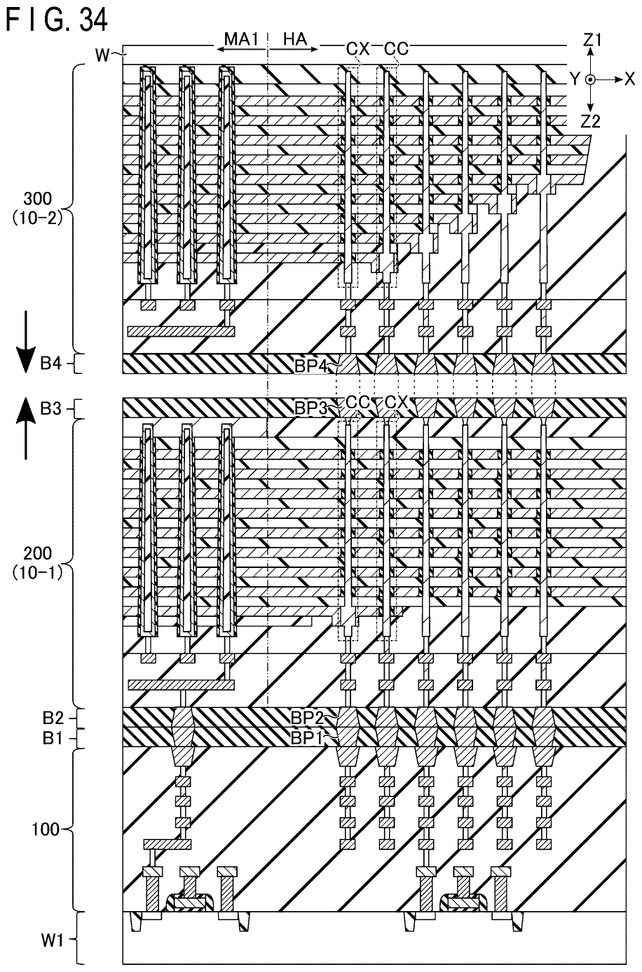

FIG. 18 is a flowchart illustrating an example of a manufacturing process of the memory cell array included in the semiconductor memory device according to the first embodiment. Each of FIGS. 19 to 34 is a sectional view illustrating an example of a sectional structure of the semiconductor memory device according to the first embodiment in the middle of manufacturing. FIGS. 19 to 22 correspond to the section illustrated in FIG. 11. FIG. 23 is a sectional view simultaneously illustrating the structures of the even-numbered block BLKe and the odd-numbered block BLKo in the XZ section of the memory cell array 10. FIGS. 24 to 29 correspond to the section illustrated in FIG. 12. FIGS. 30, 32, and 33 are sectional views simultaneously illustrating the structures of the memory area MA1 and the hookup area HA in the YZ section of the memory cell array 10. FIGS. 31 and 34 correspond to the section illustrated in FIG. 16. In FIGS. 32 and 33, the control circuit layer 100 and the joint layer B1 are omitted.

As illustrated in FIG. 18, in the manufacturing process of the hookup area HA, the processing of S101 to S120 is sequentially performed. Hereinafter, an example of a manufacturing process of the semiconductor memory device 3 will be described with reference to FIGS. 19 to 34 as appropriate. Note that, regarding the memory areas MA1 and MA2, a manufacturing process of the memory area MA1 is described as a representative in the following description, but a manufacturing process of the memory area MA2 is also similar to the manufacturing process of the memory area MA1.

In the present embodiment, the following case is described as an example: a method of forming structures corresponding to the interconnect layers 22, 23, and 24 by using sacrificial members 62, 63, and 64, respectively, and then forming the interconnect layers 22, 23, and 24 by replacing the sacrificial members 62, 63, and 64 with the conductive material (hereinafter, referred to as “replacement”) is adopted as a method of forming the plurality of interconnect layers 22, 23, and 24 corresponding to the select gate lines SGS and SGD and the word lines WL0 to WL6.

First, the memory cell arrays 10-1 and 10-2 are formed in the processing of S101 to S113. The structure formed in the processing of S101 to S113 is a structure common to the memory cell arrays 10-1 and 10-2.

First, the processing of S101 and S102 is sequentially performed, and a stepped structure is formed in the hookup area HA.

Specifically, as illustrated in FIG. 19, first, a sacrificial member 61 is stacked on the semiconductor substrate W. The sacrificial member 61 is a layer corresponding to the interconnect layer 21 and the insulating layer 40. The sacrificial member 61 includes, for example, polysilicon. Thereafter, the insulating layer 41, the sacrificial member 62, and the insulating layer 42 are stacked in this order on the sacrificial member 61. Seven sacrificial members 63 and seven insulating layers 43 are alternately stacked one by one on the insulating layer 42. The sacrificial member 64 and the insulating layer 44 are stacked in this order on the uppermost insulating layer 43. The thickness of each of the sacrificial members 62, 63, and 64 in the Z direction is equal to the first thickness D1. The insulating layers 41, 42, 43, and 44 include, for example, silicon oxide. The sacrificial members 62, 63, and 64 include, for example, silicon nitride.

Next, a mask 65 in which the memory areas MA1 and MA2 and the area where the select gate line SGD is to be formed in the hookup area HA are covered is formed. The mask 65 is formed by, for example, photolithography or the like. Thereafter, the insulating layer 44 and the sacrificial member 64 corresponding to one stage are removed by anisotropic etching using the mask 65. The sacrificial member 66 is provided in the area where the insulating layer 44 and the sacrificial member 64 were removed. The sacrificial member 66 is provided as a reference for flattening at the time of flattening performed in S104. The sacrificial member 66 includes, for example, silicon nitride.

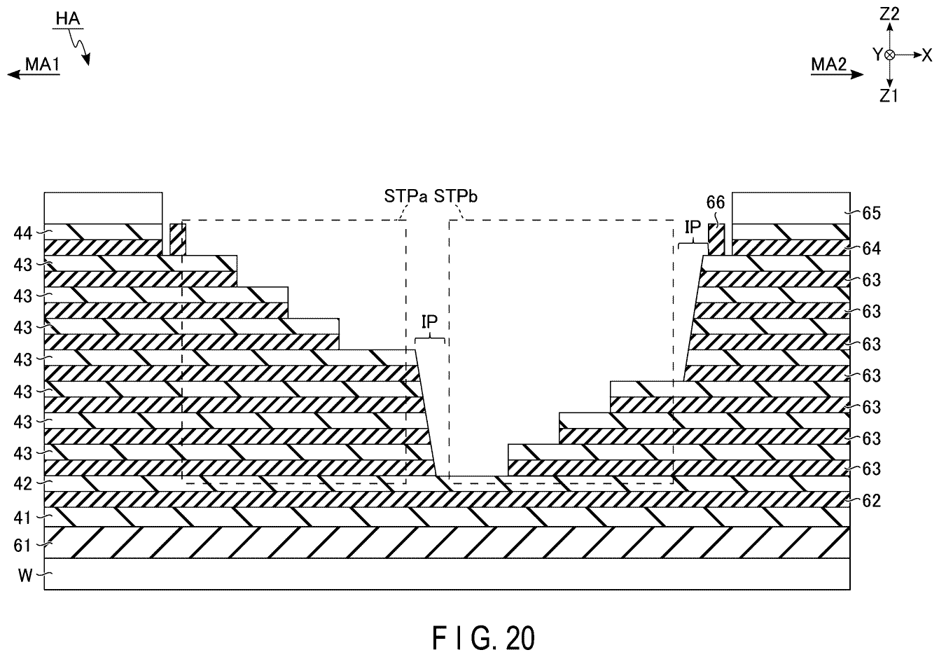

Thereafter, as illustrated in FIG. 20, a stadium-shaped stepped structure is formed in the stepped area STP (S102). The stadium-shaped stepped structure is formed by the following three steps of processing.

As a first step, the sacrificial member 66 is removed in an area corresponding to the stepped area STP. Specifically, first, a mask in which a portion corresponding to the stepped area STP is opened is formed by photolithography or the like. Then, the sacrificial member 66 provided in the stepped area STP is removed by anisotropic etching using the mask. At this time, the sacrificial member 66 provided in the bridge area BRG remains without being removed.

As a second step, the four insulating layers 43 and the four sacrificial members 63 from the upper layer are processed in a step shape in which a set of one insulating layer 43 and one sacrificial member 63 is set as one stage. Specifically, first, a mask in which a portion corresponding to the lowest stage of each of the stepped areas STPa and STPb is opened is formed by photolithography or the like. Then, the insulating layer 43 and the sacrificial member 63 corresponding to one stage are removed by anisotropic etching using the mask. Next, a portion of the mask corresponding to the second lowest stage of each of the stepped areas STPa and STPb, is removed. Thereafter, the insulating layer 43 and the sacrificial member 63 corresponding to one stage are removed by anisotropic etching using the mask. As described above, by repeating the reduction in size of the masked area and the anisotropic etching, the insulating layer 43 and the sacrificial member 63 are processed in a step shape. Such processing is called “slimming”.

As a third step, multistage processing is performed on a portion corresponding to the inclined portion IP, and the stepped structure formed in the stepped area STPb is processed so as to correspond to the interconnect layer below the stepped structure formed in the stepped area STPa. The multistage processing is the processing of removing a plurality of sets of insulating layers 43 and sacrificial members 63 in the process area at a time. Specifically, first, a mask in which an area corresponding to the inside of the inclined portion IP is opened is formed by photolithography or the like. Then, for example, a set of the insulating layers 43 and the sacrificial members 63 corresponding to four stages is removed by anisotropic etching using the mask. As a result, a structure in which the insulating layer 42 and the sacrificial member 62, three layers of the insulating layers 43 from the lower layer, and three layers of the sacrificial members 63 from the lower layer are processed in a step shape with a set of the insulating layer 42 and the sacrificial member 62 or one layer of the insulating layer 43 and one layer of the sacrificial member 63 is set as one stage is formed. In addition, the inclined portion IP is formed at the time of removing a plurality of stages by multistage processing.

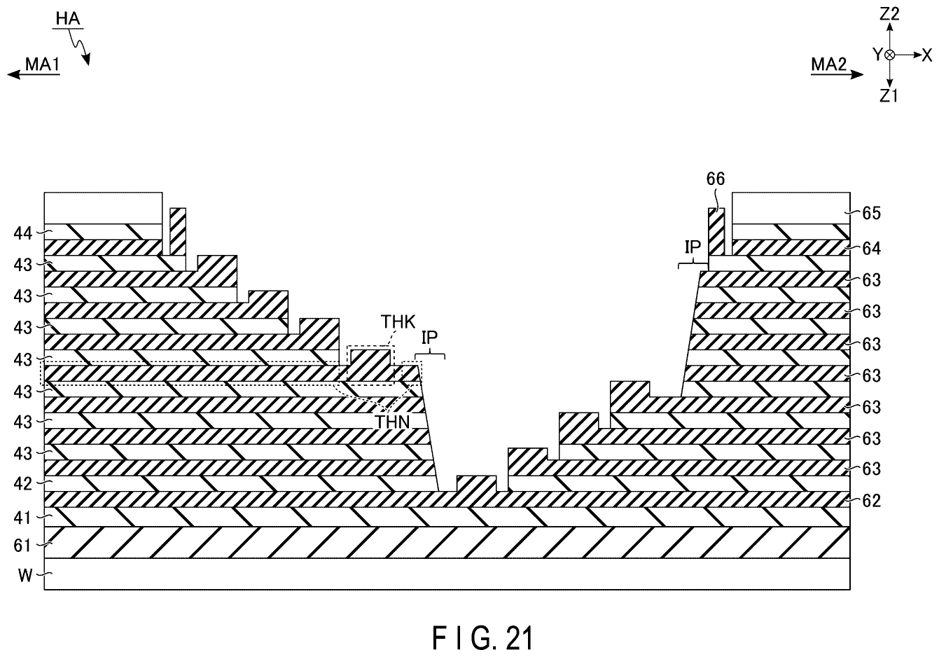

Next, the processing of S103 is executed, and as illustrated in FIG. 21, a structure corresponding to the thick film portions THK of the interconnect layers 22 and 23 in the stadium-shaped stepped structure in the hookup area HA is formed.

Specifically, terrace portions corresponding to the select gate line SGS and the word lines WL0 to WL6 are formed. First, a part of the insulating layers 42 and 43 exposed on the upper surface of the stadium-shaped stepped structure is removed. Then, a sacrificial material is formed on the sacrificial members 62 and 63, and the films of the sacrificial members 62 and 63 in the stepped portion are thickened. At this time, the film of the sacrificial member 66 provided in the bridge area BRG is similarly thickened. The sacrificial material is the same material as the sacrificial members 62 and 63 and contains, for example, SiN. Thereafter, in the sacrificial material obtained by thickening the films of the stepped portions of the sacrificial members 62 and 63, a portion in contact with the side surface portion of the sacrificial member 63 or 64 provided one layer above the sacrificial member 62 or 63 with the insulating layer 42 or 43 interposed therebetween, and the inclined portion IP and a portion provided near the inclined portion IP are removed. In this way, portions of the sacrificial members 62 and 63 where the films thereof are thickened and that correspond to the thick film portion THK are formed. The thickness in the Z direction of the sacrificial members 62 and 63 corresponding to the thick film portion THK is equal to the second thickness D2.

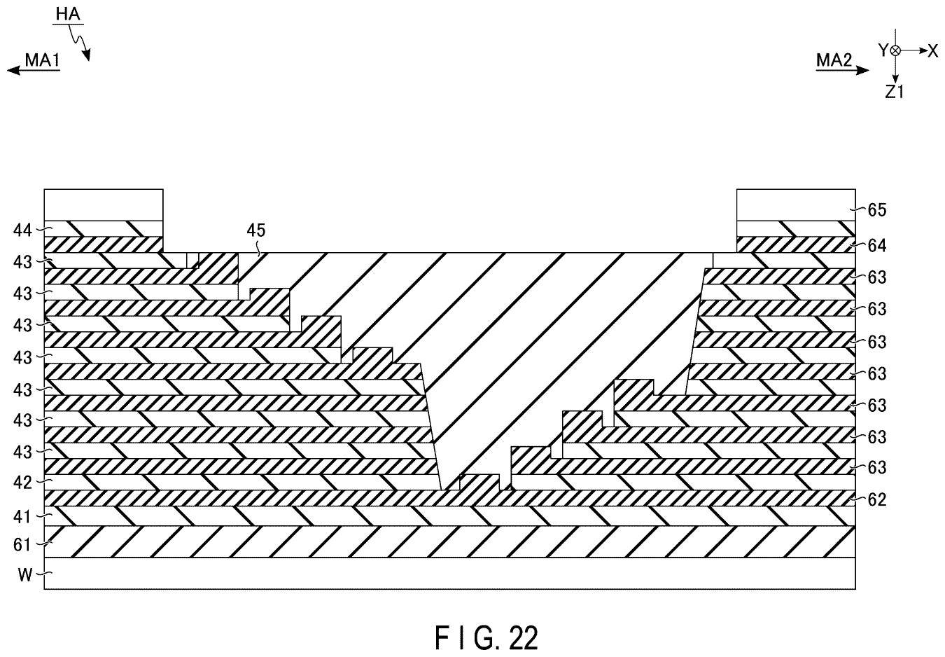

Next, the processing of S104 is performed, and the stepped area STP and the bridge area BRG are flattened as illustrated in FIG. 22.

Specifically, first, the stadium-shaped stepped structure is filled with the insulating layer 45. The insulating layer 45 contains, for example, tetra ethoxy silane (TEOS). Thereafter, a part of the insulating layer 45 and the sacrificial member 66 in the stepped area STP and the bridge area BRG are removed and flattened. At this time, the sacrificial member 66 is used as a mark, and removal is performed to a depth at which the sacrificial member 66 is completely removed. The surfaces of the insulating layers 43 and 45 after being removed are flattened by, for example, chemical mechanical polishing (CMP).

Next, the processing of S105 is executed, and as illustrated in FIG. 23, the thick film portion THK in the select gate line SGD is formed.

Specifically, first, the mask 65 and the insulating layer 44 in the portion corresponding to the select gate line SGD in the hookup area HA is removed. Next, a sacrificial material is formed on the sacrificial member 64, and the film of the sacrificial member 64 in the stepped portion is thickened. The sacrificial material is the same material as the sacrificial member 64 and contains, for example, SiN. Thereafter, a part of the sacrificial material obtained by thickening the film of the sacrificial member 64 is removed according to the block BLK in which the select gate line SGD is provided. In FIG. 23, the left side of the paper illustrates the structure of the even-numbered block BLKe, and the right side of the paper illustrates the structure of the odd-numbered block BLKo. In the even-numbered block BLKe, the portion of the inner contact area SGDe is thickened, and the thickened portion of the outer contact area SGDo is removed. In the odd-numbered block BLKo, the portion of the outer contact area SGDo is thickened, and the thickened portion of the inner contact area SGDe is removed. Thereafter, the insulating layer 45 is embedded so as to embed the thickened portion of the sacrificial member 64. The surface of the insulating layer 45 is flattened by, for example, CMP or the like.

Next, the processing of S106 and S107 is executed, and a configuration corresponding to the plurality of contacts CC and CX is formed.

Specifically, first, the processing of S106 is executed, and a plurality of holes CH are formed as illustrated in FIG. 24. The plurality of holes CH are provided at positions corresponding to the plurality of contacts CC and CX. First, a mask in which areas corresponding to the contacts CC and CX are opened is formed by photolithography or the like. Then, a plurality of holes CH corresponding to the contacts CC and CX are formed by anisotropic etching using the mask. Each hole CH passes through (penetrates) each of the insulating layers 41, 42, 43, and 45 and the sacrificial members 62, 63, and 64 provided at corresponding positions in plan view in the Z direction. The sacrificial member 61 is exposed at the bottom portion of each hole CH.

Next, as illustrated in FIG. 24, the peripheral portions of the sacrificial members 62, 63, and 64 exposed to the side surfaces of the holes CH are removed by wet etching through the holes CH. In this way, a plurality of grooves in which the sacrificial members 62, 63, and 64 are recessed in the radial direction along the XY plane direction with respect to the insulating layers 41, 42, 43, and 45 are formed on the side surfaces of the holes CH.

Although not illustrated, holes corresponding to the memory pillars MP may be formed simultaneously with the processing of S106. The holes corresponding to the memory pillars MP pass through (penetrate) each of the insulating layers 41, 42, 43, and 45 and the sacrificial members 62, 63, and 64 in the Z direction, and the sacrificial member 61 is exposed at the bottom portion. The depth of the hole corresponding to the memory pillar MP may be equal to or different from the depths of the plurality of holes CH. The hole corresponding to the memory pillar MP is filled with a sacrificial member.

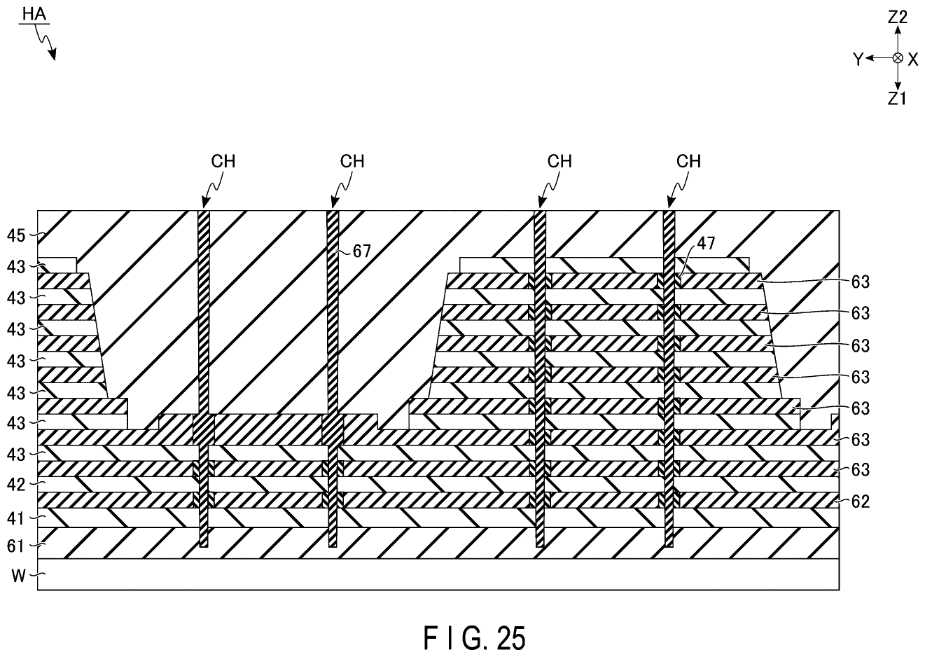

Thereafter, the processing of S107 is executed, and the insulator 47 and the sacrificial member 67 are formed as illustrated in FIG. 25. First, the film of the insulator 47 is formed on the inner wall of each hole CH. For portions where the films of the sacrificial members 62, 63, and 64 are not thickened, the film of the insulator 47 is formed so as to fill all of the plurality of grooves formed in S106. On the other hand, for a portion where the film of any of the sacrificial members 62, 63, and 64 is thickened, the film of the insulator 47 is formed so as to cover the surface of the groove while leaving a portion recessed at the central portion. The insulator 47 contains, for example, SiO.

Next, a part of the insulator 47 provided on the inner wall of each hole CH is removed by wet etching or the like. At this time, for portions where the films of the sacrificial members 62, 63, and 64 are not thickened, the insulator 47 filling the groove is not completely removed, and none of the sacrificial members 62, 63, and 64 is exposed to the side surface portion of each hole CH. On the other hand, for a portion where the film of any of the sacrificial members 62, 63, and 64 is thickened, the insulator 47 provided so as to cover the surface of the groove is removed, and the sacrificial member 62, 63, or 64 is exposed on the side surface portion of each hole CH.

Thereafter, as illustrated in FIG. 25, the hole CH is filled with the sacrificial member 67. The sacrificial member 67 contains, for example, amorphous silicon.

The memory pillar MP may be formed after the processing of S107. Specifically, first, the sacrificial member embedded in the hole corresponding to the memory pillar MP is removed. Thereafter, the stacked film 32, the semiconductor film 31, and the core film 30 are formed in this order in the hole. At this time, the semiconductor film 31 may not be in contact with the sacrificial member 61 at the bottom portion.

Next, the processing of S108 is executed to form the slit SH corresponding to the member SLT.

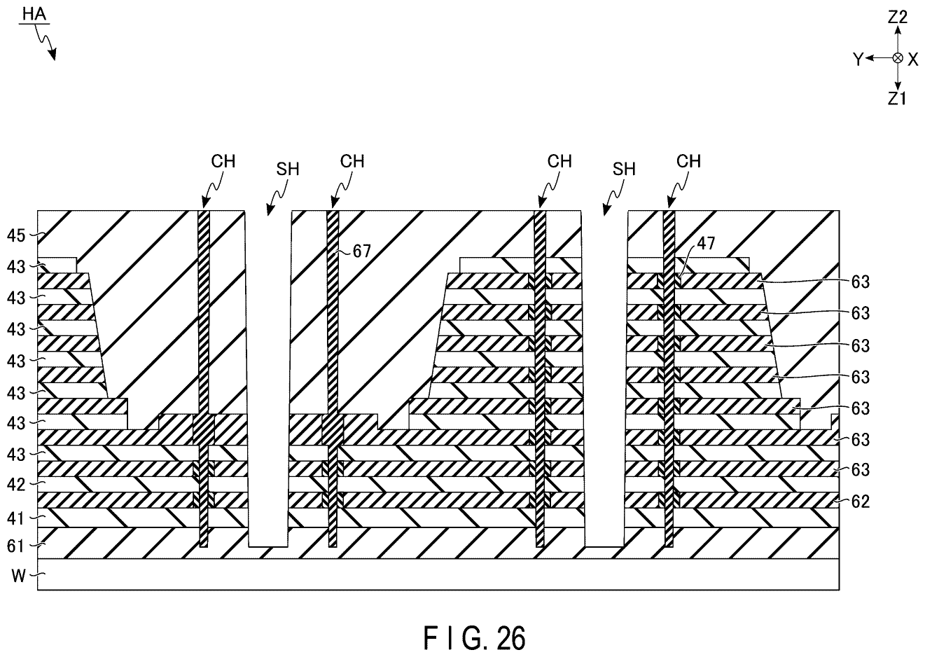

Specifically, first, a mask in which an area corresponding to each member SLT is opened is formed by photolithography or the like. Then, as illustrated in FIG. 26, a plurality of slits SH corresponding to the respective members SLT are formed by anisotropic etching using the mask. Each slit SH passes through (penetrates), in the Z direction, each of the insulating layers 41, 42, 43, 44, and 45 and the sacrificial members 62, 63, and 64 provided at corresponding positions in plan view. The sacrificial member 61 is exposed at the bottom portion of each slit SH.

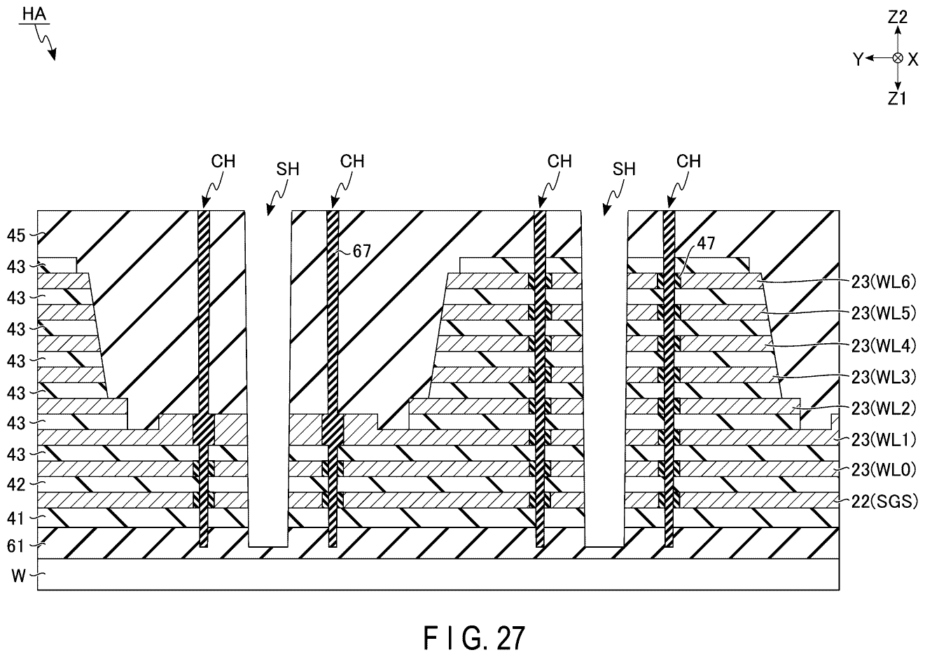

Next, the processing of S109 is performed, and replacement processing (replacement) of the sacrificial members 62, 63, and 64 corresponding to the stacked interconnect is performed as illustrated in FIG. 27.

Specifically, first, the sacrificial members 62, 63, and 64 are removed through the slits SH by wet etching. At this time, a three-dimensional structure of a structural body from which the sacrificial members 62, 63, and 64 were removed is supported by the plurality of memory pillars MP (not illustrated) and a plurality of support pillars (not illustrated) disposed as appropriate in the hookup area HA. Then, a conductor (for example, tungsten or molybdenum) is embedded in a space from which the sacrificial members 62, 63, and 64 was removed through the slit SH. For the formation of the conductor in this step, for example, chemical vapor deposition (CVD) is used. Thereafter, the conductor formed inside the slit SH is removed by etch-back processing, and the layers of the conductors adjacent in the Z direction are separated from each other. In this way, the interconnect layer 22 functioning as the select gate line SGS, the plurality of interconnect layers 23 functioning as the word lines WL0 to WL6, and the interconnect layer 24 functioning as the select gate line SGD are formed. Note that the interconnect layers 22, 23, and 24 formed in this step may contain a barrier metal. In this case, in the formation of the conductor after the removal of the sacrificial members 62, 63, and 64, for example, a film of titanium nitride (TiN) or molybdenum nitride (MoN) is formed as a barrier metal, and then tungsten or molybdenum is formed as the conductor. In addition, the interconnect layers 22, 23, and 24 may include an insulating film. In this case, in the formation of the conductor after removing the sacrificial members 62, 63, and 64, for example, a metal oxide film of aluminum oxide (AlO) or the like is formed as an insulating film, and then a barrier metal and a conductor (tungsten or molybdenum) are formed.

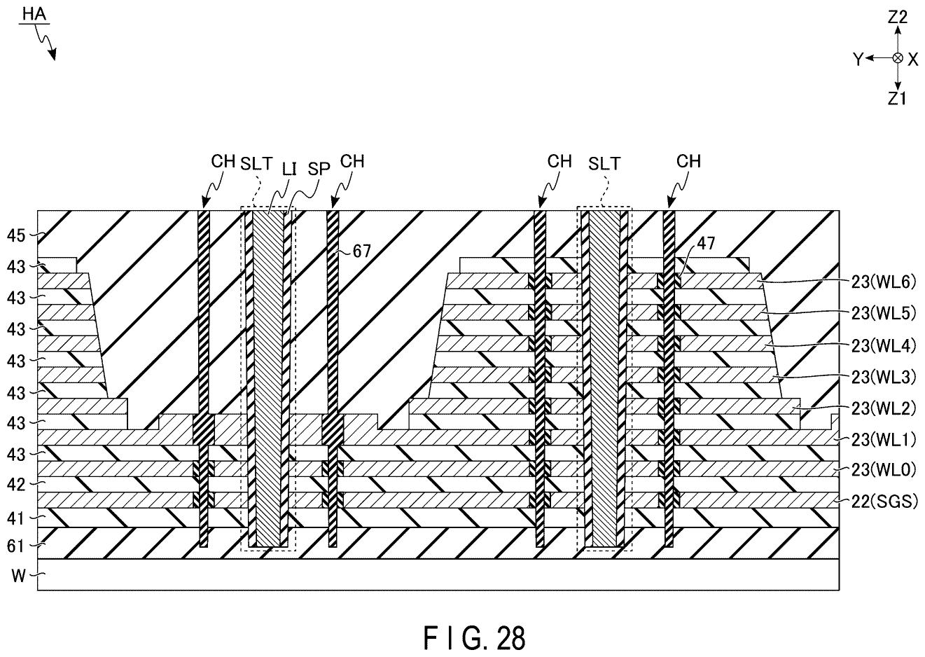

Next, the processing of S110 is performed, and the member SLT is formed in the slit SH as illustrated in FIG. 28. Although not illustrated, the member SHE is formed from the memory area MA1 to the first portion SGDa of the select gate line SGD and from the memory area MA2 to the second portion SGDb of the select gate line SGD.

Specifically, first, an insulating portion (spacer SP) is formed so as to cover the side surface and the bottom surface of the slit SH. Then, a part of the spacer SP provided at the bottom portion of the slit SH is removed, and a part of the sacrificial member 61 is exposed at the bottom portion of the slit SH. Then, a conductor (contact LI) is formed in the slit SH, and the conductor formed outside the slit SH is removed by, for example, CMP. Thereafter, a plurality of grooves are formed in an area corresponding to the member SHE between the members SLT adjacent in the Y direction so that the plurality of grooves are parallel to the member SLT. Then, the inside of each groove is filled with an insulating film, so that the member SHE dividing the interconnect layer 24 in the Y direction is formed.

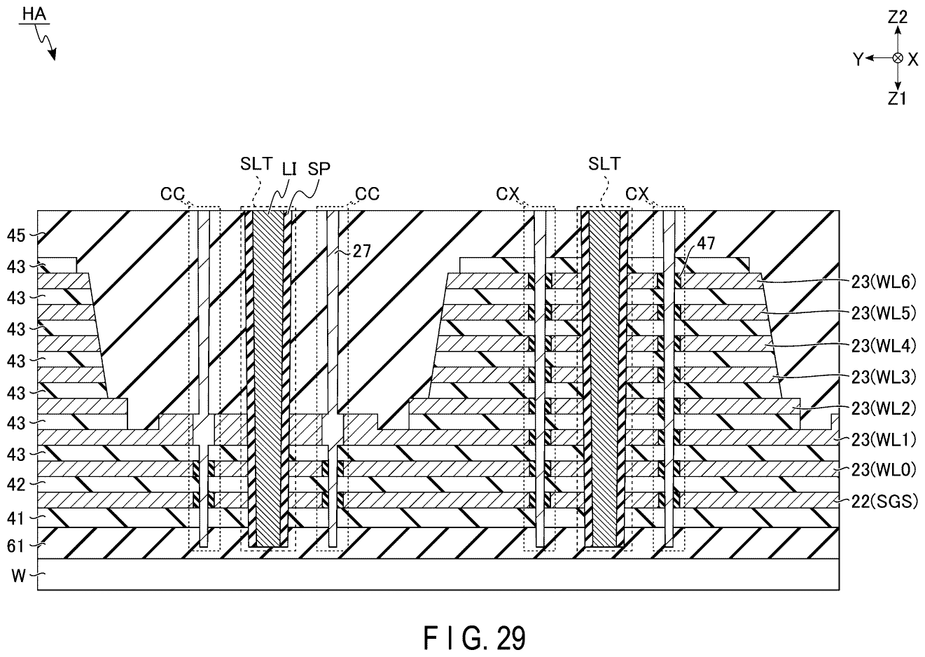

Next, the processing of S111 is performed, and as illustrated in FIG. 29, replacement processing of the sacrificial member 67 filling the hole CH is performed, and the contacts CC and CX are formed.

Specifically, first, the sacrificial member 67 filling each hole CH is removed by wet etching. At this time, in a case where each of the interconnect layers 22, 23, and 24 includes an insulating film of aluminum oxide or the like, the insulating film in contact with the sacrificial member 67 is also simultaneously removed. Then, the hole CH is filled with the plurality of conductors 27. Each conductor 27 filling the hole CH corresponding to the contact CC is in contact with the interconnect layers 22, 23, or 24 in a side direction in the groove formed in each terrace portion among the interconnect layers 22, 23, and 24. On the other hand, each of the conductors 27 filling the hole CH corresponding to the contact CX is insulated from the interconnect layers 22, 23, and 24. In addition, each conductor 27 is in contact with the sacrificial member 61 at the bottom portion. Finally, the conductor 27 formed on the upper surface of the stacked structure is removed by, for example, CMP, so that the surfaces corresponding to the upper ends of the plurality of contacts CC and CX are exposed.

Next, the processing of S112 and S113 is performed, and as illustrated in FIG. 30, the upper layer interconnects MUL and HUL, and the joint layer provided above the memory layer are formed. The joint layer B2 is formed above the first memory layer 200, and the joint layer B4 is formed above the second memory layer 300.

Specifically, after the insulating layer 45 is further stacked, the contact CV is formed above each memory pillar MP. In addition, the contact VY is formed above each of the contacts CC and CX. Thereafter, the interconnect layer 25 is formed above each contact CV, and the interconnect layer 28 is formed above each contact VY. The insulating layer 46 is formed above the insulating layer 45. The contact V1 is formed above each interconnect layer 25, and the contact V3 is formed above each interconnect layer 28. The interconnect layer 26 is formed above each contact V1, and the interconnect layer 29 is formed above each contact V3. The contact V2 is formed above each interconnect layer 26, and the contact V4 is formed above each interconnect layer 29. The contacts CV, VY, V1, V2, V3, and V4, and the interconnect layers 25, 26, 28, and 29 are formed, for example, by forming a hole or a groove at the position of the insulating layer 45 or 46 where the contact or the interconnect is formed and filling the hole or the groove with a conductor. As a result, the upper layer interconnects MUL and HUL are formed (S112). The upper layer interconnect MUL has a pattern in which the interconnect layers 25 and 26 extend in the Y direction or the X direction and are routed in the memory cell array 10, and is coupled to a structure provided above the memory cell array 10.

Next, the insulating layer 51 is stacked above the insulating layer 46. Thereafter, a plurality of grooves corresponding to the joint pad BP is formed above the plurality of contacts V2 and V4. The plurality of grooves have, for example, a tapered shape tapered in the Z1 direction, and the corresponding contacts V2 or V4 are exposed on the bottom surface. Thereafter, the plurality of grooves are filled with a conductor such as copper to form the joint pad BP. The joint pad BP corresponds to the joint pad BP2 in the memory cell array 10-1, and corresponds to the joint pad BP4 in the memory cell array 10-2. As a result, the joint layer B2 or B4 provided above the first memory layer 200 or the second memory layer 300 is formed (S113).

Next, the processing of S114 is performed, and as illustrated in FIG. 31, the separately manufactured control circuit layer 100 and the first memory layer 200 are bonded in the Z direction.

Specifically, the first memory layer 200 and the joint layer B2 reversed in the Z direction are bonded to the control circuit layer 100 and the joint layer B1 manufactured using the first semiconductor substrate W1 from the Z1 direction side. At this time, the joint pad BP2 provided on the joint layer B2 and the joint pad BP1 provided on the joint layer B1 are bonded so as to face each other in the Z direction and be in contact with each other.

Next, the processing of S115 and S116 is performed on the memory cell array 10-1 after the control circuit layer 100 and the first memory layer 200 are bonded, and the interconnect layer 21 and the insulating layer 40 are formed. At this timing, the semiconductor film 31 of the plurality of memory pillars MP and the interconnect layer 21 are coupled.

First, the semiconductor substrate W and the sacrificial member 61 are removed (S115). As a result, the end portions of the plurality of memory pillars MP, the plurality of members SLT, and the plurality of contacts CC and CX are exposed. In addition, the stacked film 32 is removed at the exposed end portion of each memory pillar MP. As a result, the semiconductor film 31 of the memory pillar MP is exposed. Note that in the memory areas MA1 and MA2, at least a part of the sacrificial member 61 provided in a portion penetrating in the Z direction by the memory pillar MP may be left without being removed. In addition, at least a part of the sacrificial member 61 in the hookup area HA may be left without being removed.

Next, as illustrated in FIG. 32, a layer to be the source line SL is formed on the surface of the insulating layer 41 in the Z1 direction. Specifically, for example, an amorphous silicon layer is deposited so as to be in contact with the semiconductor film 31 of each memory pillar MP and the exposed end portion of the member SLT. Then, the amorphous silicon layer provided in the memory areas MA1 and MA2 is doped with an impurity such as phosphorus, and subjected to heat treatment, thereby activating the doped impurity and crystallizing the amorphous silicon into polysilicon. As a result, the polysilicon layer provided in the memory areas MA1 and MA2 has conductivity and functions as the interconnect layer 21. On the other hand, the polysilicon layer formed in the hookup area HA does not have conductivity, and thus functions as the insulating layer 40. (S116).

Next, the processing of S117 is performed to form the joint layer B3 and the contact VZ provided below (in the Z1 direction) the first memory layer 200. The joint pad BP3 in the joint layer B3 and the contact VZ are formed by, for example, dual damascene processing.

Specifically, the insulating layer 52 is stacked on the lower surfaces (surfaces in the Z1 direction) of the interconnect layer 21 and the insulating layer 40. Thereafter, a plurality of grooves corresponding to the joint pad BP3 and the contact VZ are formed at positions overlapping the plurality of contacts CC and CX of the insulating layer 52 in the Z direction. The plurality of grooves are formed in two steps, and the groove in the first step is provided in the insulating layer 52, and the groove in the second step is provided in the insulating layer 40. The plurality of grooves have, for example, a tapered shape tapered in the Z2 direction, and the corresponding contacts CC or CX are exposed on the bottom surface of the groove in the second step. Thereafter, the plurality of grooves are filled with a conductor, and the plurality of contacts VZ and the plurality of joint pads BP3 are formed. As a result, as illustrated in FIG. 33, the joint layer B3 and the contact VZ provided below (in the Z1 direction) the first memory layer 200 are formed.

Next, the processing of S118 is performed, and the first memory layer 200 and the second memory layer 300 are bonded in the Z direction as illustrated in FIG. 34.

Specifically, the second memory layer 300 and the joint layer B4 reversed in the Z direction are bonded to the first memory layer 200 and the joint layer B3 from the Z1 direction side. At this time, the joint pad BP4 provided on the joint layer B4 and the joint pad BP3 provided on the joint layer B3 are bonded so as to face each other in the Z direction and be in contact with each other. The first memory layer 200 and the second memory layer 300 are bonded such that the memory cell arrays 10-1 and 10-2 provided therein are shifted by one block BLK in the Y direction and overlap in the Z direction, as illustrated in FIG. 6.

Thereafter, the processing of S119 and S120 is performed on the memory cell array 10-2 after the first memory layer 200 and the second memory layer 300 are bonded, and the interconnect layer 21 and the insulating layer 41 are formed. This processing is similar to the processing of S115 and S116 in the first memory layer 200. Thereafter, the interconnect layer 400 is provided below (in Z1 direction) the second memory layer 300. A plurality of pads PD are formed in the interconnect layer 400.

Note that the semiconductor memory device 3 may include interconnects and contacts other than those described above. For example, in the memory cell array 10-1, interconnects and contacts for routing interconnects coupled to the memory pillars MP included in the memory cell array 10-2 may be included. For example, in the memory cell arrays 10-1 and 10-2, interconnects and contacts for coupling the pads PD provided in the interconnect layer 400 and various control circuits included in the control circuit layer 100 may be included. These interconnects can function as interconnects PW. In addition, each of the joint layers B1, B2, B3, and B4 may include a joint pad for coupling to an interconnect other than those described above.

The structure of the semiconductor memory device 3 is formed by the manufacturing process described above. Note that the manufacturing process described above is merely an example, and the present invention is not limited thereto. For example, other processing may be inserted between the manufacturing processes, or some steps may be omitted or integrated with each other. In addition, each manufacturing process may be interchanged within the possible range.

### 1.3 Effects According to First Embodiment

According to the first embodiment, the degree of integration of the semiconductor memory device 3 can be improved. These effects will be described in detail below.

The semiconductor memory device 3 according to the first embodiment has a structure in which the memory cell arrays 10-1 and 10-2 overlap in the Z direction and the stepped areas STP included in the memory cell arrays 10-1 and 10-2 are alternately provided in the Y direction. With this structure, the hookup areas HA in which the stadium-shaped stepped structure is provided can be provided at positions overlapping in the Z direction. Therefore, the expansion of the hookup area HA is suppressed, and the area occupied by the memory areas MA1 and MA2 in one semiconductor memory device 3 can be increased, so that the degree of integration of the semiconductor memory device 3 can be improved.

Further, the semiconductor memory device 3 according to the first embodiment has a configuration in which the memory cell arrays 10-1 and 10-2 are stacked, and the blocks BLK included in the memory cell arrays 10-1 and 10-2 are independently driven. With this configuration, since it is possible to selectively drive one block BLK in the memory cell arrays 10-1 and 10-2 at the time of reading or writing data from or to the memory cell, it is possible to suppress a decrease in reliability of the memory cell.

In addition, the structures of the hookup areas HA of the memory cell arrays 10-1 and 10-2 are substantially the same. Therefore, since it is less likely to add a special process to one of the memory cell arrays 10-1 and 10-2, an increase in manufacturing cost in the manufacturing process can be suppressed.

### 1.4 Modifications

The semiconductor memory device 3 according to the first embodiment described above can be variously modified. Hereinafter, differences from the first embodiment will be described as to a first modification, a second modification, and a third modification of the first embodiment.

### 1.4.1 First Modification

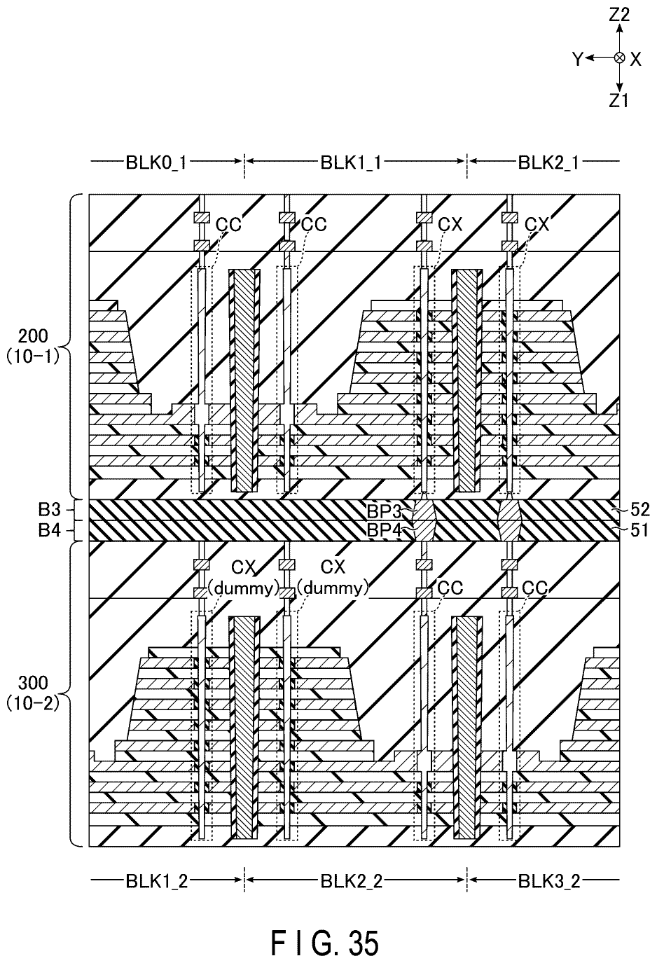

FIG. 35 is a sectional view illustrating an example of a sectional structure of a first memory layer, a second memory layer, and a joint layer provided between the first memory layer and the second memory layer included in a semiconductor memory device according to the first modification of the first embodiment. A section illustrated in FIG. 35 corresponds to the section illustrated in FIG. 13 in the first embodiment.

As illustrated in FIG. 35, the semiconductor memory device 3 according to the first modification of the first embodiment does not include a plurality of joint pads BP3 and BP4 for coupling a plurality of contacts CC provided in the first memory layer 200 and a plurality of contacts CX provided in the second memory layer 300 to each other, and a plurality of contacts VZ corresponding to the plurality of contacts CC in the first memory layer 200. That is, the plurality of contacts CC provided in the first memory layer 200 are coupled to the interconnect layers 22 to 24 corresponding to the contact CC, are in contact with the joint pad BP2 at the upper portion, and are provided inside the insulating layer 41 at the lower portion. The plurality of contacts CX provided in the second memory layer 300 are dummy contacts not coupled to all of the interconnect layers 22 to 24. On the other hand, the plurality of joint pads BP3 and BP4 for coupling the plurality of contacts CX provided in the first memory layer 200 and the plurality of contacts CC provided in the second memory layer 300, and the plurality of contacts VZ in the first memory layer 200 are provided similarly to the first embodiment. With this configuration, the interconnect layers 22, 23, and 24 provided in the second memory layer 300 are coupled to the row decoder module 16 provided in the control circuit layer 100.

### 1.4.2 Second Modification

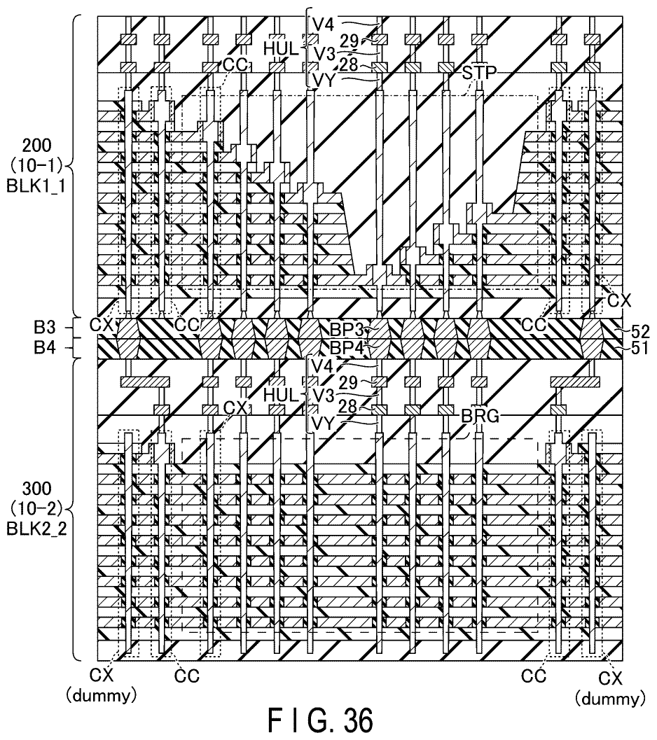

FIG. 36 is a sectional view illustrating an example of a sectional structure of a first memory layer, a second memory layer, and a joint layer provided between the first memory layer and the second memory layer included in a semiconductor memory device according to the second modification of the first embodiment. A section illustrated in FIG. 36 corresponds to the section illustrated in FIG. 14 in the first embodiment.

As illustrated in FIG. 36, in the semiconductor memory device 3 according to the second modification of the first embodiment, a plurality of contacts CC corresponding to the select gate line SGD included in each of the memory cell arrays 10-1 and 10-2 are provided at positions overlapping in the Z direction. In this case, the interconnect layer 29 included in the memory cell array 10-2 extends, for example, in the X direction and is routed to a position not overlapping the contact CC corresponding to the select gate line SGD provided in the memory cell array 10-1 in the Z direction. The memory cell array 10-1 includes a plurality of contacts CX corresponding to the select gate line SGD of the memory cell array 10-2, and the plurality of contacts CX are coupled to a plurality of corresponding contacts CC included in the memory cell array 10-2 via the joint pads BP3 and BP4, the contact VZ, and the upper layer interconnect HUL of the memory cell array 10-2. The plurality of contacts CX included in the memory cell array 10-2 and passing through the thin film portion THN of the select gate line SGD are dummy contacts not coupled to the interconnect layer 24 included in the memory cell array 10-1.

### 1.4.3 Third Modification

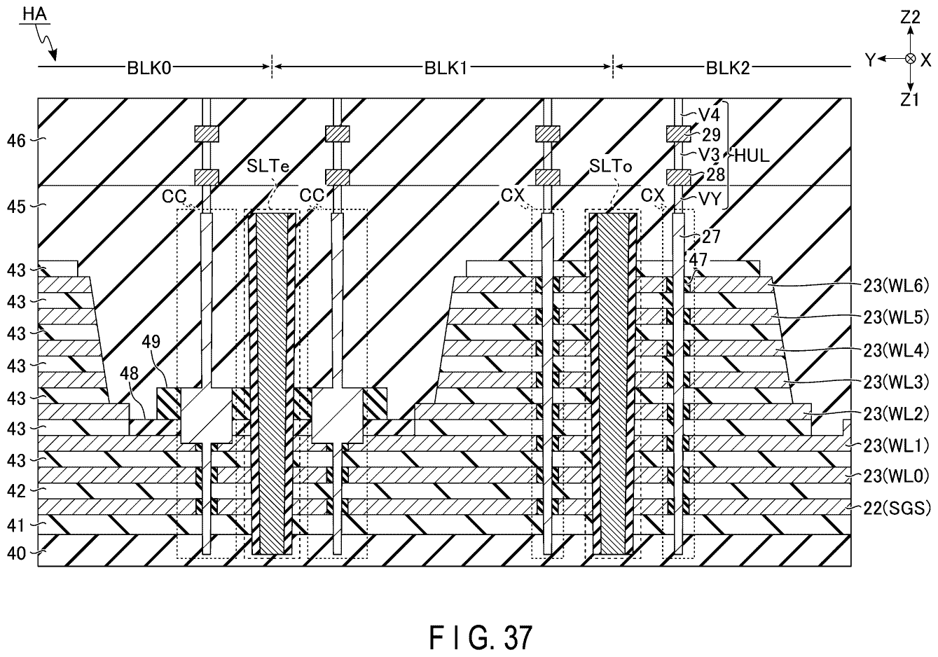

FIG. 37 is a sectional view illustrating an example of a sectional structure in a hookup area of a memory cell array included in a semiconductor memory device according to the third modification of the first embodiment. A section illustrated in FIG. 37 corresponds to the section illustrated in FIG. 12 in the first embodiment.

As illustrated in FIG. 37, the memory cell array 10 included in the semiconductor memory device 3 according to the third modification of the first embodiment further includes insulating layers 48 and 49. The insulating layers 48 and 49 contain, for example, silicon oxide. In addition, each of the interconnect layers 22, 23, and 24 of the memory cell array 10 does not include a thick film portion.

Compared to the first embodiment, the third modification of the first embodiment is different in the shape of the contact CC and the structure of the coupling portion with each of the interconnect layers 22, 23, and 24 to which the contacts CC correspond. Specifically, the conductor 27 included in the contact CC according to the first embodiment is coupled to the corresponding interconnect layer 22, 23, or 24 in the XY plane direction at the thick film portion THK. On the other hand, the conductor 27 included in the contact CC according to the third modification of the first embodiment is coupled to the corresponding interconnect layer 22, 23, or 24 in the Z direction on the upper surface.

In the manufacturing process of the memory cell array 10 according to the third modification of the first embodiment, step S103 in the first embodiment is omitted, and instead, a step in which the insulating layer 48 and the thick film sacrificial member are stacked in this order is inserted. The thick film sacrificial member includes, for example, silicon nitride. At this time, the thickness of the thick film sacrificial member to be stacked is larger than the first thickness D1 and is, for example, equal to the second thickness D2. After step S107, a step in which a part of the thick film sacrificial member is removed through the hole CH is inserted. In the step of filling the hole CH with the sacrificial member 67, a portion where a part of the thick film sacrificial member was removed is filled with the sacrificial member 67. In step S109, the sacrificial members 62, 63, and 64 are removed, and at the same time, all the thick film sacrificial members are removed through the slit SH. In step S110, at the same time as the formation of the spacer SP of the member SLT, the insulating layer 49 is formed at the portion from which the thick film sacrificial member was removed. In step S111, a part of the insulating layer 48 is removed until the upper surface of the corresponding interconnect layer 22, 23, or 24 is exposed.

### 2. Second Embodiment

Next, a semiconductor memory device according to a second embodiment will be described. A semiconductor memory device 3 according to the second embodiment is different from a semiconductor memory device 3 according to the first embodiment in shapes of contacts in each memory cell array 10 and a configuration of a coupling portion with a corresponding contact in each of interconnect layers 22, 23, and 24. In the following description, description about configurations and manufacturing methods equivalent to those of the first embodiment will be omitted, and configurations different from those of the first embodiment will be mainly described.

### 2.1 Configurations

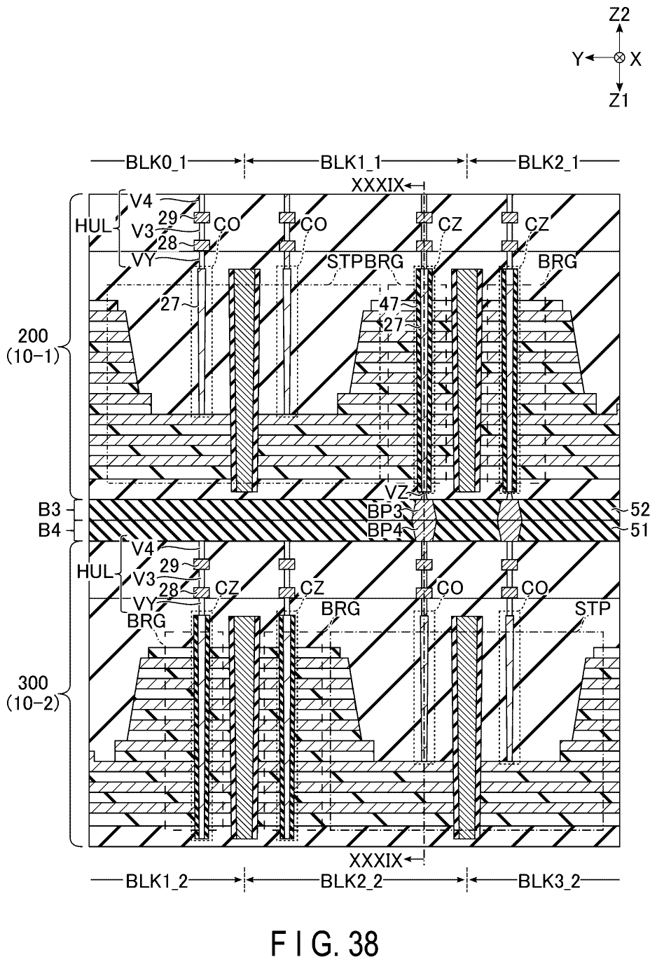

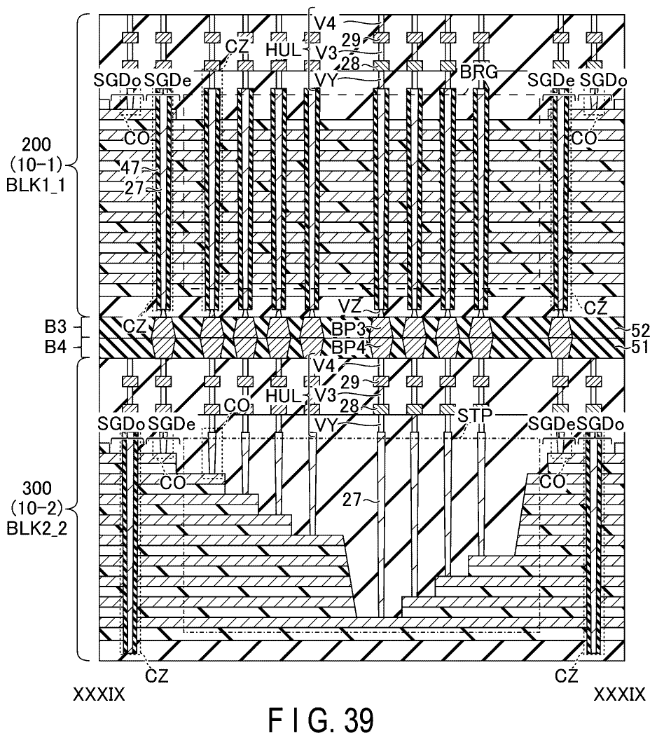

FIG. 38 is a sectional view illustrating an example of a sectional structure of a first memory layer, a second memory layer, and a joint layer provided between the first memory layer and the second memory layer included in the semiconductor memory device according to the second embodiment. FIG. 39 is a sectional view taken along line XXXIX-XXXIX in FIG. 38, illustrating an example of a sectional structure of the first memory layer, the second memory layer, and a joint layer provided between the first memory layer and the second memory layer included in the semiconductor memory device according to the second embodiment. FIGS. 38 and 39 correspond to FIGS. 13 and 15 in the first embodiment. Each memory cell array 10 included in the semiconductor memory device 3 according to the second embodiment includes a plurality of contacts CO and CZ instead of a plurality of contacts CC and CX. In addition, the interconnect layers 22, 23, and 24 included in each memory cell array 10 do not include a thick film portion, and have substantially the same thickness in a Z direction.

As illustrated in FIGS. 38 and 39, the plurality of contacts CO are provided at positions where the plurality of contacts CC are provided in each memory cell array 10 included in the semiconductor memory device 3 according to the first embodiment. The contact CO is a contact electrically coupled to one of the interconnect layers 22 to 24 included in the corresponding memory cell array 10. The contact CZ is a contact that is insulated from the interconnect layers 22 to 24 included in the corresponding memory cell array 10 and passes through a stacked interconnect in the Z direction. The plurality of contacts CZ provided in a memory cell array 10-1 function as interconnects PW that couple the plurality of contacts CO provided in a memory cell array 10-2 and a row decoder module 16 provided in a control circuit layer 100. Each memory cell array 10 has a two-lane contact structure by the plurality of contacts CO and CZ.

Each of the plurality of contacts CO extends in the Z direction and is in contact with a terrace portion of the corresponding interconnect layer 22, 23, or 24 at the bottom portion. That is, the plurality of contacts CO are not through contacts. Each of the plurality of contacts CZ is a through contact extending in the Z direction, insulated from the interconnect layers 22 to 24 included in the memory cell array 10, and passing through the stacked interconnect in the Z direction.

An upper surface of each of the contacts CO and CZ is in contact with a corresponding contact VY. A lower surface of each contact CZ in the memory cell array 10-1 is in contact with a corresponding contact VZ. The lower surface of each contact CZ in the memory cell array 10-2 is provided in an insulating layer 40. Each of the contacts CO and CZ has, for example, a larger sectional area (XY sectional area) along an XY plane from the lower side toward the upper side.

Each of the plurality of contacts CO and CZ includes a conductor 27. The conductor 27 functions as a conductive portion of the contacts CO and CZ. The conductor 27 contains, for example, tungsten or molybdenum.

The conductor 27 included in each contact CO is in contact with the contact VY at an upper end and in contact with any one of the interconnect layers 22, 23, and 24 at a lower end. The interconnect layer 22, 23, or 24 to which the conductor 27 included in each contact CO is coupled is the interconnect layer 22, 23, or 24 corresponding to the contact CO. The conductor 27 included in each contact CO couples the interconnect layer 22, 23, or 24 corresponding to the contact CO and the contact VY.

The conductor 27 included in each contact CZ is not electrically coupled to all of the interconnect layers 22, 23, and 24 included in the memory cell array 10. The conductor 27 included in each contact CZ is in contact with the contact VY at the upper end, and the lower end is provided inside the insulating layer 40. The conductor 27 included in each contact CZ provided in the memory cell array 10-1 is in contact with the corresponding contact VZ at the lower end. The conductor 27 included in each contact CZ provided in the memory cell array 10-1 couples the contacts VY and VZ.

Each of the plurality of contacts CZ includes an insulator 47. The insulator 47 includes, for example, silicon oxide. The insulator 47 included in each contact CZ is provided so as to surround the side surface of the conductor 27. The insulator 47 insulates the conductor 27 from the interconnect layers 22, 23, and 24.

Note that the configuration of the contact CO is not limited to the above configuration as long as the contact CO is coupled to the corresponding interconnect layer 22, 23, or 24 and is insulated from the other interconnect layer 22, 23, or 24.

The contact CZ included in the memory cell array 10-1 is coupled to a plurality of joint pads BP3 provided in a joint layer B3 on the lower surface side of the memory cell array 10-1 via the contact VZ. The contact CO included in the memory cell array 10-2 is coupled to a plurality of joint pads BP4 on the upper surface side of the memory cell array 10-2 via an upper layer interconnect HUL. At the boundary between the joint layers B3 and B4, the joint pads BP3 and BP4 are disposed to face each other and are coupled to each other in the Z direction. The contact CZ included in the memory cell array 10-1 is coupled to the contact CO included in the memory cell array 10-2 via the joint pads BP3 and BP4. In a case where the contact CZ is formed on one side at a position where the memory cell arrays 10-1 and 10-2 overlap in the Z direction, the contact CO is formed on the other side. Note that the contact CZ formed in the memory cell array 10-2 is not coupled to the contact CO formed in the memory cell array 10-1. That is, the contact CZ formed in the memory cell array 10-2 becomes a dummy contact. For example, the upper layer interconnect HUL corresponding to the contact CZ formed in the memory cell array 10-2 may be omitted.

In the two bonded memory cell arrays 10, the contact CO provided in a stepped area STP of one memory cell array 10 and the contact CZ provided in a bridge area BRG of the other memory cell array 10 correspond to each other and are provided at positions overlapping each other in the approximately Z direction.

As illustrated in FIG. 39, in terrace portions of select gate lines SGD provided at the positions overlapping each other in the Z direction of the memory cell arrays 10-1 and 10-2, the positions where the contacts CO corresponding to the respective select gate lines SGD are provided are shifted in the X direction and do not overlap each other in the Z direction. In a section illustrated in FIG. 39, since the memory cell array 10-1 corresponds to a block BLK1, the contact CO is provided in an outer contact area SGDo, and the contact CZ is provided in an inner contact area SGDe. On the other hand, since the memory cell array 10-2 corresponds to a block BLK2, the contact CZ is provided in the outer contact area SGDo, and the contact CO is provided in the inner contact area SGDe. In the inner contact area SGDe where the contact CO is provided in the memory cell array 10-2, the contacts CO and CZ provided at positions overlapping each other in the Z direction are coupled to each other via the joint pads BP3 and BP4, the contact VZ, and the upper layer interconnect HUL provided in the memory cell array 10-2.

### 2.2 Manufacturing Process

A manufacturing process of the memory cell array 10 included in the semiconductor memory device 3 according to the second embodiment is different from a manufacturing process of the first embodiment in a manufacturing process of the contacts CO and CZ. Hereinafter, the manufacturing process will be described.

The processing of S103 and the processing of S105 forming the thick film portion illustrated in FIG. 18 is omitted, and after the processing of S104 ends, a plurality of contacts CZ are formed. Specifically, a hole corresponding to each of the plurality of contacts CZ is formed, and an inner wall of the hole is covered with the insulator 47. Thereafter, the conductor 27 is provided inside the hole. The plurality of contacts CZ may be formed as vias passing through the interconnect layers 22, 23, and 24 and the insulating layers 41, 42, 43, 44, and 45 in the Z direction.

Next, a hole corresponding to each of the plurality of contacts CO is formed. Each of the plurality of holes has a different length in the Z direction depending on the corresponding interconnect layer 22, 23, or 24. At the bottom portion of each of the plurality of holes, the corresponding sacrificial member 62, 63, or 64 is exposed.

Thereafter, in the processing of S109, when the stacked interconnect is replaced, a metal corresponding to the conductor 27 is also poured into the holes corresponding to the plurality of contacts CO. As a result, the plurality of contacts CO are formed. Further, the processing of S111 is omitted.

### 2.3 Effects According to Second Embodiment

According to the second embodiment, similarly to the first embodiment, the degree of integration of the semiconductor memory device 3 can be improved.

Further, according to the second embodiment, since the plurality of contacts CO are not through contacts, the contacts CO do not pass through an interconnect layer different from the corresponding interconnect layer. Therefore, it is possible to suppress a short circuit due to unintentional coupling of the contact with an interconnect layer different from the corresponding interconnect layer.

### 2.4 Modifications

The semiconductor memory device 3 according to the second embodiment described above can be variously modified. Hereinafter, differences from the second embodiment will be described as to a first modification and a second modification of the second embodiment.

### 2.4.1 First Modification

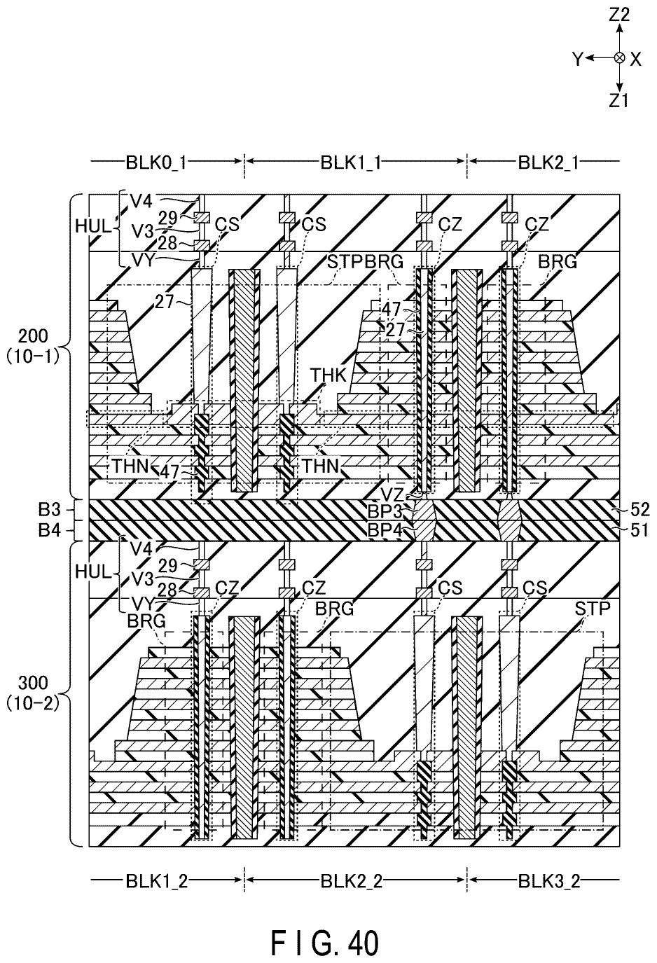

FIG. 40 is a sectional view illustrating an example of a sectional structure of a first memory layer, a second memory layer, and a joint layer provided between the first memory layer and the second memory layer included in a semiconductor memory device according to the first modification of the second embodiment. A memory cell array 10 included in a semiconductor memory device 3 according to the first modification of the second embodiment includes a plurality of contacts CS instead of the plurality of contacts CO. Similarly to the memory cell array 10 included in the semiconductor memory device 3 according to the first embodiment, each of the interconnect layers 22, 23, and 24 includes a thick film portion THK and a thin film portion THN.

Each of the plurality of contacts CS includes a conductor 27 and an insulator 47. The conductor 27 included in the plurality of contacts CS is in contact with the corresponding contact VY on the upper surface and in contact with the insulator 47 on the bottom surface. The conductor 27 included in the plurality of contacts CS is in contact with the thick film portion THK of the corresponding interconnect layer 22, 23, or 24 in the XY plane direction in the vicinity of the bottom portion. The conductor 27 included in the plurality of contacts CS passes through the insulating layer 45 in the Z direction, and does not pass through the interconnect layers 22, 23, and 24 other than the corresponding interconnect layer 22, 23, or 24 and the insulating layers 41, 42, 43, and 44 in the Z direction. The insulator 47 included in the plurality of contacts CS extends in the Z direction and extends through the interconnect layers 22 and 23 and the insulating layers 41, 42, and 43 provided below the interconnect layers 22, 23, or 24 corresponding to the contacts CS. The insulator 47 has a protrusion extending in the radial direction along the XY plane direction in a portion passing through the insulating layers 41, 42, and 43 in the Z direction. The insulator 47 is in contact with the conductor 27 at the upper end, and the lower end is provided inside the insulating layer 40.

The manufacturing process of the memory cell array 10 according to the first modification of the second embodiment will be described with respect to differences from the manufacturing process of the memory cell array 10 according to the first embodiment. When the processing of S106 is performed, the peripheral portions exposed to the side surfaces of the holes CH of the insulating layers 41, 42, 43, 44, and 45 are removed by wet etching instead of the step of removing a part of the sacrificial members 62, 63, and 64 after forming the plurality of holes CH corresponding to the plurality of contacts CS. In this way, a plurality of grooves in which the insulating layers 41, 42, 43, 44, and 45 are recessed in the radial direction along the XY plane direction with respect to the insulating layer 40 and the sacrificial members 62, 63, and 64 are formed on the side surfaces of the holes CH. Thereafter, the insulator 47 is embedded in the hole CH by the processing of S107, and a part of the insulator 47 is removed by further wet etching. At this time, the insulator 47 embedded in the lower layer of the portion where the sacrificial member 62, 63, or 64 through which the hole CH passes was thickened is not removed. Thereafter, the sacrificial member 67 is embedded in the hole CH. The sacrificial member 67 is in contact with a portion where the corresponding sacrificial member 62, 63, or 64 was thickened at the bottom portion. Thereafter, the sacrificial member 67 is replaced with the conductor 27 by the processing of S111, whereby the conductor 27 is coupled to the corresponding interconnect layer 22, 23, or 24.

### 2.4.2 Second Modification

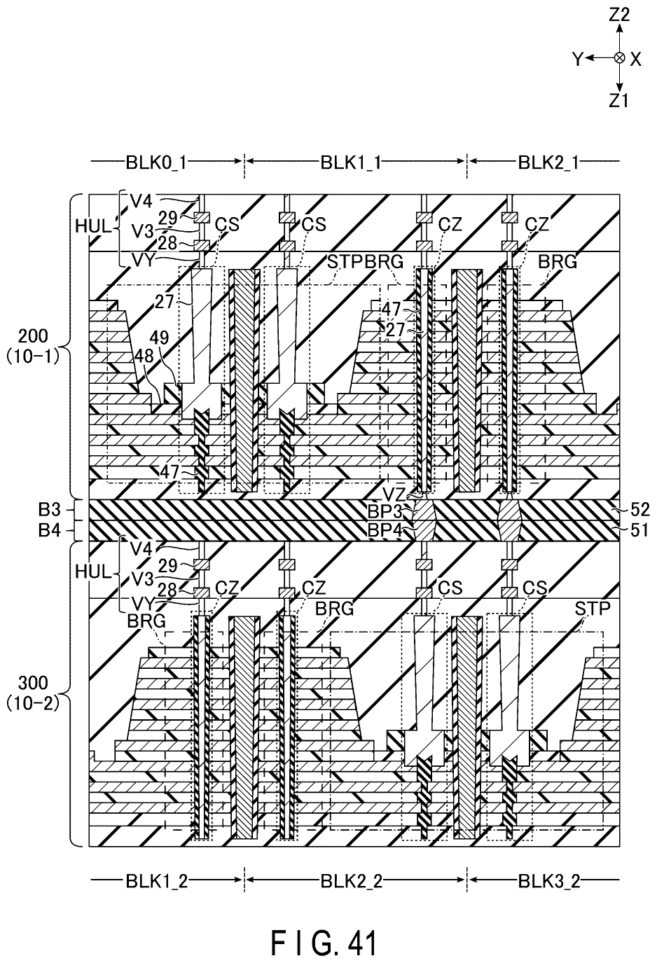

FIG. 41 is a sectional view illustrating an example of a sectional structure of a first memory layer, a second memory layer, and a joint layer provided between the first memory layer and the second memory layer included in a semiconductor memory device according to a second modification of the second embodiment. A memory cell array 10 included in a semiconductor memory device 3 according to the second modification of the second embodiment includes a plurality of contacts CS instead of the plurality of contacts CO. The memory cell array 10 further includes insulating layers 48 and 49. The insulating layers 48 and 49 contain, for example, silicon oxide.

Each of the plurality of contacts CS includes a conductor 27 and an insulator 47. The conductor 27 included in the plurality of contacts CS is in contact with the corresponding contact VY on the upper surface and in contact with the insulator 47 on the bottom surface. The conductor 27 included in the plurality of contacts CS is in contact with the corresponding interconnect layer 22, 23, or 24 in the Z direction in the vicinity of the bottom portion. The conductor 27 included in the plurality of contacts CS passes through the insulating layers 45, 48, and 49 in the Z direction, and does not pass through the interconnect layers 22, 23, and 24 and the insulating layers 41, 42, 43, and 44 in the Z direction. The insulator 47 included in the plurality of contacts CS extends in the Z direction and extends through the interconnect layers 22 and 23 and the insulating layers 41, 42, and 43 provided below the interconnect layers 22, 23, or 24 corresponding to the contacts CS. The insulator 47 has a protrusion extending in the radial direction along the XY plane direction in a portion passing through the insulating layers 41, 42, and 43 in the Z direction. The insulator 47 is in contact with the conductor 27 at the upper end, and the lower end is provided inside the insulating layer 40.

The manufacturing process of the memory cell array 10 according to the second modification of the second embodiment will be described with respect to differences from the manufacturing process of the memory cell array 10 according to the first modification of the second embodiment. First, S103 is omitted, and instead, a step of stacking the insulating layer 48 and the thick film sacrificial member in this order is inserted. The thick film sacrificial member includes, for example, silicon nitride. The thick film sacrificial member stacked at this time is larger than the first thickness D1 and is, for example, equal to the second thickness D2. After the insulator 47 is embedded, a step of removing a part of the thick film sacrificial member through the hole CH is inserted. In the step of filling the hole CH with the sacrificial member 67, a portion where a part of the thick film sacrificial member was removed is filled with the sacrificial member 67. In step S109, the sacrificial members 62, 63, and 64 are removed, and at the same time, all the thick film sacrificial members are removed through the slit SH. In step S110, at the same time as the formation of the spacer SP of the member SLT, the insulating layer 49 is formed at the portion from which the thick film sacrificial member was removed. In step S111, a part of the insulating layer 48 is removed until the upper surface of the corresponding interconnect layer 22, 23, or 24 is exposed.

### 3. Third Embodiment

Next, a semiconductor memory device according to a third embodiment will be described. A semiconductor memory device 3 according to the third embodiment is different from a semiconductor memory device 3 according to the first embodiment in a stepped structure in each memory cell array 10. In the following description, description about configurations equivalent to those of the first embodiment will be omitted, and configurations different from those of the first embodiment will be mainly described.

### 3.1 Structure of Memory Cell Array

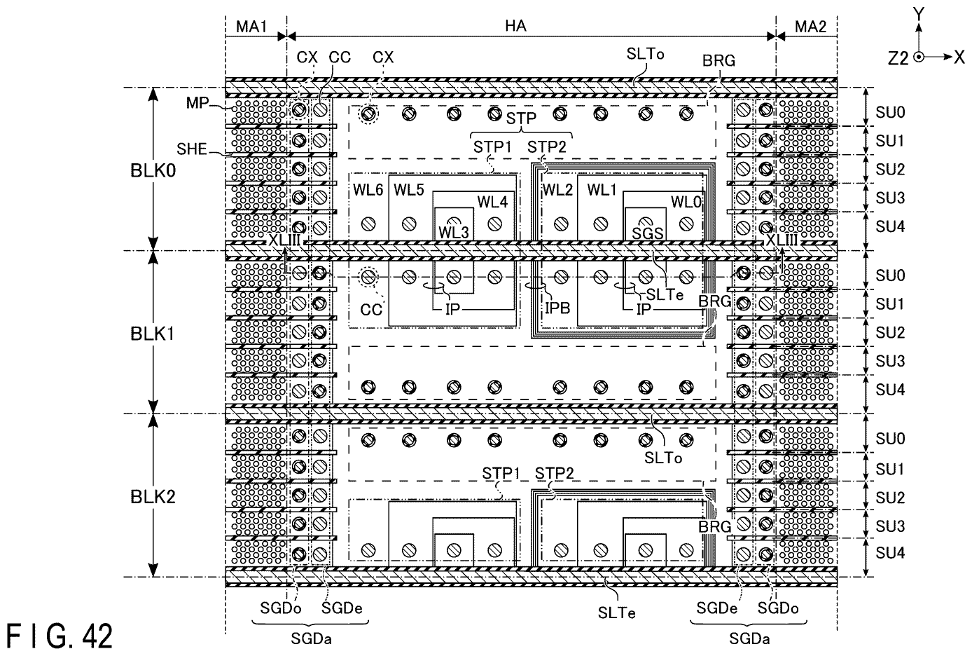

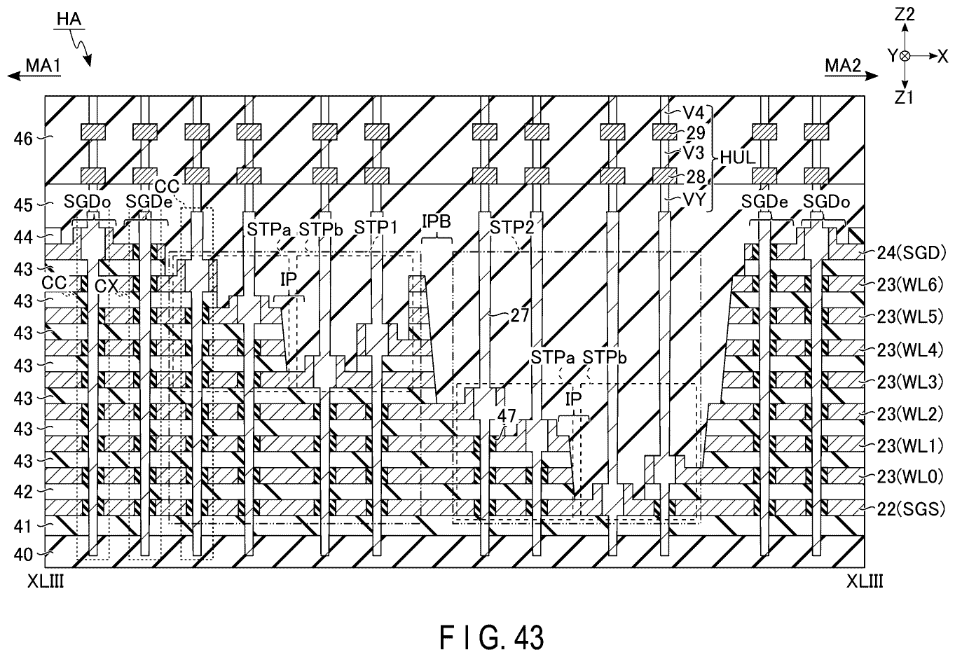

FIG. 42 is a plan view illustrating an example of a planar layout in a hookup area of the memory cell array included in the semiconductor memory device according to the third embodiment. FIG. 42 illustrates areas corresponding to three blocks BLK0 to BLK2. FIG. 43 is a sectional view taken along line XLIII-XLIII in FIG. 42 in the hookup area of the memory cell array included in the semiconductor memory device according to the third embodiment. FIG. 43 illustrates XZ sections of a hookup area HA of the block BLK1 and contacts CC and CX.

As illustrated in FIGS. 42 and 43, each memory cell array 10 includes an inclined portion IPB in the hookup area HA. The inclined portion IPB is an end surface provided in a rectangular shape in plan view and including end portions of a plurality of interconnect layers 23 continuously stacked. A part of the inclined portion IPB is provided to cross the stepped area STP in a Y direction. In the inclined portion IPB, the end portions of the plurality of interconnect layers 23 continuously stacked are inclined at substantially the same inclination angle in an oblique direction on an XZ plane and a YZ plane and form an inclined surface. The inclined portion IPB divides the stepped area STP into stepped areas STP1 and STP2.

The stepped area STP1 is an area outside the inclined portion IPB in the stepped area STP. The stepped area STP2 is an area inside the inclined portion IPB of the stepped area STP. The stepped areas STP1 and STP2 are provided so as to straddle a member SLTe in the Y direction and are arranged in the X direction. A stadium-shaped stepped structure is provided in each of the stepped areas STP1 and STP2. In the stepped area STP1, for example, terrace portions corresponding to word lines WL3 to WL6 are provided. In the stepped area STP2, for example, terrace portions corresponding to a select gate line SGS and word lines WL0 to WL2 are provided. A plurality of contacts CC are provided corresponding to the respective terrace portions of each stadium-shaped stepped structure.

In the stepped areas STP1 and STP2, an inclined portion IP and stepped areas STPa and STPb divided by the inclined portion IP are provided, respectively. The stepped area STPa is an area outside the inclined portion IP. In the stepped area STPa, a stadium-shaped stepped structure ascending in a direction toward a memory area MA1 is provided. The stepped area STPb is an area inside the inclined portion IP. In the stepped area STPb, a stadium-shaped stepped structure ascending in a direction toward the memory area MA2 is provided.

The number of interconnect layers 23 constituting the end surface in each inclined portion IP is smaller than the number of interconnect layers 23 constituting the end surface in the inclined portion IPB. In the example illustrated in FIGS. 42 and 43, the inclined portion IPB is an end surface including the end portions of the four interconnect layers 23 continuously stacked, whereas each inclined portion IP is an end surface including the end portions of the two interconnect layers 23 continuously stacked.

The memory cell arrays 10-1 and 10-2 formed respectively are bonded in the Z direction similarly to the first embodiment.

### 3.2 Effects

According to the third embodiment, similarly to the first embodiment, the degree of integration of the semiconductor memory device 3 can be improved.

In addition, according to the third embodiment, it is possible to arrange a plurality of stadium-shaped stepped structures having different interconnect layers 22 to 24 in the same block BLK in the X direction. Since each stadium-shaped stepped structure is formed in the same process, the overall number of processes is reduced, and an increase in manufacturing cost of the memory cell array 10 can be suppressed.

### 3.3 Modifications

The semiconductor memory device 3 according to the third embodiment described above can be variously modified. For example, modifications corresponding to the first to third modifications of the first embodiment and modifications corresponding to the second embodiment and the first and second modifications of the second embodiment may be applied to the semiconductor memory device 3 according to the third embodiment.

### 4. Fourth Embodiment

Next, a semiconductor memory device according to a fourth embodiment will be described. A semiconductor memory device 3 according to the fourth embodiment is different from a semiconductor memory device 3 according to the first embodiment in a stepped structure in each memory cell array 10. In the following description, description about configurations equivalent to those of the first embodiment will be omitted, and configurations different from those of the first embodiment will be mainly described.

### 4.1 Structure of Memory Cell Array

### 4.1.1 Overview

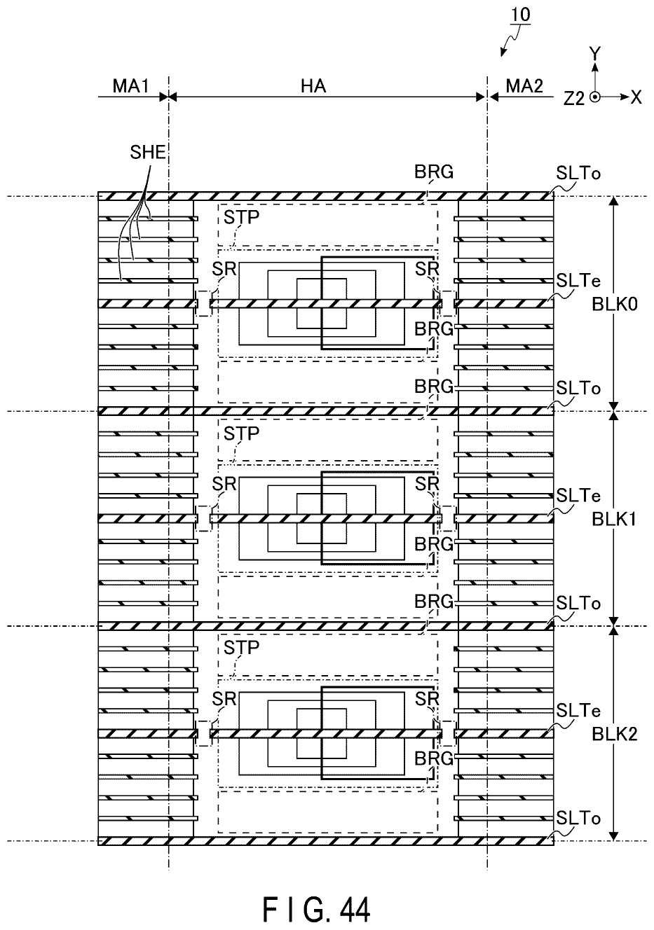

FIG. 44 is a plan view illustrating an example of a planar layout of the memory cell array included in the semiconductor memory device according to the fourth embodiment. FIG. 44 illustrates areas corresponding to three blocks BLK0 to BLK2.

In the fourth embodiment, each of the areas partitioned by a plurality of members SLTo included in each memory cell array 10 corresponds to one block BLK in each memory cell array 10. Each member SLTo divides the stacked interconnect adjacent to each other with the member SLTo interposed therebetween.

A plurality of members SLTe included in each memory cell array 10 according to the fourth embodiment are divided into a plurality of portions in an X direction in one or more divided areas SR provided in a hookup area HA. In the example illustrated in FIG. 44, the member SLTe is divided into three portions in the X direction by the two divided areas SR. That is, the member SLTe is divided in the divided area SR, so that each of a plurality of interconnect layers 22 and 23 corresponding to the select gate line SGS and the word lines WL0 to WL6 is not divided in the Y direction. In other words, the interconnect layers 22 and 23 adjacent to each other in the Y direction with the member SLTe interposed therebetween are coupled to each other in the Y direction via the divided area SR. That is, the divided area SR is a coupling area of the interconnect layers 22 and 23 adjacent to each other in the Y direction with the member SLTe interposed therebetween.

The hookup area HA includes one stepped area STP and two bridge areas BRG in one block BLK. The stepped area STP is provided so as to straddle the member SLTe. In each block BLK, the bridge area BRG is provided between the stepped area STP and two members SLTo provided so as to sandwich the block BLK.

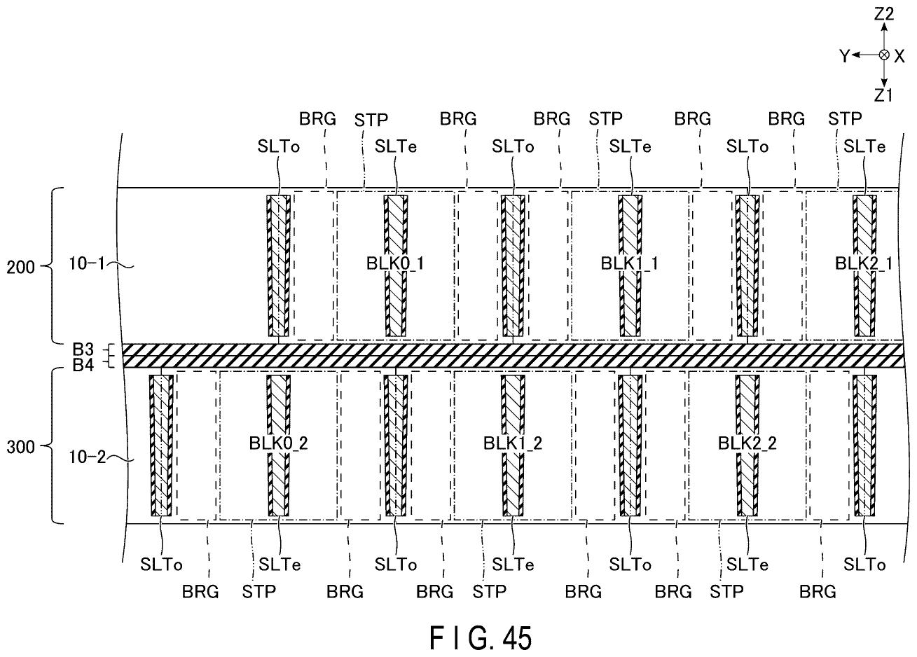

FIG. 45 is a schematic sectional view schematically illustrating an example of a sectional structure of a first memory layer and a second memory layer that are bonded together, which are included in the semiconductor memory device according to the fourth embodiment. FIG. 45 illustrates a first memory layer 200 and a second memory layer 300, and joint layers B3 and B4. As illustrated in FIG. 45, a memory cell array 10-1 of the first memory layer 200 and a memory cell array 10-2 of the second memory layer 300 are bonded to each other in the Z direction while being shifted in the Y direction by a half block BLK via the joint layers B3 and B4.

Specifically, a block BLKi_1 of the memory cell array 10-1 is provided above a block BLKi_2 and a block BLK(i+1)_2 of the memory cell array 10-2, and the block BLK(i+1)_2 of the memory cell array 10-2 is provided below the block BLKi_1 and the block BLK(i+1)_1 of the memory cell array 10-1 (i is an integer satisfying 0≤i≤n−1). A dummy block is not provided.

The member SLTe of the memory cell array 10-1 is provided above the member SLTo of the memory cell array 10-2. The member SLTo of the memory cell array 10-1 is provided above the member SLTe of the memory cell array 10-2. That is, the members SLTo and SLTe are provided so as to overlap each other one by one in the Z direction.

The stepped area STP of the memory cell array 10-1 and the stepped area STP of the memory cell array 10-2 are provided side by side in the Y direction at positions different from each other in the Z direction. Specifically, the bridge area BRG of the memory cell array 10-2 is provided below the stepped area STP of the memory cell array 10-1. The bridge area BRG of the memory cell array 10-1 is provided above the stepped area STP of the memory cell array 10-2. That is, in the vicinity of the member SLT, in a case where the stepped area STP is provided and a stepwise structure is formed in one of the memory cell arrays 10-1 and 10-2 at positions overlapping each other in the Z direction, a structure in which the bridge area BRG is provided and the plurality of interconnect layers 22 and 23 are stacked is formed in the other of the memory cell arrays 10-1 and 10-2.

### 4.1.2 Planar Layout

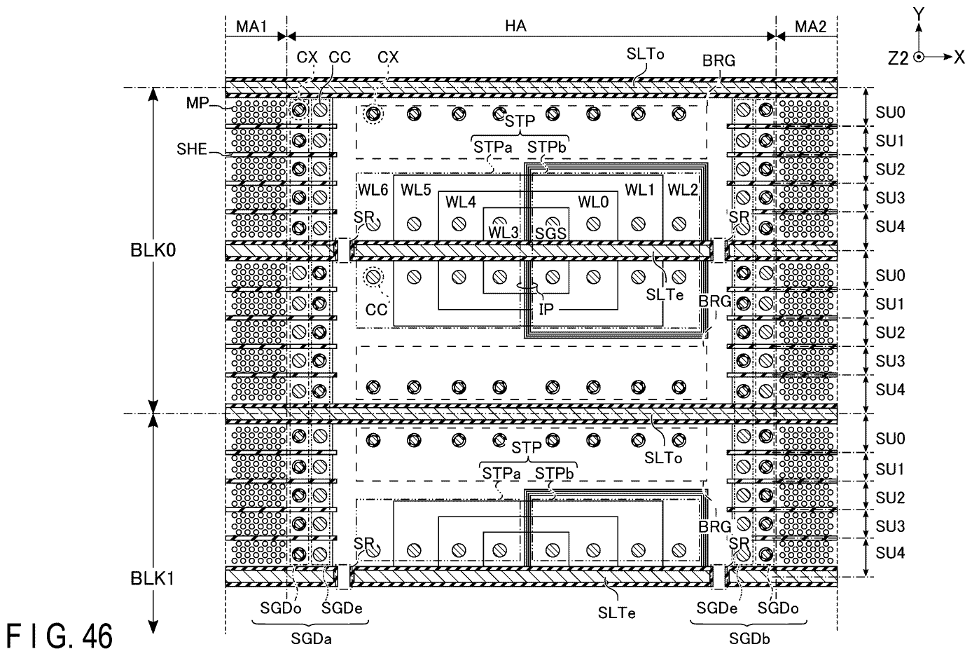

FIG. 46 is a plan view illustrating an example of a planar layout in a hookup area of the memory cell array included in the semiconductor memory device according to the fourth embodiment. In FIG. 46, areas corresponding to the block BLK0 and a part of the block BLK1 are illustrated.

As illustrated in FIG. 46, each of a first portion SGDa and a second portion SGDb of the select gate line SGD is divided into 10 portions in one block BLK by the members SLTe and SHE. Each of the first portion SGDa and the second portion SGDb of the select gate line SGD has two portions, each of which corresponds to string units SU0 to SU4 in one block BLK. For each portion of the select gate line SGD divided into 10 portions, one of contacts CC and CX is provided in each of an inner contact area SGDe and an outer contact area SGDo. Specifically, for example, in the select gate line SGD provided above the member SLTe provided so as to cross the block BLK on the paper, the contact CC is provided in the inner contact area SGDe, and the contact CX is provided in the outer contact area SGDo. In the select gate line SGD provided below the member SLTe provided so as to cross the block BLK on the paper, the contact CX is provided in the inner contact area SGDe, and the contact CC is provided in the outer contact area SGDo.

Note that the structure of the select gate line SGD is not limited to the above structure. For example, each of the first portion SGDa and the second portion SGDb of the select gate line SGD may include one portion corresponding to the string units SU0 to SU4.

In the stepped area STP in one block BLK, two corresponding contacts CC are provided for each of the select gate line SGS and the word lines WL0 to WL6. Specifically, for example, a set of two contacts CC corresponding to the same interconnect layer 22 or 23 is provided at substantially symmetrical positions with respect to the member SLTe, and a plurality of contacts CC constituting each set is arranged in the X direction. In each of the two bridge areas BRG, a plurality of contacts CX are provided side by side in the X direction.

### 4.2 Effects

According to the fourth embodiment, similarly to the first embodiment, the degree of integration of the semiconductor memory device 3 can be improved.

According to the fourth embodiment, two contacts CC corresponding to each interconnect layer 22 or 23 are provided. As a result, it is possible to reduce the electrical resistance in interconnects that mediate each interconnect layer 22 or 23 and a row decoder module 16. Therefore, the read speed and the write speed of the semiconductor memory device 3 can be improved.

### 4.3 Modifications

The semiconductor memory device 3 according to the fourth embodiment described above can be variously modified. For example, modifications corresponding to the first to third modifications of the first embodiment and modifications corresponding to the second embodiment and the first and second modifications of the second embodiment may be applied to the semiconductor memory device 3 according to the fourth embodiment.

### 5. Fifth Embodiment

Next, a semiconductor memory device according to a fifth embodiment will be described. A semiconductor memory device 3 according to the fifth embodiment is different from a semiconductor memory device 3 according to the first embodiment in a stepped structure in each memory cell array 10. In the following description, description about configurations equivalent to those of the first embodiment will be omitted, and configurations different from those of the first embodiment will be mainly described.

### 5.1 Configurations

In the semiconductor memory device 3 according to the fifth embodiment, each NAND string NS includes, for example, 15 memory cell transistors MT0 to MT14 and select transistors ST1 and ST2. The control gates of the memory cell transistors MT0 to MT14 in the same block BLK are coupled to word lines WL0 to WL14, respectively.

### 5.2 Structure of Memory Cell Array

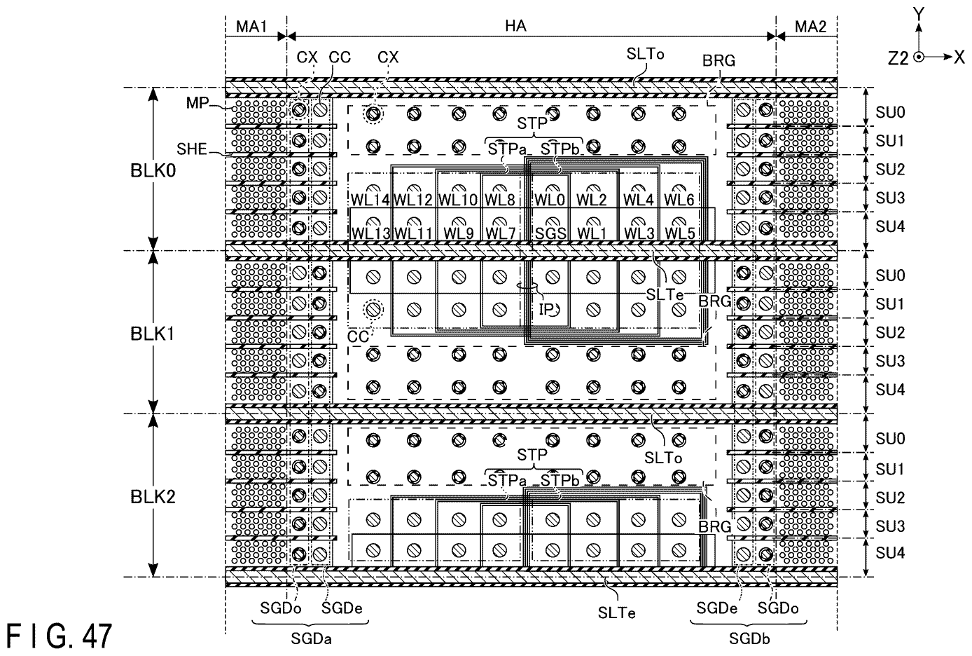

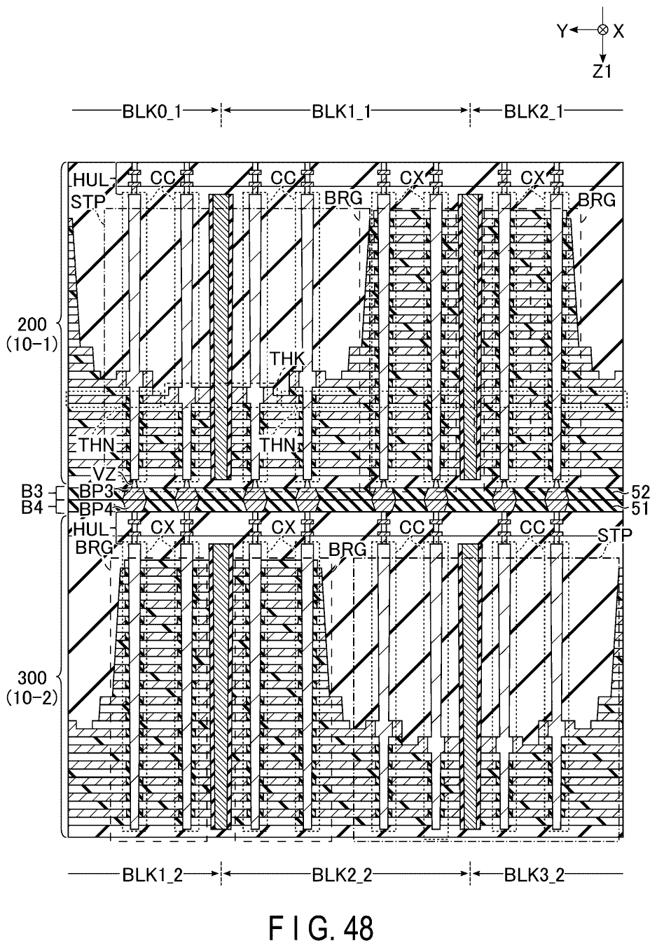

FIG. 47 is a plan view illustrating an example of a planar layout in a hookup area of the memory cell array included in the semiconductor memory device according to the fifth embodiment. FIG. 47 illustrates areas corresponding to three blocks BLK0 to BLK2. FIG. 48 is a sectional view illustrating an example of a sectional structure of a first memory layer, a second memory layer, and a joint layer provided between the first memory layer and the second memory layer included in the semiconductor memory device according to the fifth embodiment. In FIG. 48, areas corresponding to the blocks BLK0 to BLK2 in a memory cell array 10-1 and the blocks BLK1 to BLK3 in a memory cell array 10-2 are illustrated. The stacked interconnects in the memory cell arrays 10-1 and 10-2 illustrated in FIG. 48 correspond to the select gate line SGS and the word lines WL0 to WL14 in this order from the bottom.

As illustrated in FIGS. 47 and 48, the memory cell array 10 includes, for example, a two-column stepped structure having one step in the Y direction and two steps in the X direction stepwise in a stepped area STP. A plurality of contacts CC are provided corresponding to the respective terrace portions of the two-column stepped structures. In addition, a plurality of contacts CX are provided in a bridge area BRG.

The memory cell array 10 according to the fifth embodiment has a structure in which a plurality of contacts CC and CX are provided so as to be arranged for four rows in total, two rows each in the Y direction, in an area sandwiched between two members SLT in the Y direction. This structure is referred to as a “four-lane contact structure”.

In addition, each thick film portion THK in each of interconnect layers 22 and 23 is separated in the X direction from a side surface of a thick film portion THK of the interconnect layer 23 or 24 provided two layers above the interconnect layer 22 and 23. In addition, each thick film portion THK in each of the interconnect layers 22 and 23 is separated in the Y direction from the side surface of the thick film portion THK of the interconnect layer 23 or 24 provided one layer above the interconnect layer 22 and 23.

### 5.3 Effects

According to the fifth embodiment, similarly to the first embodiment, the degree of integration of the semiconductor memory device 3 can be improved. In addition, the memory cell array 10 according to the fifth embodiment includes a four-lane contact structure. With this structure, it is possible to further suppress an increase in the length of the memory cell array 10 in one direction (for example, the X direction) due to the terrace portions and the corresponding contacts CC in the interconnect layers 22 and 23 being arranged in the one direction, as compared with a two-lane contact structure. Therefore, the chip area of the semiconductor memory device 3 can be reduced (expansion can be suppressed), and the degree of integration can be further improved.

### 5.4 Modifications

The semiconductor memory device 3 according to the fifth embodiment described above can be variously modified. For example, modifications corresponding to the first to third modifications of the first embodiment and modifications corresponding to the second embodiment and the first and second modifications of the second embodiment may be applied to the semiconductor memory device 3 according to the fifth embodiment.

### 6. Sixth Embodiment

Next, a semiconductor memory device according to a sixth embodiment will be described. A semiconductor memory device 3 according to the sixth embodiment is different from a semiconductor memory device 3 according to the fifth embodiment in a stepped structure in each memory cell array 10. In the following description, description about configurations equivalent to those of the fifth embodiment will be omitted, and configurations different from those of the fifth embodiment will be mainly described.

### 6.1 Structure of Memory Cell Array

In each memory cell array 10 included in the semiconductor memory device 3 according to the sixth embodiment, similarly to the fourth embodiment, each of areas partitioned by a plurality of members SLTo included in each memory cell array 10 corresponds to one block BLK in each memory cell array 10. A plurality of members SLTe included in each memory cell array 10 are divided into a plurality of portions in an X direction in one or more divided areas SR provided in a hookup area HA. That is, the member SLTe is divided in the divided area SR, so that each of a plurality of interconnect layers 22 and 23 corresponding to a select gate line SGS and word lines WL0 to WL14 is not divided in a Y direction. In other words, the interconnect layers 22 and 23 adjacent to each other in the Y direction with the member SLTe interposed therebetween are coupled to each other in the Y direction via the divided area SR. That is, the divided area SR is a coupling area of the interconnect layers 22 and 23 adjacent to each other in the Y direction with the member SLTe interposed therebetween.

The hookup area HA includes one stepped area STP and two bridge areas BRG in one block BLK. The stepped area STP is provided so as to straddle the member SLTe. In each block BLK, the bridge area BRG is provided between the stepped area STP and two members SLTo provided so as to sandwich the block BLK.

In the semiconductor memory device 3 according to the sixth embodiment, similarly to the fourth embodiment, a memory cell array 10-1 of a first memory layer 200 and a memory cell array 10-2 of a second memory layer 300 are bonded in the Z direction to be shifted in the Y direction by a half block BLK via joint layers B3 and B4. The bonding structure of the memory cell arrays 10-1 and 10-2 of the semiconductor memory device 3 according to the sixth embodiment is substantially the same as the structure illustrated in FIG. 45 in the fourth embodiment.

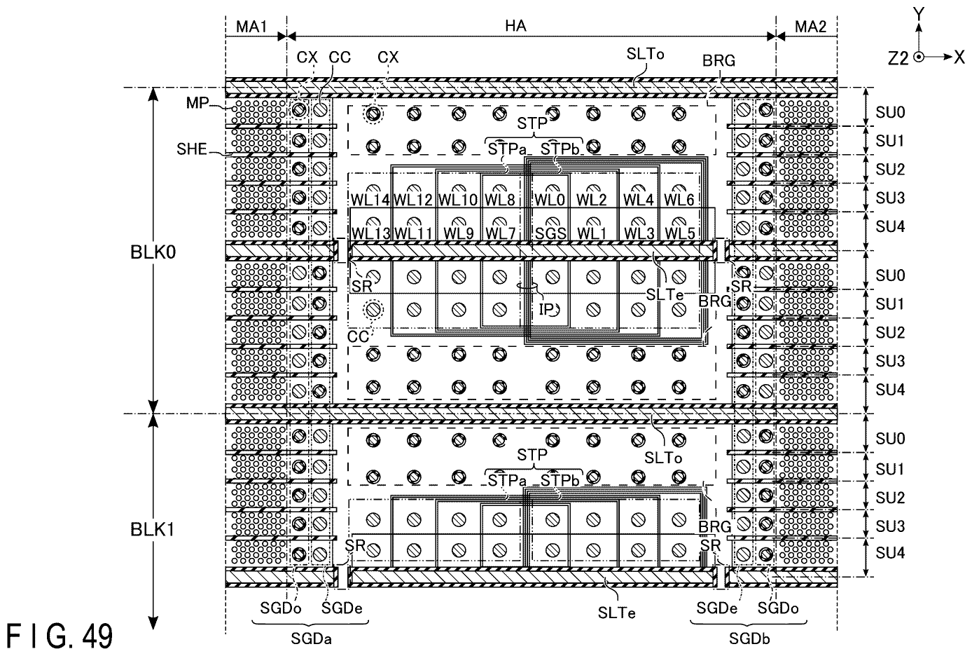

FIG. 49 is a plan view illustrating an example of a planar layout in a hookup area of the memory cell array included in the semiconductor memory device according to the sixth embodiment. In FIG. 49, areas corresponding to the block BLK0 and a part of the block BLK1 are illustrated.

As illustrated in FIG. 49, each of a first portion SGDa and a second portion SGDb of the select gate line SGD is divided into 10 portions in one block BLK by the members SLTe and SHE. Each of the first portion SGDa and the second portion SGDb of the select gate line SGD has two portions, each of which corresponds to string units SU0 to SU4 in one block BLK. For each portion of the select gate line SGD divided into 10 portions, one of contacts CC and CX is provided in each of an inner contact area SGDe and an outer contact area SGDo. Specifically, for example, in the select gate line SGD provided above the member SLTe provided so as to cross the block BLK on the paper, the contact CC is provided in the inner contact area SGDe, and the contact CX is provided in the outer contact area SGDo. In the select gate line SGD provided below the member SLTe provided so as to cross the block BLK on the paper, the contact CX is provided in the inner contact area SGDe, and the contact CC is provided in the outer contact area SGDo.

Note that the structure of the select gate line SGD is not limited to the above structure. For example, each of the first portion SGDa and the second portion SGDb of the select gate line SGD may include one portion corresponding to the string units SU0 to SU4.

In the stepped area STP in one block BLK, two corresponding contacts CC are provided for each of the select gate line SGS and the word lines WL0 to WL14. Specifically, for example, a set of two contacts CC corresponding to the same interconnect layer 22 or 23 is provided at substantially symmetrical positions with respect to the member SLTe, and a plurality of contacts CC constituting each set is arranged in the X direction. In each of the two bridge areas BRG, two rows of contacts CX are provided side by side in the X direction.

### 6.2 Effects

According to the sixth embodiment, similarly to the fifth embodiment, the degree of integration of the semiconductor memory device 3 can be improved.

According to the sixth embodiment, two contacts CC corresponding to each interconnect layer 22 or 23 are provided. As a result, it is possible to reduce the electrical resistance in interconnects that mediate each interconnect layer 22 or 23 and a row decoder module 16. Therefore, the read speed and the write speed of the semiconductor memory device 3 can be improved.

### 6.3 Modifications

The semiconductor memory device 3 according to the sixth embodiment described above can be variously modified. For example, modifications corresponding to the first to third modifications of the first embodiment and modifications corresponding to the second embodiment and the first and second modifications of the second embodiment may be applied to the semiconductor memory device 3 according to the sixth embodiment.

### 7. Seventh Embodiment

Next, a semiconductor memory device according to a seventh embodiment will be described. A semiconductor memory device 3 according to the seventh embodiment is different from a semiconductor memory device 3 according to the fifth embodiment in a stepped structure in each memory cell array 10. In the following description, description about configurations equivalent to those of the fifth embodiment will be omitted, and configurations different from those of the fifth embodiment will be mainly described.

### 7.1 Structure of Memory Cell Array

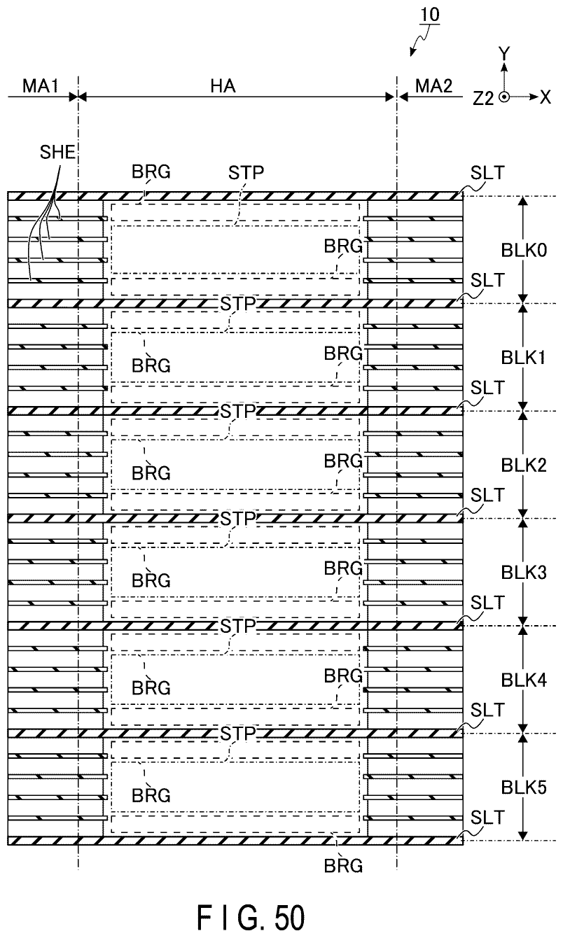

FIG. 50 is a plan view illustrating an example of a planar layout of the memory cell array included in the semiconductor memory device according to the seventh embodiment. FIG. 50 illustrates areas corresponding to six blocks BLK0 to BLK5.

In the seventh embodiment, each of the areas partitioned by a plurality of members SLT included in each memory cell array 10 corresponds to one block BLK in each memory cell array 10. Each member SLT divides the stacked interconnect adjacent to each other with the member SLT interposed therebetween.

The hookup area HA includes one stepped area STP and two bridge areas BRG in one block BLK. The stepped area STP is provided at the center in the Y direction of the hookup area HA in each block BLK. The two bridge areas BRG are provided at positions sandwiched between the stepped area STP and the two members SLT adjacent to the block BLK in the Y direction.

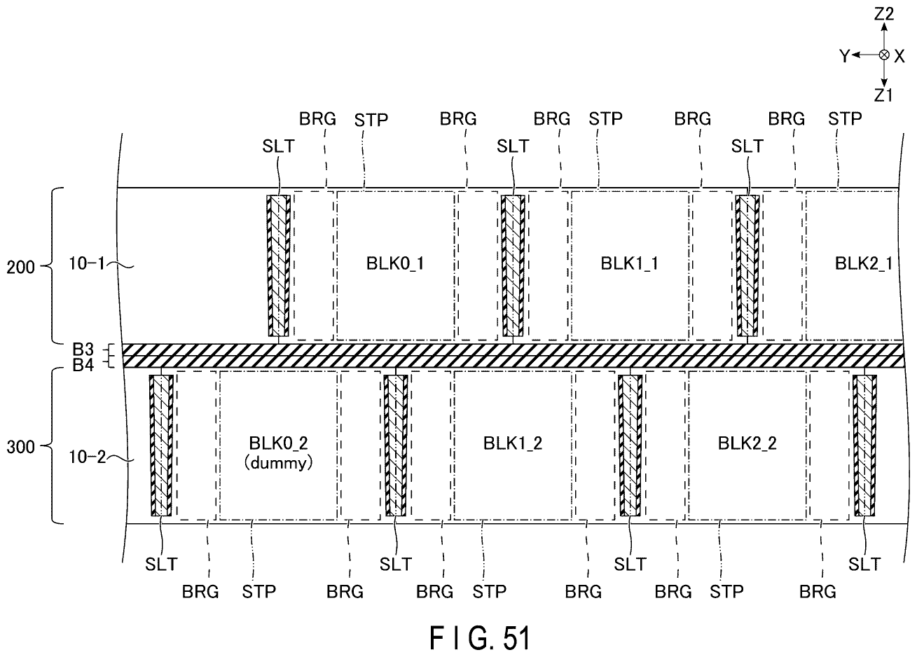

FIG. 51 is a schematic sectional view schematically illustrating an example of a sectional structure of a first memory layer and a second memory layer that are bonded together, which are included in the semiconductor memory device according to the seventh embodiment. FIG. 51 illustrates a first memory layer 200 and a second memory layer 300, and joint layers B3 and B4. As illustrated in FIG. 51, a memory cell array 10-1 of the first memory layer 200 and a memory cell array 10-2 of the second memory layer 300 are bonded to each other in the Z direction while being shifted in the Y direction by a half block BLK via the joint layers B3 and B4.

Specifically, a block BLKi_1 of the memory cell array 10-1 is provided above a block BLKi_2 and a block BLK(i+1)_2 of the memory cell array 10-2, and the block BLK(i+1)_2 of the memory cell array 10-2 is provided below the block BLKi_1 and the block BLK(i+1)_1 of the memory cell array 10-1 (i is an integer satisfying 0≤i≤n−1). A block BLK0_2 of the memory cell array 10-2 and a block BLKn_1 of the memory cell array 10-1 are dummy blocks.

A stepped area STP of the memory cell array 10-1 is provided above the member SLT of the memory cell array 10-2. A stepped area STP of the memory cell array 10-2 is provided below the member SLT of the memory cell array 10-1. That is, the member SLT of one of the memory cell arrays 10-1 and 10-2 overlaps the stepped area STP of the other of the memory cell.

The stepped area STP of the memory cell array 10-1 and the stepped area STP of the memory cell array 10-2 are provided side by side in the Y direction at different positions in the Z direction in plan view. Specifically, the bridge area BRG of the memory cell array 10-2 is provided below the stepped area STP of the memory cell array 10-1. The bridge area BRG of the memory cell array 10-1 is provided above the stepped area STP of the memory cell array 10-2. That is, in a case where the stepped area STP is provided and a stepwise structure is formed in one of the memory cell arrays 10-1 and 10-2 at positions overlapping each other in the Z direction, a structure in which the bridge area BRG is provided and the plurality of interconnect layers 22 and 23 are stacked is formed in the other of the memory cell arrays 10-1 and 10-2.

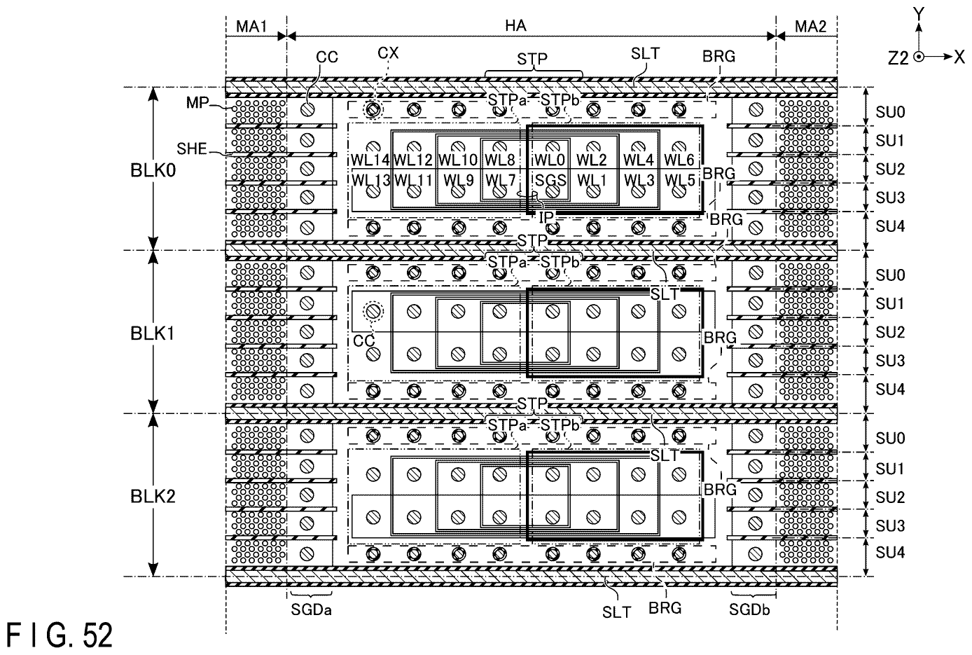

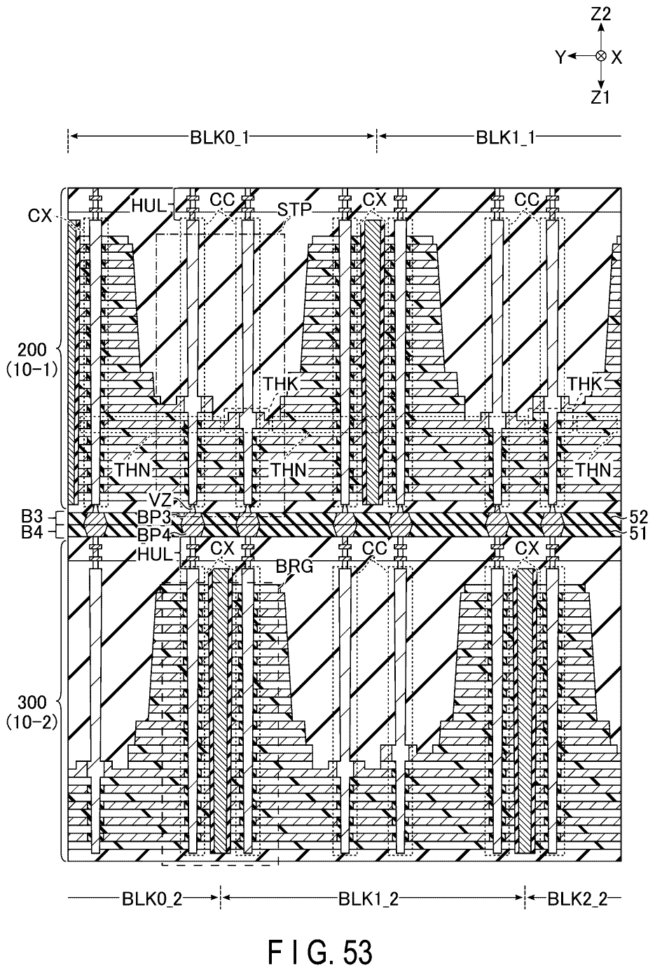

FIG. 52 is a plan view illustrating an example of a planar layout in the hookup area of the memory cell array included in the semiconductor memory device according to the seventh embodiment. illustrates areas corresponding to three blocks BLK0 to BLK2. FIG. 52 illustrates areas corresponding to three blocks BLK0 to BLK2. FIG. 53 is a sectional view illustrating an example of a sectional structure of the first memory layer, the second memory layer, and the joint layer provided between the first memory layer and the second memory layer included in the semiconductor memory device according to the seventh embodiment. In FIG. 53, areas corresponding to the block BLK0 and a part of the block BLK1 in the memory cell array 10-1 and the block BLK1 and a part of the blocks BLK0 and BLK2 in the memory cell array 10-2 are illustrated. The stacked interconnects in the memory cell arrays 10-1 and 10-2 illustrated in FIG. 53 correspond to a select gate line SGS and word lines WL0 to WL14 in this order from the bottom.

As illustrated in FIGS. 52 and 53, each memory cell array 10 includes, for example, a two-column stepped structure having one step in the Y direction and two steps in the X direction stepwise in the stepped area STP. In the example illustrated in FIGS. 52 and 53, one step in the Y direction is provided in two blocks BLK adjacent to each other with the member SLT interposed therebetween in a line-symmetric shape in the Y direction with respect to the member SLT. Two rows of contacts CC are provided corresponding to the respective terrace portions of the two-column stepped structures. In addition, two rows of contacts CX are provided in the bridge area BRG. That is, each memory cell array 10 has a four-lane contact structure.

Each thick film portion THK in each of interconnect layers 22 and 23 is separated in the X direction from a side surface of a thick film portion THK of the interconnect layer 23 or 24 provided two layers above the interconnect layer 22 and 23. In addition, each thick film portion THK in each of the interconnect layers 22 and 23 is separated in the Y direction from the side surface of the thick film portion THK of the interconnect layer 23 or 24 provided one layer above the interconnect layer 22 and 23.

As illustrated in FIG. 53, the contact CC of the memory cell array 10-1 is not provided above the member SLT provided in the memory cell array 10-2. Further, the contact CC of the memory cell array 10-2 is not provided below the member SLT provided in the memory cell array 10-1. That is, in the memory cell arrays 10-1 and 10-2, the member SLT of one of the memory cell arrays 10-1 and 10-2 and the contact CC of the other of the memory cell arrays 10-1 and 10-2 are provided so as not to overlap each other.

As illustrated in FIG. 52, for example, the contact CX is not provided in the terrace portion of the select gate line SGD. The contact CC coupled to the terrace portion of the select gate line SGD in the memory cell array 10-2 is routed via the upper layer interconnect HUL, the joint pads BP3 and BP4, and interconnects (not illustrated), and is coupled to a row decoder module 16.

### 7.2 Effects

According to the seventh embodiment, similarly to the first embodiment and the fifth embodiment, the degree of integration of the semiconductor memory device 3 can be improved.

### 7.3 Modifications

The semiconductor memory device 3 according to the seventh embodiment described above can be variously modified. For example, modifications corresponding to the first to third modifications of the first embodiment and modifications corresponding to the second embodiment and the first and second modifications of the second embodiment may be applied to the semiconductor memory device 3 according to the seventh embodiment.

### 8. Eighth Embodiment

Next, a semiconductor memory device according to an eighth embodiment will be described. A semiconductor memory device 3 according to the eighth embodiment is different from a semiconductor memory device 3 according to the seventh embodiment in a stepped structure in each memory cell array 10. In the following description, description about configurations equivalent to those of the seventh embodiment will be omitted, and configurations different from those of the seventh embodiment will be mainly described.

### 8.1 Structure of Memory Cell Array

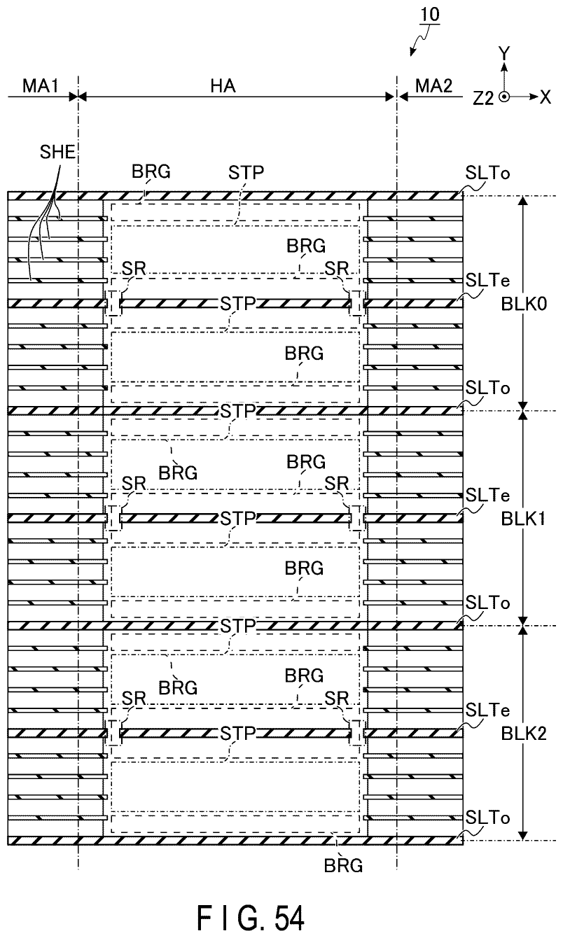

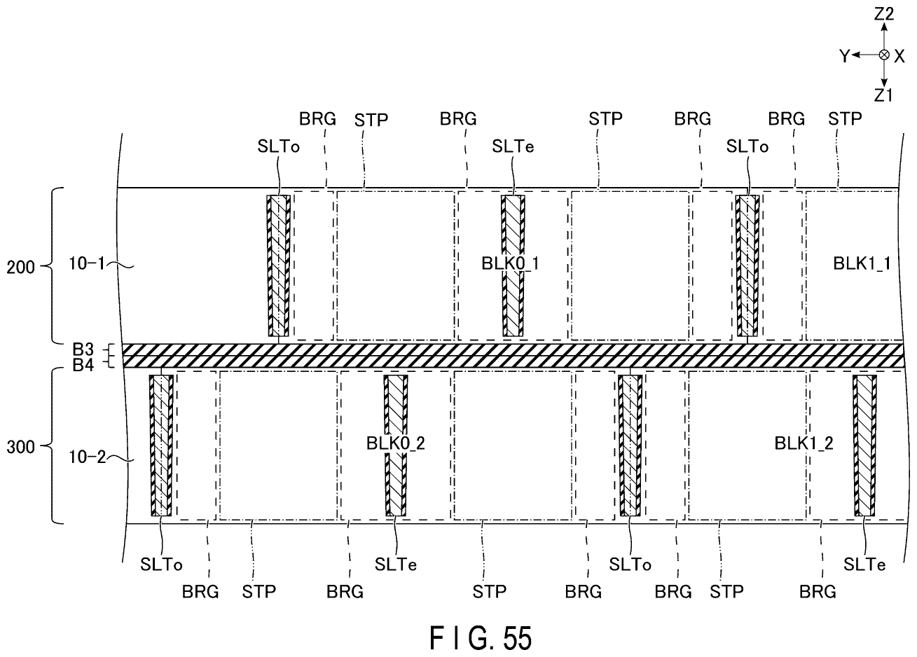

FIG. 54 is a plan view illustrating an example of a planar layout of the memory cell array included in the semiconductor memory device according to the eighth embodiment. FIG. 54 illustrates areas corresponding to three blocks BLK0 to BLK2. FIG. 55 is a schematic sectional view schematically illustrating an example of a sectional structure of a first memory layer and a second memory layer that are bonded together, which are included in the semiconductor memory device according to the eighth embodiment. FIG. 55 illustrates a first memory layer 200 and a second memory layer 300, and joint layers B3 and B4.

As illustrated in FIG. 54, in each memory cell array 10 included in the semiconductor memory device 3 according to the eighth embodiment, similarly to the fourth embodiment, each of areas partitioned by a plurality of members SLTo included in each memory cell array 10 corresponds to one block BLK in each memory cell array 10. A plurality of members SLTe included in each memory cell array 10 are divided into a plurality of portions in an X direction in one or more divided areas SR provided in a hookup area HA. That is, the member SLTe is divided in the divided area SR, so that each of a plurality of interconnect layers 22 and 23 corresponding to a select gate line SGS and word lines WL0 to WL14 is not divided in a Y direction. In other words, the interconnect layers 22 and 23 adjacent to each other in the Y direction with the member SLTe interposed therebetween are coupled to each other in the Y direction via the divided area SR. That is, the divided area SR is a coupling area of the interconnect layers 22 and 23 adjacent to each other in the Y direction with the member SLTe interposed therebetween.

As illustrated in FIG. 55, a memory cell array 10-1 of the first memory layer 200 and a memory cell array 10-2 of the second memory layer 300 are bonded to each other in the Z direction while being shifted in the Y direction by a quarter block BLK via the joint layers B3 and B4. Specifically, a block BLKi_1 of the memory cell array 10-1 is provided above a block BLKi_2 and a block BLK(i+1)_2 of the memory cell array 10-2, and the block BLK(i+1)_2 of the memory cell array 10-2 is provided below the block BLKi_1 and the block BLK(i+1)_1 of the memory cell array 10-1 (i is an integer satisfying 0≤i≤n−1). A dummy block is not provided.

The stepped area STP of the memory cell array 10-1 is provided above the members SLTo and SLTe of the memory cell array 10-2. The stepped area STP of the memory cell array 10-2 is provided below the members SLTo and SLTe of the memory cell array 10-1. That is, the member SLT of one of the memory cell arrays 10-1 and 10-2 overlaps the stepped area STP of the other of the memory cell arrays 10-1 and 10-2.

The stepped area STP of the memory cell array 10-1 and the stepped area STP of the memory cell array 10-2 are provided side by side in the Y direction at positions different from each other in the Z direction. Specifically, the bridge area BRG of the memory cell array 10-2 is provided below the stepped area STP of the memory cell array 10-1. The bridge area BRG of the memory cell array 10-1 is provided above the stepped area STP of the memory cell array 10-2. That is, in a case where the stepped area STP is provided and a stepwise structure is formed in one of the memory cell arrays 10-1 and 10-2 at positions overlapping each other in the Z direction, a structure in which the bridge area BRG is provided and the plurality of interconnect layers 22 and 23 are stacked is formed in the other of the memory cell arrays 10-1 and 10-2.

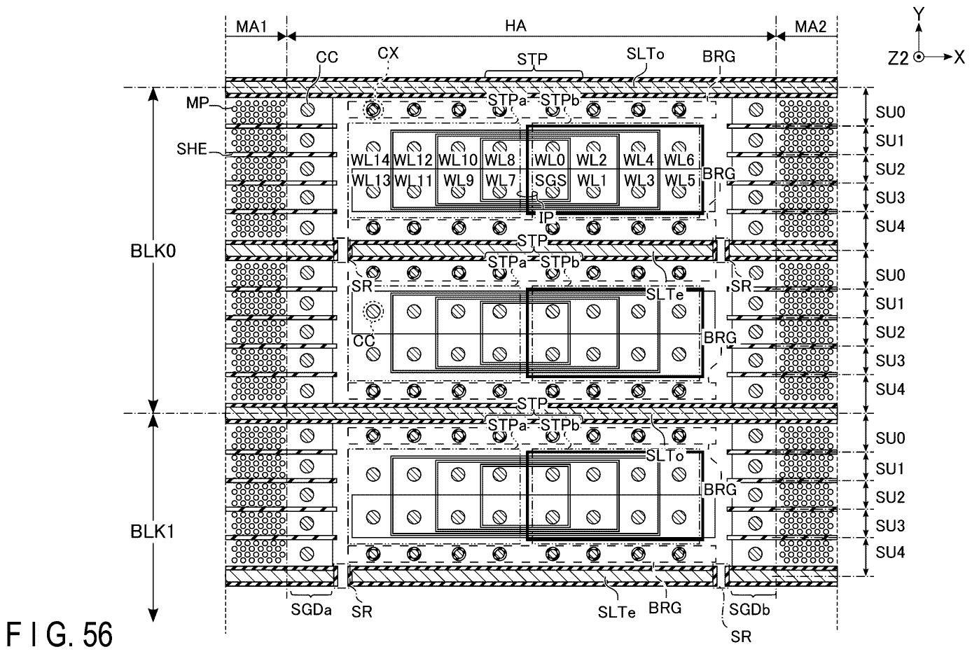

FIG. 56 is a plan view illustrating an example of a planar layout in the hookup area of the memory cell array included in the semiconductor memory device according to the eighth embodiment. In FIG. 56, areas corresponding to the block BLK0 and a part of the block BLK1 are illustrated. As illustrated in FIG. 56, a first portion SGDa and a second portion SGDb of the select gate line SGD are divided into 10 portions in one block BLK by the members SLTe and SHE. Each of the first portion SGDa and the second portion SGDb of the select gate line SGD has two portions, each of which corresponds to string units SU0 to SU4 in one block BLK. For each portion of the select gate line SGD divided into 10 portions, one contact CC is provided. As illustrated in FIG. 56, for example, a contact CX is not provided in a terrace portion of the select gate line SGD. The contact CC coupled to the terrace portion of the select gate line SGD in the memory cell array 10-2 is routed via the upper layer interconnect HUL, the joint pads BP3 and BP4, and interconnects (not illustrated), and is coupled to a row decoder module 16.

Note that the structure of the select gate line SGD is not limited to the above structure. For example, each of the first portion SGDa and the second portion SGDb of the select gate line SGD may include one portion corresponding to the string units SU0 to SU4.

The configurations of two stepped areas STP in one block BLK are substantially the same. Therefore, two contacts CC corresponding to the same interconnect layer 22 or 23 are provided in one block BLK. In addition, among the three bridge areas BRG, in each of the two bridge areas BRG provided between the two stepped areas STP and the two members SLTo adjacent to the block BLK, one row of contacts CX are provided side by side in the X direction. In the bridge area BRG provided between the two stepped areas STP, two rows of contacts CX are provided side by side in the X direction so as to sandwich the member SLTe.

### 8.2 Effects

According to the eighth embodiment, similarly to the seventh embodiment, the degree of integration of the semiconductor memory device 3 can be improved.

In addition, according to the eighth embodiment, two contacts CC corresponding to each interconnect layer 22 or 23 are provided. As a result, it is possible to reduce the electrical resistance in interconnects that mediate each interconnect layer 22 or 23 and a row decoder module 16. Therefore, the read speed and the write speed of the semiconductor memory device 3 can be improved.

### 8.3 Modifications

The semiconductor memory device 3 according to the eighth embodiment described above can be variously modified. For example, modifications corresponding to the first to third modifications of the first embodiment and modifications corresponding to the second embodiment and the first and second modifications of the second embodiment may be applied to the semiconductor memory device 3 according to the eighth embodiment.

### 9. Others

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A semiconductor memory device comprising:
a first interconnect layer which is provided in a first area as viewed in a first direction;
a plurality of second interconnect layers which are provided apart from each other in the first direction above the first interconnect layer and over the first area and a second area aligned with the first area in a second direction intersecting the first direction, the second interconnect layers including, in the second area, a plurality of first terrace portions provided so as not to overlap an upper second interconnect layer in the first direction and a first bridge portion extending in the second direction, and the first terrace portions and the first bridge portion being arranged in a third direction intersecting the first direction and the second direction;
a third interconnect layer which is provided in the first area above the second interconnect layers;
a plurality of fourth interconnect layers which are provided apart from each other in the first direction above the third interconnect layer and over the first area and the second area, the fourth interconnect layers including, in the second area, a plurality of second terrace portions provided at positions overlapping the first bridge portion as viewed in the first direction so as not to overlap an upper fourth interconnect layer in the first direction and a second bridge portion extending in the second direction and provided at positions overlapping the first terrace portions as viewed in the first direction, and the second terrace portions and the second bridge portion being arranged in the third direction;
a first memory pillar which extends in the first direction in the first area and is in contact with the first interconnect layer, and in which portions passing through the second interconnect layers function as a plurality of first memory cells;
a second memory pillar which extends in the first direction in the first area and is in contact with the third interconnect layer, and in which portions passing through the fourth interconnect layers function as a plurality of second memory cells;
a first contact which is in contact with one of the first terrace portions and extends in the first direction in the second area;
a second contact which extends in the first direction above the first contact in the second area, passes through the fourth interconnect layers, and is electrically coupled to the first contact; and
a third contact which is in contact with one of the second terrace portions and extends in the first direction in the second area.

2. The semiconductor memory device according to claim 1, further comprising:
a first electrode and a second electrode which are provided to face each other in the first direction and are in contact with each other in the first direction at positions sandwiched in the first direction between the second interconnect layers and the third interconnect layer, wherein
the first electrode is electrically coupled to the first contact,
the second electrode is electrically coupled to the second contact, and
the first contact and the second contact are electrically coupled via the first electrode and the second electrode.

3. The semiconductor memory device according to claim 1, further comprising:
a fourth contact which extends in the first direction below the third contact and passes through the second interconnect layers in the second area.

4. The semiconductor memory device according to claim 1, wherein
the first contact passes through a second interconnect layer provided below the one of the first terrace portions among the second interconnect layers in the first direction, and
the third contact passes through a fourth interconnect layer provided below the one of the second terrace portions among the fourth interconnect layers in the first direction.

5. The semiconductor memory device according to claim 1, wherein
each of the first terrace portions is thicker in the first direction than other portions of the second interconnect layers, and
each of the second terrace portions is thicker in the first direction than other portions of the fourth interconnect layers.

6. The semiconductor memory device according to claim 1, wherein
the first terrace portions include a plurality of first sub-terrace portions which are provided in a step shape descending to one side in the second direction, and a plurality of second sub-terrace portions which are provided in a step shape ascending to the one side in the second direction,
the second terrace portions include a plurality of third sub-terrace portions which are provided in a step shape descending to the one side in the second direction, and a plurality of fourth sub-terrace portions which are provided in a step shape ascending to the one side in the second direction,
the first sub-terrace portions and the second sub-terrace portions are arranged side by side in the second direction in the second area, and
the third sub-terrace portions and the fourth sub-terrace portions are arranged side by side in the second direction in the second area.

7. The semiconductor memory device according to claim 6, wherein
the first sub-terrace portions and the third sub-terrace portions are arranged side by side in the third direction as viewed in the first direction, and
the second sub-terrace portions and the fourth sub-terrace portions are arranged side by side in the third direction as viewed in the first direction.

8. The semiconductor memory device according to claim 6, wherein
some of the second interconnect layers continuously provided in the first direction have a first end surface intersecting the second direction in a portion sandwiched in the second direction between the first sub-terrace portions and the second sub-terrace portions in the second area, and
some of the fourth interconnect layers continuously provided in the first direction have a second end surface intersecting the second direction in a portion sandwiched in the second direction between the third sub-terrace portions and the fourth sub-terrace portions in the second area.

9. The semiconductor memory device according to claim 1, wherein
the second contact and the third contact are provided side by side in the third direction.

10. The semiconductor memory device according to claim 3, wherein
the first contact and the fourth contact are provided side by side in the third direction.

11. The semiconductor memory device according to claim 1, further comprising:
a fifth interconnect layer which is provided over the first area and the second area at a position sandwiched in the first direction between the second interconnect layers and the third interconnect layer;
a sixth interconnect layer which is provided over the first area and the second area above the fourth interconnect layers;
a fifth contact which is in contact with the fifth interconnect layer and extends in the first direction in the second area;
a sixth contact which extends in the first direction above the fifth contact in the second area, passes through the fourth interconnect layers and the sixth interconnect layer, and is electrically coupled to the fifth contact; and
a seventh contact which is in contact with the sixth interconnect layer and extends in the first direction in the second area, wherein
the sixth contact and the seventh contact are arranged in the second direction.

12. The semiconductor memory device according to claim 11, further comprising:
an eighth contact which extends in the first direction below the seventh contact and passes through the second interconnect layers and the fifth interconnect layer in the second area, wherein
the fifth contact and the eighth contact are arranged in the second direction.

13. The semiconductor memory device according to claim 1, further comprising:
a first insulating member and a second insulating member which extend in the first direction and the second direction in the first area and the second area and are provided so as to sandwich the second interconnect layers in the third direction; and
a third insulating member and a fourth insulating member which extend in the first direction and the second direction in the first area and the second area and are provided so as to sandwich the fourth interconnect layers in the third direction, wherein
the first bridge portion of the second interconnect layers are in contact with the first insulating member in the third direction, and
the second bridge portion of the fourth interconnect layers are in contact with the third insulating member in the third direction.

14. The semiconductor memory device according to claim 13, wherein
the first insulating member and the fourth insulating member are provided at positions overlapping each other as viewed in the first direction, and
the second insulating member and the third insulating member are provided at positions overlapping each other as viewed in the first direction.

15. The semiconductor memory device according to claim 14, wherein
each of the first terrace portions of the second interconnect layers is in contact with the second insulating member in the third direction, and
each of the second terrace portions of the fourth interconnect layers is in contact with the fourth insulating member in the third direction.

16. The semiconductor memory device according to claim 13, wherein
the first insulating member is provided at a position overlapping the second terrace portions of the fourth interconnect layers as viewed in the first direction, and
the third insulating member is provided at a position overlapping the first terrace portions of the second interconnect layers as viewed in the first direction.

17. The semiconductor memory device according to claim 16, wherein
each of the second interconnect layers further includes a third bridge portion which extends in the second direction and is provided so as to sandwich the first terrace portions in the third direction together with the first bridge portion,
each of the fourth interconnect layers further includes a fourth bridge portion which extends in the second direction and is provided so as to sandwich the second terrace portions in the third direction together with the second bridge portion,
the third bridge portion of the second interconnect layers are in contact with the second insulating member in the third direction, and
the fourth bridge portion of the fourth interconnect layers are in contact with the fourth insulating member in the third direction.

18. The semiconductor memory device according to claim 13, further comprising:
a fifth insulating member which extends in the first direction and the second direction in the second area and divides the first terrace portions of the second interconnect layers in the third direction; and
a sixth insulating member which extends in the first direction and the second direction in the second area and divides the second terrace portions of the fourth interconnect layers in the third direction, wherein
the first insulating member and the sixth insulating member are provided at positions overlapping each other as viewed in the first direction, and
the third insulating member and the fifth insulating member are provided at positions overlapping each other as viewed in the first direction.

19. The semiconductor memory device according to claim 18, further comprising:
a seventh insulating member which extends and passes through the second interconnect layers in the first direction and the second direction in the first area, is separated from the fifth insulating member in the second direction and provided side by side with the fifth insulating member in the second direction; and
an eighth insulating member which extends and passes through the fourth interconnect layers in the first direction and the second direction in the first area, is separated from the sixth insulating member in the second direction and provided side by side with the sixth insulating member in the second direction.

20. The semiconductor memory device according to claim 1, wherein
the first interconnect layer, the second interconnect layers, the third interconnect layer, and the fourth interconnect layers are further provided in a third area which is located on a side opposite to the first area in the second direction with respect to the second area and is aligned with the second area in the second direction, and
the device further comprises:
a third memory pillar which extends in the first direction in the third area and is in contact with the first interconnect layer, and in which portions passing through the second interconnect layers function as a plurality of third memory cells; and
a fourth memory pillar which extends in the first direction in the third area and is in contact with the third interconnect layer, and in which portions passing through the fourth interconnect layers function as a plurality of fourth memory cells.
